(19) United States
(12) Patent Application Publication
(10) Pub. No.: US 2025/0311613 A1
(43) Pub. Date: Oct. 2, 2025

(54) ORGANIC ELECTROLUMINESCENT DEVICE AND DISPLAY DEVICE THEREOF

(71) Applicant: BEIJING SUMMER SPROUT TECHNOLOGY CO., LTD., Beijing (CN)

(72) Inventors: Chunliang ZHAO, Beijing (CN); Ming SANG, Beijing (CN); Xuechao TIAN, Beijing (CN); Liuhuan CAI, Beijing (CN); Chi Yuen Raymond KWONG, Beijing (CN); Chuanjun XIA, Beijing (CN); Zhen WANG, Beijing (CN); Hongbo LI, Beijing (CN); Wei CAI, Beijing (CN); Zheng WANG, Beijing (CN)

(21) Appl. No.: 19/091,522

(22) Filed: Mar. 26, 2025

(30) Foreign Application Priority Data
Mar. 28, 2024 (CN) 202410369633.3
Feb. 14, 2025 (CN) 202510163633.2

(51) Int. Cl. H10K 85/30; C09K 11/02; C09K 11/06; H10K 50/12; H10K 85/60; H10K 101/00

(52) U.S. Cl. CPC H10K 85/342; C09K 11/02; C09K 11/06; H10K 85/346; H10K 85/654; H10K 85/6572; H10K 85/6574; H10K 85/658; C09K 2211/1018; H10K 50/121; H10K 2101/27

(57) ABSTRACT

Provided are an organic electroluminescent device and a display device. The organic layer of the organic electroluminescent device includes a metal complex having a specific structure (including a ligand Lₐ having a structure of Formula 1), a fluorescent emissive material having a structure represented by Formula 1-1, and a specific small-molecule first host compound having a triplet energy level higher than the triplet energy level of the metal complex. The new organic electroluminescent device can further achieve significant improvements in device power efficiency and/or lifetime while maintaining a relatively low drive voltage and a relatively narrow full width at half maximum and has excellent overall performance. Further provided is a display device including the organic electroluminescent device.

### CROSS-REFERENCE TO RELATED APPLICATION(S)

This application claims priority to Chinese Patent Application No. 202410369633.3 filed Mar. 28, 2024, and Chinese Patent Application No. 202510163633.2 filed Feb. 14, 2025, the disclosure of which are incorporated herein by reference in their entireties.

### TECHNICAL FIELD

The present disclosure relates to organic electronic devices, for example, organic electroluminescent devices. More particularly, the present disclosure relates to an organic electroluminescent device including a first host compound, a metal complex, and a fluorescent emissive material in an organic layer and a display device including the organic electroluminescent device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron transport layer and emitting layer (Applied Physics Letters, 1987, 51 (12): 913-915). Once a bias is applied to the device, green light was emitted from the device. This device laid the foundation for the development of modem organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently. Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

Angew. Chem. Int. Ed. 2023, 62, e202304104, discloses a fluorescent emissive compound with a structural formula of

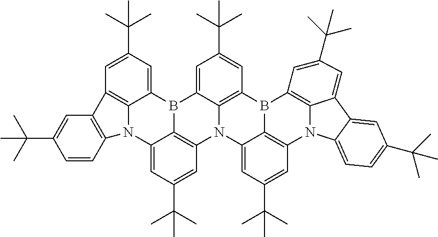 [SMILES: CC(C)(C)c1cc2c3c(c1)B1c4c(cc(C(C)(C)C)cc4-n4c5ccc(C(C)(C)C)cc5c5cc(C(C)(C)C)cc1c54)N3c1cc(C(C)(C)C)cc3c1B2c1cc(C(C)(C)C)cc2c4cc(C(C)(C)C)ccc4n-3c12]

and a device including the same. The device uses Ir(ppy)₃ as a phosphorescent sensitizer and adopts various host materials to achieve relatively good performance in phosphor-sensitized fluorescence. However, this article only discloses the specific application of Ir(ppy)₃ as a phosphorescent sensitizer and does not teach devices using metal complexes of other structures as phosphorescent sensitizers in conjunction with fluorescent emissive materials with specific structures and the special effects thereof.

In addition to the new emissive materials, the combination of various materials, in particular, the combination of various phosphorescent sensitizers, fluorescent emissive materials and/or host materials, is particularly important for the performance of the device. To meet increasing requirements of the industry, especially requirements for performance such as higher device efficiency and longer lifetime, the combination of different phosphorescent sensitizers and fluorescent emissive materials still requires further research and development.

### SUMMARY

The present disclosure aims to provide a new organic electroluminescent device to solve at least part of the above problems. The organic layer of the organic electroluminescent device includes a metal complex having a specific structure (including a ligand Lₐ having a structure of Formula 1), a fluorescent emissive material having a structure represented by Formula 1-1, and a specific small-molecule first host compound having a triplet energy level higher than the triplet energy level of the metal complex. The new organic electroluminescent device of the present disclosure can further achieve a significant improvement in device efficiency and/or lifetime while maintaining a relatively low drive voltage and a relatively narrow full width at half maximum and has excellent overall performance.

According to an embodiment of the present disclosure, an organic electroluminescent device is disclosed. The organic electroluminescent device includes:
an anode,
a cathode, and
an organic layer disposed between the anode and the cathode, wherein the organic layer at least includes a first host compound, a metal complex, and a fluorescent emissive material;
wherein the triplet energy level of the first host compound is greater than the triplet energy level of the metal complex;
the first host compound is a small molecule compound;
the metal complex includes a metal M and a ligand Lₐ coordinated to the metal M, wherein the metal M is selected from a metal with a relative atomic mass greater than 40, and Lₐ has a structure represented by Formula 1:

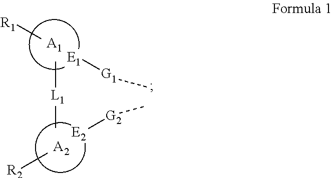

wherein,
the ring A₁ and the ring A₂ are selected from an aromatic ring having 6 to 30 ring atoms, a heteroaromatic ring having 5 to 30 ring atoms or a combination thereof;
E₁ and E₂ are, at each occurrence identically or differently, selected from C or N;
G₁ and G₂ are, at each occurrence identically or differently, selected from a single bond, O, S or NR′;
L₁ is, at each occurrence identically or differently, selected from the group consisting of: a single bond, BR″, CR″R″, NR″, O, SiR″R″, PR″, S, GeR″R″, Se, substituted or unsubstituted vinylene, ethynylene, substituted or unsubstituted arylene having 6 to 30 carbon atoms, substituted or unsubstituted heteroarylene having 3 to 30 carbon atoms, and combinations thereof; when two R″ are present at the same time, the two R″ are the same or different;
R₁ and R₂ represent, at each occurrence identically or differently, mono-substitution, multiple substitutions or non-substitution,
R₁, R₂, R′, and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
when the metal M is selected from Ir. L₁ is selected from a single bond, G₁ and G₂ are selected from a single bond, one of the ring A₁ and the ring A₂ is selected from a benzene ring, and the other of the ring A₁ and the ring A₂ is selected from a pyridine ring, R₁ and R₂ represent, at each occurrence identically or differently, mono-substitution or multiple substitutions, and at least one of R₁ and R₂ is selected from deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, or a combination thereof;
adjacent substituents R₁, R₂, R′, and R″ can be optionally joined to form a ring;
the fluorescent emissive material has a structure represented by Formula 1-1:

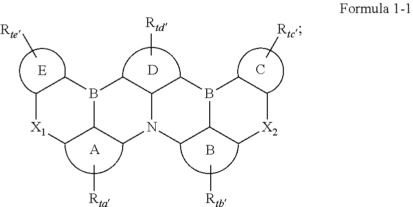

wherein the ring A, the ring B, the ring C, the ring D, and the ring E are, at each occurrence identically or differently, selected from an unsaturated carbocyclic ring having 5 to 30 carbon atoms or an unsaturated heterocyclic ring having 3 to 30 carbon atoms;
X₁ and X₂ are selected from O, S. Se, BR_{E}, NR_{E}, CR_{E}R_{E}, or SiR_{E}R_{E}; when two R_{E} are present at the same time, the two R_{E} are the same or different;
Rₜₐ′, R_{tb}′, R_{tc}′, R_{td}′, Rₜₑ′, and R_{E} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BRₜ″Rₜ″, and combinations thereof;
Rₜ″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₜₐ′, R_{tb}′, R_{tc}′, R_{td}′, Rₜₑ′, Rₜ″ and R_{E} can be optionally joined to form a ring.

According to another embodiment of the present disclosure, a display device is further disclosed. The display device includes the organic electroluminescent device described above.

According to another embodiment of the present disclosure, the use of the organic electroluminescent device described above in a display device is further disclosed.

### BRIEF DESCRIPTION OF DRAWINGS

FIG. 1 is a schematic diagram of an organic light-emitting device that may include an organic electroluminescent device disclosed herein.

FIG. 2 is a schematic diagram of another organic light-emitting device that may include an organic electroluminescent device disclosed herein.

### DETAILED DESCRIPTION

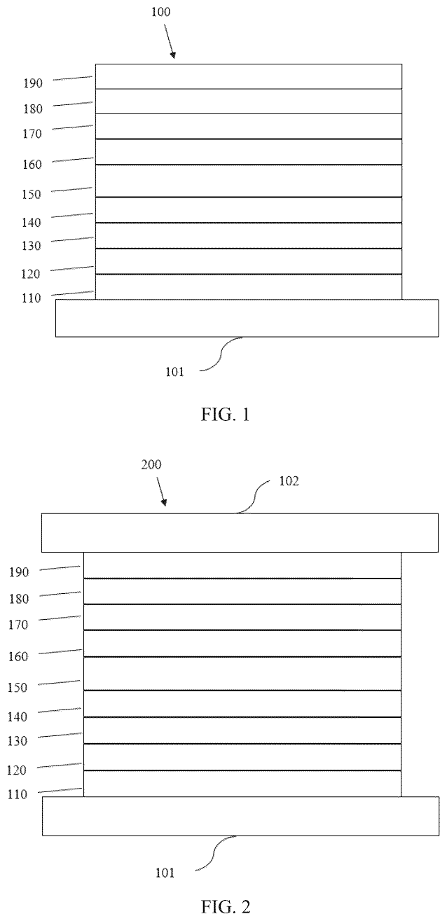

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly on the exterior of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

As used herein, “terminal emissive material” means a material serving as the final light-emitting source in an organic electroluminescent device (a device including at least two emissive materials in the emissive layer) described herein when the organic electroluminescent device is lit. For example, when the emissive layer of the organic electroluminescent device includes a metal complex (phosphorescent emissive material) and a fluorescent emissive material, if the metal complex does not/hardly emits light due to energy transfer when the device is lit while the fluorescent emissive material serves as the main light-emitting source of the device, then the fluorescent emissive material is the terminal emissive material of the electroluminescent device at this time in, including but not limited to, the Device Examples 1 to 7 of the present disclosure. Of course, the terminal emissive material in the organic electroluminescent device of the present disclosure may be one material or a variety of different materials.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbomyl, 2-norbomyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinvl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenvl, cyclopentenyl, cyclopentadienyl, cyclohexenyl, cycloheptenyl, cycloheptatrienyl, cyclooctenyl, cyclooctatetraenyl, and norbomenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group or an aromatic ring—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocyclyl—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl or a heteroaromatic ring—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrinmidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with at least one aryl group. Arylsilyl groups may be those having 6 to 30 carbon atoms, preferably those having 8 to 20 carbon atoms. Examples of arylsilyl groups include triphenylsilyl, phenvldibiphenvlylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

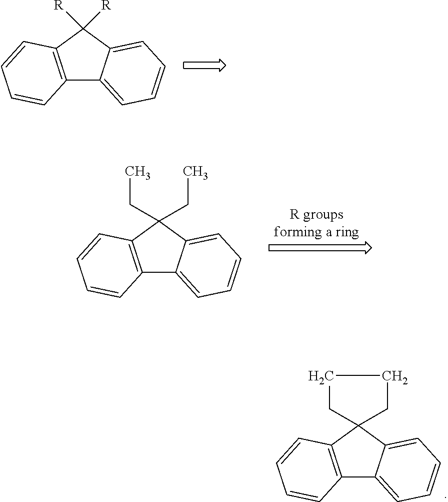

The expression that adjacent substituents can be optionally joined to form a ring is also intended to mean that two substituents bonded to carbon atoms which are directly bonded to each other are joined to each other via a chemical bond to form a ring, which can be exemplified by the following formula:

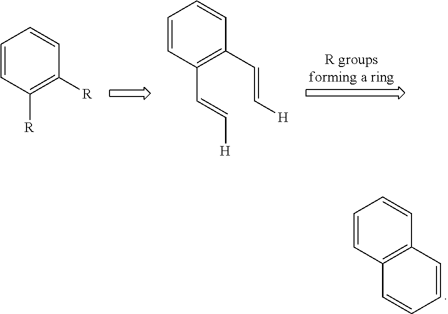

The expression that adjacent substituents can be optionally joined to form a ring is also intended to mean that two substituents bonded to further distant carbon atoms are joined to each other via a chemical bond to form a ring, which can be exemplified by the following formula:

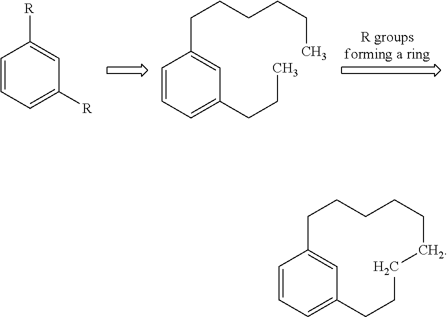

Furthermore, the expression that adjacent substituents can be optionally joined to form a ring is also intended to mean that, in the case where one of the two adjacent substituents represents hydrogen, the second substituent is bonded at a position at which the hydrogen atom is bonded, thereby forming a ring. This is exemplified by the following formula:

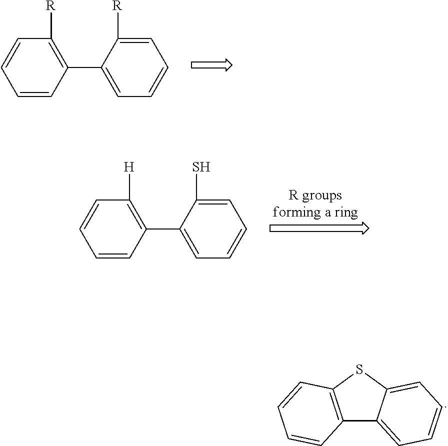

According to an embodiment of the present disclosure, an organic electroluminescent device is disclosed. The organic electroluminescent device includes:
an anode,
a cathode, and
an organic layer disposed between the anode and the cathode, wherein the organic layer at least
includes a first host compound, a metal complex, and a fluorescent emissive material;
wherein the triplet energy level of the first host compound is greater than the triplet energy level of the metal complex;
the first host compound is a small molecule compound;
the metal complex includes a metal M and a ligand Lₐ coordinated to the metal M, wherein the metal M is selected from a metal with a relative atomic mass greater than 40, and Lₐ has a structure represented by Formula 1:

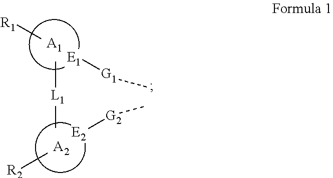

wherein,
the ring A₁ and the ring A₂ are selected from an aromatic ring having 6 to 30 ring atoms, a heteroaromatic ring having 5 to 30 ring atoms or a combination thereof;
E₁ and E₂ are, at each occurrence identically or differently, selected from C or N;
G₁ and G₂ are, at each occurrence identically or differently, selected from a single bond, O, S or NR′;
L₁ is, at each occurrence identically or differently, selected from the group consisting of: a single bond, BR″, CR″R″, NR″, O, SiR″R″, PR″. S, GeR″R″, Se, substituted or unsubstituted vinylene, ethynylene, substituted or unsubstituted arylene having 6 to 30 carbon atoms, substituted or unsubstituted heteroarylene having 3 to 30 carbon atoms, and combinations thereof; when two R″ are present at the same time, the two R″ are the same or different;
R₁ and R₂ represent, at each occurrence identically or differently, mono-substitution, multiple substitutions or non-substitution;
R₁, R₂, R′, and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
when the metal M is selected from Ir, L₁ is selected from a single bond, G₁ and G₂ are selected from a single bond, one of the ring A₁ and the ring A₂ is selected from a benzene ring, and the other of the ring A₁ and the ring A₂ is selected from a pyridine ring, R₁ and R₂ represent, at each occurrence identically or differently, mono-substitution or multiple substitutions, and at least one of R₁ and R₂ is selected from: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, or a combination thereof;
adjacent substituents R₁, R₂, R′, and R″ can be optionally joined to form a ring;
the fluorescent emissive material has a structure represented by Formula 1-1:

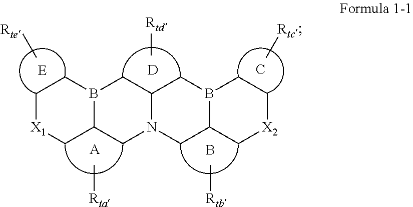

wherein the ring A, the ring B, the ring C, the ring D, and the ring E are, at each occurrence identically or differently, selected from an unsaturated carbocyclic ring having 5 to 30 carbon atoms or an unsaturated heterocyclic ring having 3 to 30 carbon atoms;
X₁ and X₂ are, at each occurrence identically or differently, selected from O, S, Se, BR_{E}, NR_{E}, CR_{E}R_{E}, or SiR_{E}R_{E}; when two R_{E} are present at the same time, the two R_{E} are the same or different;
wherein Rₜₐ′, R_{tb}′, R_{tc}′, R_{td}′ and Rₜₑ′ represent, at each occurrence identically or differently, mono-substitution, multiple substitutions or non-substitution;
Rₜₐ′, R_{tb}′, R_{tc}′, R_{td}′, Rₜₑ′, Rₜ″ and R_{E} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BRₜ″R″, and combinations thereof;
Rₜ″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₜₐ′, R_{tb}′, R_{tc}′, R_{td}′, Rₜₑ′, Rₜ″, and R_{E} can be optionally joined to form a ring.

As used herein, “small molecule compound” is a concept well known to those skilled in the art and refers to a compound that is not a polymer, as described in the Background of the present application. The “small molecule compound” herein is preferably an organic or organometallic compound having a well defined structure.

In the present disclosure, the expression that “adjacent substituents R₁, R₂, R′, and R″ can be optionally joined to form a ring” is intended to mean that any one or more of groups of adjacent substituents, such as two substituents R₁, two substituents R₂, two substituents R′, two substituents R″, substituents R₁ and R₂, substituents R′ and R₁, substituents R′ and R₂, substituents R″ and R₁, substituents R″ and R₂, and substituents R′ and R″, can be joined to form a ring. Obviously, it is also possible that none of these substituents are joined to form a ring.

In the present disclosure, the expression that “adjacent substituents Rₜₐ′, R_{tb}′, R_{tc}′, R_{td}′, Rₜₑ′, Rₜ″, and R_{E} can be optionally joined to form a ring” is intended to mean that any one or more of groups of adjacent substituents, such as two substituents Rₜₐ′, two substituents R_{tb}′, two substituents R_{tc}′, two substituents R_{td}′, two substituents Rₜₑ′, two substituents Rₜ″, two substituents R_{E}, substituents R_{E} and Rₜₑ′, substituents R_{E} and Rₜₐ′, substituents R_{E} and R_{tb}′ substituents R_{E} and R_{tc}′, substituents R_{td}′ and R_{tc}′, substituents R_{td}′ and R_{tc}′, and substituents Rₜₐ′ and R_{tb}′, can be joined to form a ring. Preferably, one or more groups of these substituents may be joined to form a carbocyclic ring (which may be aromatic or non-aromatic) or a heterocyclic ring (which may be aromatic or non-aromatic); more preferably, one or more groups of these substituents may be joined to from a carbocyclic ring or a heterocyclic ring having 3 to 24 ring atoms; even more preferably, one or more groups of these substituents may be joined to from a carbocyclic ring or a heterocyclic ring having 5 to 12 ring atoms; even still more preferably, one or more groups of these substituents may be joined to from a monocyclic carbocyclic ring or a monocyclic heterocyclic ring having 5 to 6 ring atoms. Obviously, it is also possible that none of these substituents are joined to form a ring.

In the present disclosure, the “carbocyclic ring” includes a saturated carbocyclic ring and an unsaturated carbocyclic ring, the “unsaturated carbocyclic ring” includes an aromatic unsaturated carbocyclic ring and a non-aromatic unsaturated carbocyclic ring, the “heterocyclic ring” includes a saturated heterocyclic ring and an unsaturated heterocyclic ring, and the “unsaturated heterocyclic ring” includes an aromatic unsaturated heterocyclic ring and a non-aromatic unsaturated heterocyclic ring.

In the present disclosure, when L₁ is selected from a single bond, it is indicated that the ring A₁ and the ring A₂ are directly joined by a single bond. When G₁ or G₂ is selected from a single bond, it is indicated that the ring A₁ or the ring A₂ is directly joined to the metal M by a single bond.

In the present disclosure, L₁ being joined to the ring A₁ and the ring A₂ in Formula 1 is intended to mean that L₁ in Formula 1 may be joined to any ring atom in the ring A₁ or the ring A₂ and does not only include the case in which L₁ is joined to an atom adjacent to E₁ in the ring A₁ or an atom adjacent to E₂ in the ring A₂.

According to an embodiment of the present disclosure, the relative molecular mass of the fluorescent emissive material ranges from 450 to 1500.

According to an embodiment of the present disclosure, the relative molecular mass of the fluorescent emissive material ranges from 500 to 1300.

According to an embodiment of the present disclosure, the relative molecular mass of the fluorescent emissive material ranges from 800 to 1200.

According to an embodiment of the present disclosure, the relative molecular mass of the fluorescent emissive material ranges from 600 to 1000.

According to an embodiment of the present disclosure, the ring A, the ring B, the ring C, the ring D, and the ring E are, at each occurrence identically or differently, selected from a five-membered unsaturated carbocyclic ring, an aromatic ring having 6 to 30 carbon atoms or a heteroaromatic ring having 3 to 30 carbon atoms.

According to an embodiment of the present disclosure, the ring A, the ring B, the ring C, the ring D. and the ring E are, at each occurrence identically or differently, selected from a five-membered unsaturated carbocyclic ring, an aromatic ring having 6 to 18 carbon atoms or a heteroaromatic ring having 3 to 18 carbon atoms.

According to an embodiment of the present disclosure, the ring A, the ring B, the ring C, the ring D, and the ring E are, at each occurrence identically or differently, selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring or a combination thereof.

According to an embodiment of the present disclosure, X₁ and X₂ are, at each occurrence identically or differently, selected from O, S, Se or NR_{E}.

According to an embodiment of the present disclosure, X₁ and X₂ are, at each occurrence identically or differently, selected from O or NR_{E}.

According to an embodiment of the present disclosure, the fluorescent emissive material has a structure represented by Formula 2-1. Formula 2-2, Formula 2-3, Formula 2-4, Formula 2-5 or Formula 2-6:

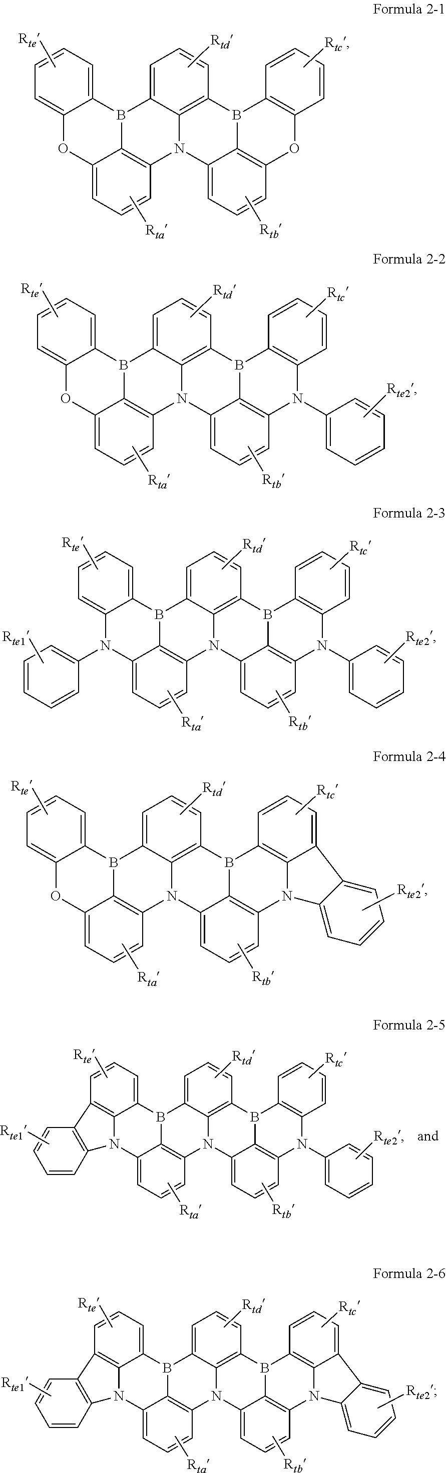

wherein Rₜₐ′, R_{tb}′, R_{tc}′, R_{td}′, Rₜₑ′, Rₜₑ₁′, and R_{te2′} represent, at each occurrence identically or differently, mono-substitution, multiple substitutions or non-substitution;
Rₜₐ′, R_{tb}′, R_{tc}′, R_{td}′, Rₜₑ′, Rₜₑ₁′, and R_{te2′} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BRₜ″Rₜ″, and combinations thereof;
Rₜ″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₜₐ′, R_{tb}′, R_{tc}′, R_{td}′, Rₜₑ′, Rₜ″, Rₜₑ₁′, and R_{te2′} can be optionally joined to form a ring.

In the present disclosure, the expression that “adjacent substituents Rₜₐ′, R_{tb}′, R_{tc}′, R_{td}′, Rₜₑ′, Rₜ″, Rₜₑ₁′, and R_{te2′} can be optionally joined to form a ring” is intended to mean that any one or more of groups of adjacent substituents, such as two substituents Rₜₐ′, two substituents R_{tb}′, two substituents R_{tc}′, two substituents R_{td}′, two substituents R_{tc}′, two substituents Rₜ″, two substituents R_{tc1}′, two substituents R_{tc2}′, substituents R_{tc1}′ and Rₜₑ′, substituents R_{tc1}′ and Rₜₐ′, substituents Rₜₑ₂′ and R_{tb}′, substituents Rₜₑ₂′ and R_{tc}′, substituents R_{td}′ and Rₜₑ′, substituents R_{td}′ and R_{tc}′, and substituents Rₜₐ′ and R_{tb}′, can be joined to form a ring. Obviously, it is also possible that none of these substituents are joined to form a ring.

According to an embodiment of the present disclosure, Rₜₐ′, R_{tb}′, R_{tc}′, R_{td}′, Rₜₑ′, Rₜ″, Rₜₑ₁′, and R_{te2′} are, at each occurrence identically or differently, selected from the group consisting of: hydrogen, deuterium, halogen, a cyano group, a hydroxyl group, a sulfanyl group, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, substituted or unsubstituted aryl having 6 to 24 carbon atoms, substituted or unsubstituted heteroaryl having 3 to 12 carbon atoms, substituted or unsubstituted alkylsilyl having 3 to 6 carbon atoms, substituted or unsubstituted arylsilyl having 6 to 12 carbon atoms, substituted or unsubstituted alkylgermanyl having 3 to 6 carbon atoms, substituted or unsubstituted arylgermanyl having 6 to 12 carbon atoms, substituted or unsubstituted amino having 0 to 12 carbon atoms, and combinations thereof.

According to an embodiment of the present disclosure, Rₜₐ′, R_{tb}′, R_{tc}′, R_{td}′, Rₜₑ′, Rₜ″, Rₜₑ₁′, and R_{te2′} are, at each occurrence identically or differently, selected from the group consisting of: hydrogen, deuterium, fluorine, cyano, hydroxyl, sulfanyl, methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, tetraphenyl, triphenylene, tetraphenylene, naphthyl, phenanthryl, anthryl, indenyl, fluorenyl, indolyl, carbazolyl, benzofuryl, dibenzofuryl, benzosilolyl, dibenzosilolyl, benzothienvl, dibenzothienvl, dibenzoselenophenyl, diphenylamino, dibenzofurylphenylamino, and combinations thereof.

According to an embodiment of the present disclosure, at least one of Rₜₐ′, R_{tb}′, R_{tc}′, R_{td}′, Rₜₑ′, Rₜ″, Rₜₑ₁′, and R_{te2′} is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least one of Rₜₐ′, R_{tb}′, R_{tc}′, R_{td}′, Rₜₑ′, Rₜ″, Rₜₑ₁′, and R_{te2′} is, at each occurrence identically or differently, selected from the group consisting of: deuterium, halogen, a cyano group, a hydroxyl group, a sulfanyl group, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, substituted or unsubstituted aryl having 6 to 24 carbon atoms, substituted or unsubstituted heteroaryl having 3 to 12 carbon atoms, substituted or unsubstituted alkylsilyl having 3 to 6 carbon atoms, substituted or unsubstituted arylsilyl having 6 to 12 carbon atoms, substituted or unsubstituted alkylgermanyl having 3 to 6 carbon atoms, substituted or unsubstituted arylgermanyl having 6 to 12 carbon atoms, substituted or unsubstituted amino having 0 to 12 carbon atoms, and combinations thereof.

According to an embodiment of the present disclosure, at least one of Rₜₐ′, R_{tb}′, R_{tc}′, R_{td}′, Rₜₑ′, Rₜ″, Rₜₑ₁′, and R_{te2′} is, at each occurrence identically or differently, selected from the group consisting of: deuterium, fluorine, cyano, hydroxyl, sulfanyl, methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, tetraphenyl, triphenylene, tetraphenylene, naphthyl, phenanthrvl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, diphenylanino, dibenzofurylphenylamino, and combinations thereof.

According to an embodiment of the present disclosure, the fluorescent emissive material is selected from the group consisting of Compound BD-1 to Compound BD-54, wherein the specific structures of Compound BD-1 to Compound BD-54 are referred to claim 7.

According to an embodiment of the present disclosure, hydrogens in Compound BD-1 to Compound BD-54 can be partially or fully substituted with deuterium.

According to an embodiment of the present disclosure, the metal complex has a general formula of M(Lₐ)ₘ(L_{b})ₙ(L_{c})_{q}, Lₐ, L_{b}, and L_{c} are a first ligand, a second ligand, and a third ligand coordinated to the metal M, respectively, and Lₐ is the same as or different from L_{c} or L_{b}; wherein Lₐ, L_{b}, and L_{c} can be optionally joined to form a multidentate ligand; the metal M is selected from a metal with a relative atomic mass greater than 40;
m is selected from 1, 2 or 3, n is selected from 0, 1 or 2, q is selected from 0, 1 or 2, and m+n+q is equal to an oxidation state of the metal M; when m is greater than or equal to 2, a plurality of Lₐ are the same or different; when n is equal to 2, two L_{b} are the same or different; when q is equal to 2, two L_{c} are the same or different;
L_{b} and L_{c} are, at each occurrence identically or differently, selected from a structure represented by any one of the group consisting of:

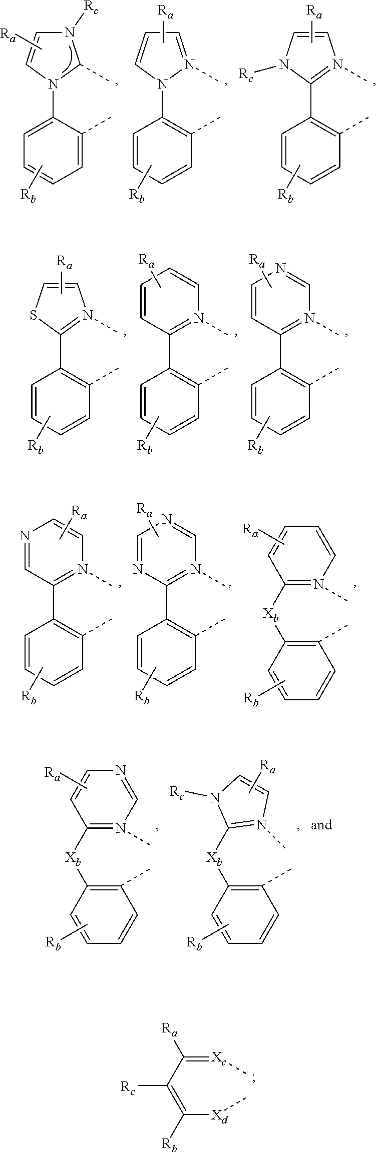

wherein,
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of O, S, Se, and NR_{N2};
Rₐ and R_{b}, represent, at each occurrence identically or differently, mono-substitution, multiple substitutions or non-substitution;
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ, R_{b}, R_{c}, R_{N1}, R_{N2}, R_{C1}, and R_{C2} can be optionally joined to form a ring.

In the present disclosure, the expression that “adjacent substituents Rₐ, R_{b}, R_{c}, R_{N1}, R_{N2}, R_{C1}, and R_{C2} can be optionally joined to form a ring” is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and Rₑ, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, can be joined to form a ring. For example, adjacent substituents Rₐ and R_{b} in

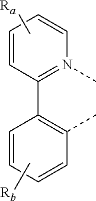

can be optionally joined to form a ring, which can form one or more of the following structures including, but not limited to,

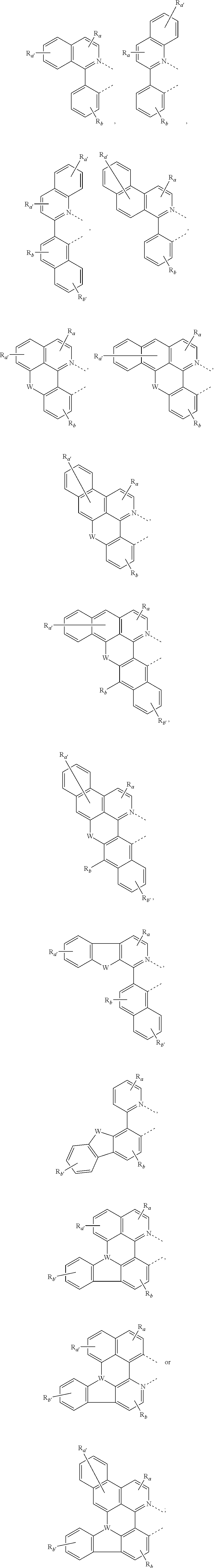

wherein W is selected from O, S, Se, NR_{w}, or CR_{w}R_{w}, and R_{w}, Rₐ′, and R_{b}′ are defined the same as Rₐ. Obviously, it is also possible that none of these substituents are joined to form a ring.

According to an embodiment of the present disclosure, the metal M is selected from the group consisting of Cu, Ag, Au, Ru, Rh, Pd, Os, Ir, and Pt.

According to an embodiment of the present disclosure, the metal M is selected from Pt or Ir.

According to an embodiment of the present disclosure, the metal complex has a general structure of Ir(Lₐ)ₘ(L_{b})₃₋ₘ and has a structure represented by Formula M-a:

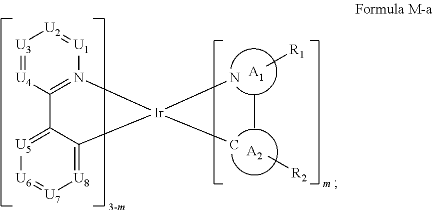

wherein,
m is selected from 1, 2 or 3; when m is selected from 1, two L_{b} are the same or different; when
m is selected from 2 or 3, multiple Lₐ are the same or different;
the ring A₁ is selected from a heteroaromatic ring having 5 to 30 ring atoms;
the ring A₂ is selected from an aromatic ring having 6 to 30 ring atoms, a heteroaromatic ring
having 5 to 30 ring atoms or a combination thereof;
U₁ to U₈ are, at each occurrence identically or differently, selected from CRᵤ or N;
R₁ and R₂ represent, at each occurrence identically or differently, mono-substitution, multiple substitutions or non-substitution;
R₁, R₂, and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
when the ring A₁ is selected from a pyridine ring and the ring A₂ is selected from a benzene ring, at least one of R₁ and R₂ is selected from deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, or a combination thereof;
adjacent substituents R₁, R₂, and Rᵤ can be optionally joined to form a ring.

In this embodiment, the expression that “adjacent substituents R₁, R₂, and Rᵤ can be optionally joined to form a ring” is intended to mean that any one or more of groups of adjacent substituents, such as two substituents R₁, two substituents R₂, two substituents Rᵤ, substituents R₁ and R₂, substituents R₁ and Rᵤ, and substituents R₂ and Rᵤ, can be joined to form a ring. Obviously, it is also possible that none of these substituents are joined to form a ring.

According to an embodiment of the present disclosure, the ring A₁ is, at each occurrence identically or differently, selected from any one of the following structures:

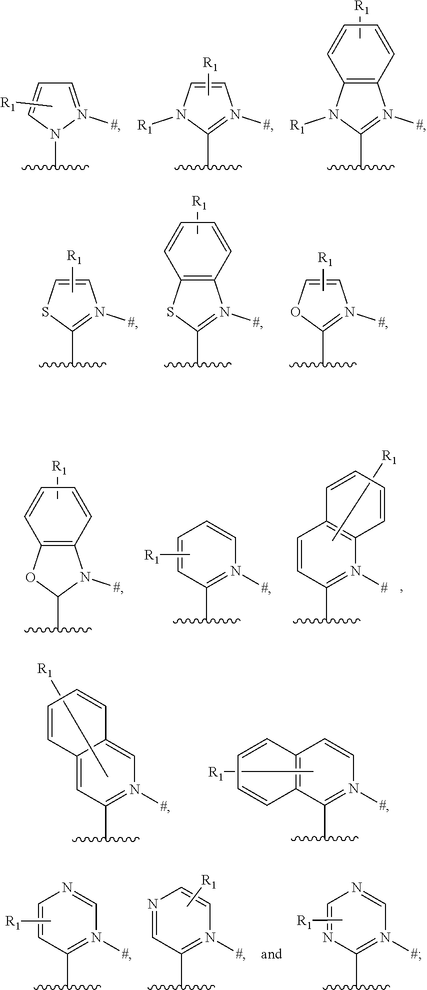

wherein,
R₁ represents, at each occurrence identically or differently, mono-substitution, multiple substitutions or non-substitution; when a plurality of R₁ are present at the same time in any structure, the plurality of R₁ are the same or different;
R₁ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ can be optionally joined to form a ring;
“#” represents a position where the metal Ir is joined, and

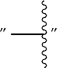

represents a position where the ring A₂ is joined.

According to an embodiment of the present disclosure, the ring A₁ is, at each occurrence identically or differently, selected from any one of the following structures:

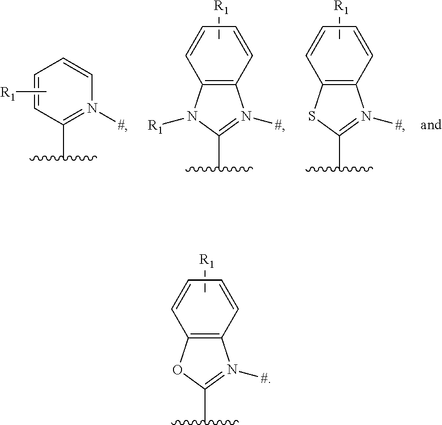

According to an embodiment of the present disclosure, the ring A₁ is, at each occurrence identically or differently, selected from

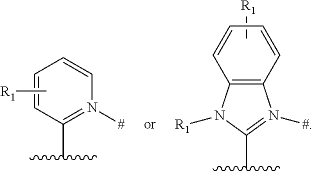

According to an embodiment of the present disclosure, the ring A₂ is, at each occurrence identically or differently, selected from any one of the following structures:

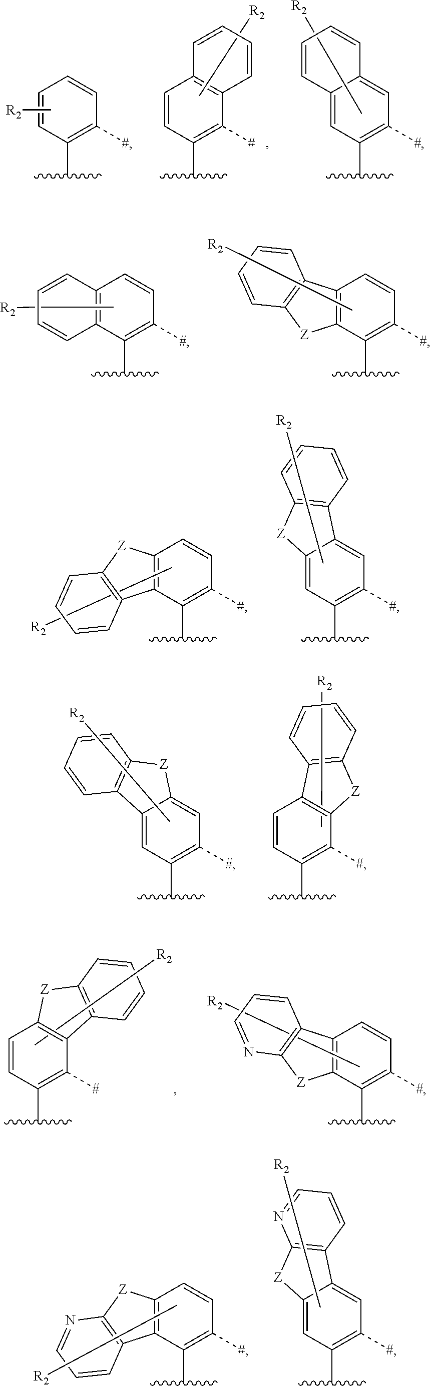

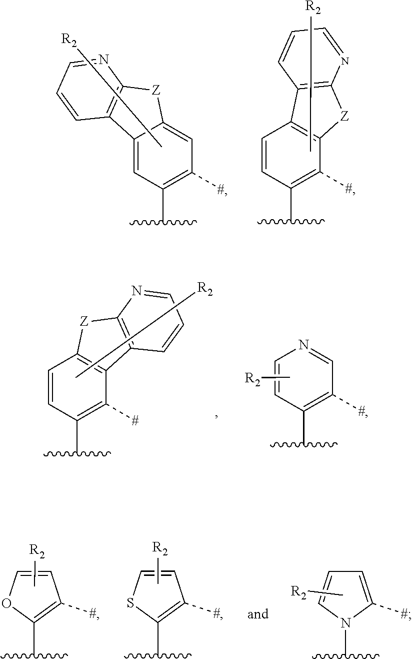

wherein,
Z is, at each occurrence identically or differently, selected from the group consisting of O, S, Se, NR, CRR, SiRR, and GeRR;
R₂ represents, at each occurrence identically or differently, mono-substitution, multiple substitutions or non-substitution; when a plurality of R₂ are present at the same time in any structure, the plurality of R₂ are the same or different;
R₂ and R are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₂ and R can be optionally joined to form a ring;
“#” represents a position where the metal Ir is joined, and

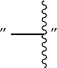

represents a position where the ring A₁ is joined.

According to an embodiment of the present disclosure, the ring A₂ is selected from

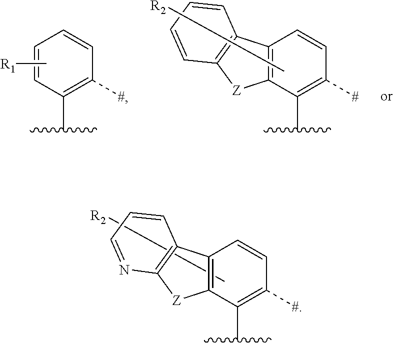

According to an embodiment of the present disclosure, the metal complex has a general structure of Ir(Lₐ)ₘ(L_{b})₃₋ₘ and has a structure represented by Formula M-a-1:

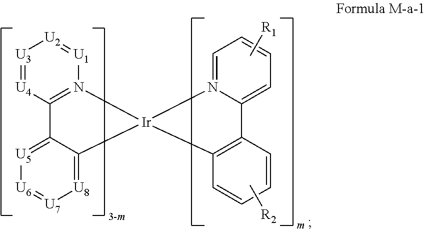

wherein,
m is selected from 1, 2 or 3; when m is selected from 1, two L_{b} are the same or different; when
m is selected from 2 or 3, two or three Lₐ are the same or different;
U₁ to U₈ are, at each occurrence identically or differently, selected from CRᵤ or N;
R₁ and R₂ represent, at each occurrence identically or differently, mono-substitution, multiple substitutions or non-substitution;
R₁, R₂, and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least one of R₁ and R₂ is selected from deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, or a combination thereof;
adjacent substituents R₁, R₂, and Rᵤ can be optionally joined to form a ring.

According to an embodiment of the present disclosure, when R₁ is multiple substitutions, at least one R₁ is, at each occurrence identically or differently, selected from deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, or a combination thereof.

According to an embodiment of the present disclosure, U₁ to U₈ are, at each occurrence identically or differently, selected from CRᵤ, and R₂ and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, and combinations thereof.

According to an embodiment of the present disclosure, the metal complex has a general structure of Ir(Lₐ)ₘ(L_{b})₃₋ₘ and has a structure represented by Formula M-a-0:

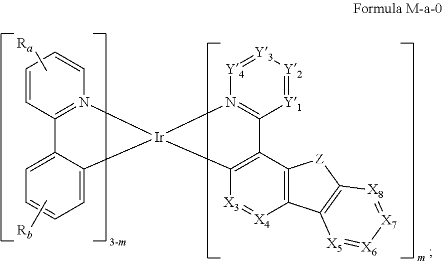

wherein,
m is selected from 1, 2 or 3; when m is selected from 1, two L_{b} are the same or different; when
m is selected from 2 or 3, two or three Lₐ are the same or different;
Z is selected from the group consisting of O, S, Se, NR, CRR, SiRR, and GeRR; when a plurality of R are present at the same time, the plurality of R are the same or different;
X₃ to X₈ are, at each occurrence identically or differently, selected from CR′₂ or N;
Y′₁ to Y′₄ are, at each occurrence identically or differently, selected from CR′₁ or N;
Rₐ and R_{b} represent, at each occurrence identically or differently, mono-substitution, multiple substitutions or non-substitution;
R′₁, R′₂, R, Rₐ, and R_{b} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R′₁, R′₂, R, Rₐ, and R_{b} can be optionally joined to form a ring.

In this embodiment, the expression that “adjacent substituents R′₁, R′₂, R, Rₐ, and R_{b} can be optionally joined to form a ring” is intended to mean that any one or more of groups of adjacent substituents, such as two substituents R′₁, two substituents R′₂, two substituents R, two substituent Rₐ, two substituents R_{b}, substituents R′₁ and R′₂, substituents R and R′₁, and substituents R and R′₂, can be joined to form a ring. Obviously, it is also possible that none of these substituents are joined to form a ring.

According to an embodiment of the present disclosure, Z is selected from O, S. Se, NR or CRR.

According to an embodiment of the present disclosure, Z is selected from O or S.

According to an embodiment of the present disclosure, Y′₁ to Y′₄ are, at each occurrence identically or differently, selected from CR′₁, and X₃ to X₈ are, at each occurrence identically or differently, selected from CR′₂, R′₁ and R′₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group, and combinations thereof.

According to an embodiment of the present disclosure, at least one of X₃ to X₈ is selected from N.

According to an embodiment of the present disclosure, X₈ is selected from N, and X₃ to X₇ are, at each occurrence identically or differently, selected from CR′₂; R′₂ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group, and combinations thereof.

According to an embodiment of the present disclosure, at least one of X₃ to X₈ is selected from CR′₂, and R′₂ is selected from a cyano group or fluorine.

According to an embodiment of the present disclosure, X₇ is selected from CR′₂, and R′₂ is selected from a cyano group or fluorine; or X₈ is selected from CR′₂, and R′₂ is selected from a cyano group.

According to an embodiment of the present disclosure, the metal complex has a structure represented by Formula M-b:

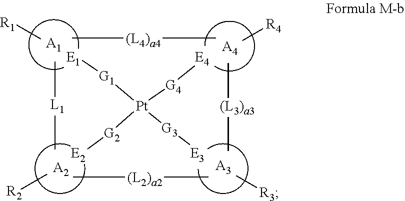

wherein the ring A₁ to the ring A₄ are, at each occurrence identically or differently, selected from an aromatic ring having 6 to 30 ring atoms, a heteroaromatic ring having 5 to 30 ring atoms or a combination thereof;
E₁ to E₄ are, at each occurrence identically or differently, selected from C or N;
G₁ to G₄ are, at each occurrence identically or differently, selected from a single bond, O, S or NR′,
L₁ to L₄ are, at each occurrence identically or differently, selected from the group consisting of: a single bond, BR″, CR″R″, NR″, O, SiR″R″, PR″, S, GeR″R″, Se, substituted or unsubstituted vinylene, ethynylene, substituted or unsubstituted arylene having 6 to 30 carbon atoms, substituted or unsubstituted heteroarylene having 3 to 30 carbon atoms, and combinations thereof; when two R″ are present at the same time, the two R″ are the same or different;
a₂ to a₄ are, at each occurrence identically or differently, selected from 0 or 1, and at least one of a₂ to a₄ is selected from 1;
R₁ to R₄ represent, at each occurrence identically or differently, mono-substitution, multiple substitutions or non-substitution;
R₁ to R₄, R′, and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ to R₄, R′, and R″ can be optionally joined to form a ring.

In the present disclosure, the expression that “adjacent substituents R₁ to R₄, R′, and R″ can be optionally joined to form a ring” is intended to mean that any one or more of groups of adjacent substituents, such as two substituents R₁, two substituents R₂, two substituents R₃, two substituents R₄, two substituents R″, two substituents R′, substituents R₁ and R₂, substituents R₁ and R₄, substituents R₂ and R₃, substituents R₃ and R₄, substituents R′ and R₁, substituents R′ and R₂, substituents R′ and R₁, substituents R′ and R₄, substituents R″ and R₁, substituents R″ and R₂, substituents R″ and R₃, and substituents R″ and R₄, can be joined to form a ring. Obviously, it is also possible that none of these substituents are joined to form a ring.

According to an embodiment of the present disclosure, the ring A₁ to the ring A₄ are, at each occurrence identically or differently, selected from an aromatic ring having 6 to 18 ring atoms, a heteroaromatic ring having 5 to 18 ring atoms or a combination thereof.

According to an embodiment of the present disclosure, one or two of the ring A₁ to the ring A₄ includes a 5-membered heteroaromatic ring structure, and the remainder of the ring A, to the ring A₄ is selected from an aromatic ring having 6 ring atoms or a heteroaromatic ring having 6 ring atoms.

According to an embodiment of the present disclosure, the ring A₁ and the ring A₃ are selected from an aromatic ring having 6 ring atoms, the ring A₂ is selected from a heteroaromatic ring having 9 ring atoms, and the ring A₄ is selected from a heteroaromatic ring having 6 ring atoms.

According to an embodiment of the present disclosure, the ring A₁ to the ring A₄ are, at each occurrence identically or differently, selected from the group consisting of: a pyrrole ring, a furan ring, a thiophene ring, a selenophene ring, an imidazole ring, an imidazole-carbene ring, an oxazole ring, a thiazole ring, a selenazole ring, a benzene ring, a pyridine ring, a pyrimidine ring, a pyrazine ring, a pyridazine ring, a triazine ring, a benzopyrrole ring, a benzofuran ring, a benzothiophene ring, a benzoselenophene ring, a benzimidazole ring, a benzimidazole-carbene ring, a benzoxazole ring, a benzothiazole ring, a benzoselenazole ring, a fluorene ring, a carbazole ring, a dibenzofuran ring, a dibenzothiophene ring, a dibenzoselenophene ring, an azafluorene ring, an azacarbazole ring, an azadibenzofuran ring, an azadibenzothiophene ring, an azadibenzoselenophene ring, and combinations thereof.

According to an embodiment of the present disclosure, the ring A₁ and the ring A₃ are selected from a benzene ring, the ring A₂ is selected from a benzimidazole ring, and the ring A₄ is selected from a pyridine ring.

According to an embodiment of the present disclosure, the ring A₁ is selected from a benzene ring, the ring A₂ is selected from a benzimidazole ring, the ring A₃ is selected from a dibenzofuran ring, and the ring A₄ is selected from a pyridine ring.

According to an embodiment of the present disclosure, L₁ to L₄ are, at each occurrence identically or differently, selected from a single bond, NR′, O or S.

According to an embodiment of the present disclosure, a₂ to a₄ are, at each occurrence identically or differently, selected from 0 or 1, and at least two of a₂ to a₄ are selected from 1.

According to an embodiment of the present disclosure, a₄ is selected from 0, and a₂ to as are selected from 1; L₁ to L₃ are, at each occurrence, selected from a single bond.

According to an embodiment of the present disclosure, G₁ to G₄ are, at each occurrence identically or differently, selected from a single bond, O. S or NR″, and at least two of G₁ to G₄ are selected from a single bond.

According to an embodiment of the present disclosure, G₁ to G₄ are, at each occurrence identically or differently, selected from a single bond, O, S or NR″, and at least three of G₁ to G₄ are selected from a single bond.

According to an embodiment of the present disclosure, G₁ is selected from O, and G₂ to G₄ are, at each occurrence identically or differently, selected from a single bond.

According to an embodiment of the present disclosure, the metal complex has a structure represented by Formula M-b-1:

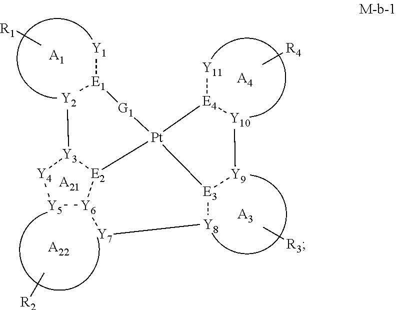

wherein,
the ring A₁, the ring A₂₂, the ring A₃, and the ring A₄ are, at each occurrence identically or differently, selected from an aromatic ring having 6 to 30 ring atoms, a heteroaromatic ring having 5 to 30 ring atoms or a combination thereof;
the ring A₂₁ is selected from a heteroaromatic ring having 5 ring atoms;
E₁ to E₄ are, at each occurrence identically or differently, selected from C or N;
G₁ is, at each occurrence identically or differently, selected from O or S;
Y₁, Y₄, and Y₁₁ are, at each occurrence identically or differently, selected from CR″′, N, NR′″, O or S;
Y₂, Y₃, and Y₅ to Y₁₀ are, at each occurrence identically or differently, selected from C or N;
R₁ to R₄ represent, at each occurrence identically or differently, mono-substitution, multiple substitutions or non-substitution;
R₁ to R₄ and R″′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ to R₄ and R″′ can be optionally joined to form a ring.

In this embodiment, the expression that “adjacent substituents R₁ to R₄ and R″′ can be optionally joined to form a ring” is intended to mean that any one or more of groups of adjacent substituents, such as two substituents R₁, two substituents R₂, two substituents R₃, two substituents R₄, two substituents R″′, substituents R₁ and R₂, substituents R₁ and R₄, substituents R₂ and R₃, substituents R₃ and R₄, substituents R″′ and R₁, substituents R′″ and R₂, substituents R″′ and R₃, and substituents R′″ and R₄, can be joined to form a ring. Obviously, it is also possible that none of these substituents are joined to form a ring.

According to an embodiment of the present disclosure, G₁ is selected from O, E₁ and E₃ are selected from C, and E₂ and E₄ are selected from N.

According to an embodiment of the present disclosure, in M-b-1, the ring A₁, the ring A₂₂, the ring A₃, and the ring A₄ are, at each occurrence identically or differently, selected from an aromatic ring having 6 to 18 ring atoms, a heteroaromatic ring having 5 to 18 ring atoms or a combination thereof; the ring A₂₁ is, at each occurrence identically or differently, selected from a heteroaromatic ring having 5 ring atoms.

According to an embodiment of the present disclosure, in M-b-1, the ring A₁, the ring A₂₂, and the ring A₃ are selected from a benzene ring, the ring A₄ is selected from a pyridine ring, and the ring A₂₁ is selected from an imidazole ring.

According to an embodiment of the present disclosure, in M-b-1, the ring A₁ and the ring A₂₂ are selected from a benzene ring, the ring A₃ is selected from a dibenzofuran ring, the ring A₄ is selected from a pyridine ring, and the ring A₂₁ is selected from an imidazole ring.

According to an embodiment of the present disclosure, in Formula M-b-1, Y₂, Y₃, and Y₅ to Y₁₀ are, at each occurrence identically or differently, selected from C; Y₁ and Y₁₁ are, at each occurrence identically or differently, selected from CR″′, and R″′ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group, and combinations thereof.

According to an embodiment of the present disclosure, the metal complex has a structure represented by Formula M-b-2:

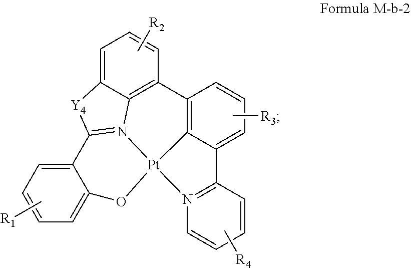

wherein in Formula M-b-2,
Y₄ is, at each occurrence identically or differently, selected from NR″′, O or S;
R₁ to R₄ represent, at each occurrence identically or differently, mono-substitution, multiple substitutions or non-substitution,
R₁ to R₄ and R″′ are, at each occurrence identically or differently, selected from the group consisting of; hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ to R₄ and R″′ can be optionally joined to form a ring.

According to an embodiment of the present disclosure, in Formula M-b-1 and Formula M-b-2, Y₄ is, at each occurrence identically or differently, selected from NR′″. O or S; R′″ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, in Formula M-b-1 and Formula M-b-2, Y₄ is, at each occurrence identically or differently, selected from NR″′, and R″′ is, at each occurrence identically or differently, selected from substituted or unsubstituted aryl having 6 to 30 carbon atoms, substituted or unsubstituted heteroaryl having 3 to 30 carbon atoms or a combination thereof.

According to an embodiment of the present disclosure, R₁ to R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, a hydroxyl group, a sulfanyl group, and combinations thereof.

According to an embodiment of the present disclosure, at least one R₁, at least one R₂, at least one R₃ or at least one R₄ is, at each occurrence identically or differently, selected from deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group or a combination thereof.

According to an embodiment of the present disclosure, the metal complex is selected from the group consisting of M-a1 to M-a64 and M-b1 to M-b62, wherein the specific structures of M-a1 to M-a64 and M-b1 to M-b62 are referred to claim 20.

According to an embodiment of the present disclosure, the metal complex is selected from the group consisting of M-a65 to M-a92, wherein the specific structures of M-a65 to M-a92 are as follows:

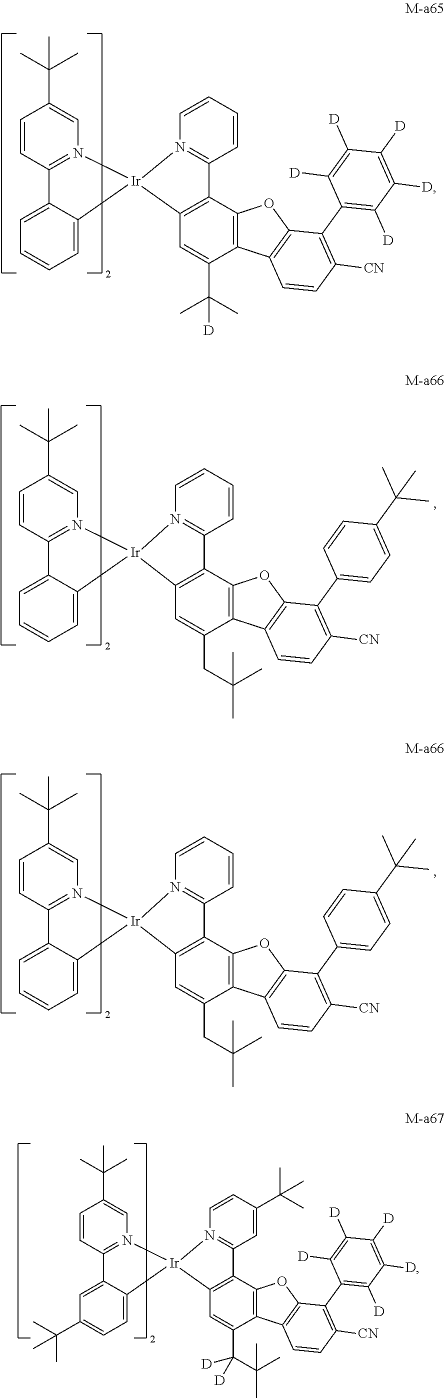

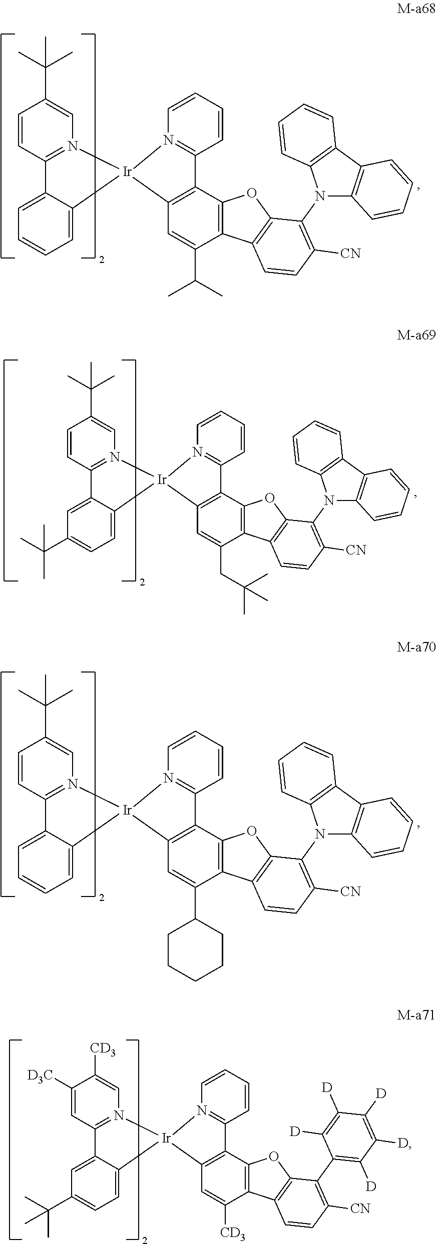

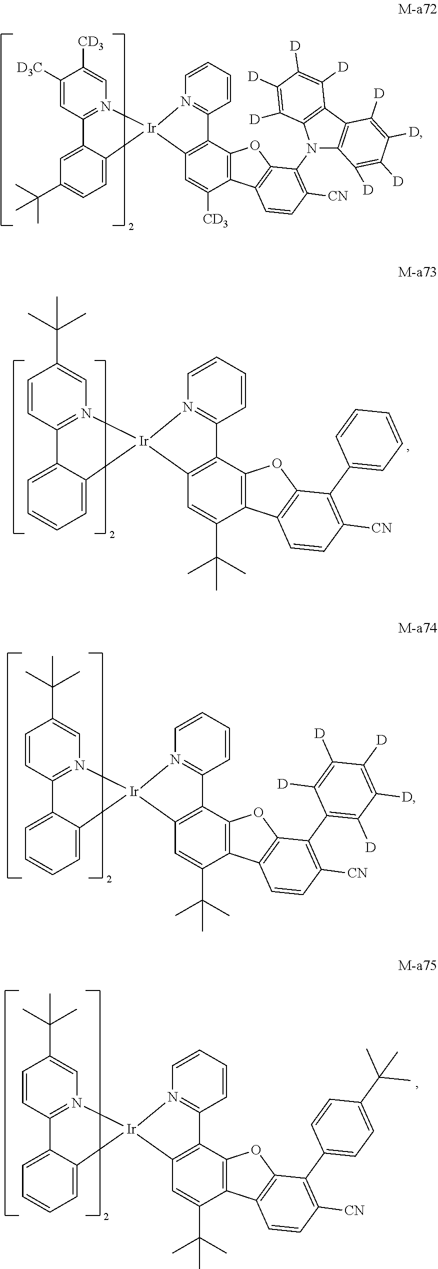

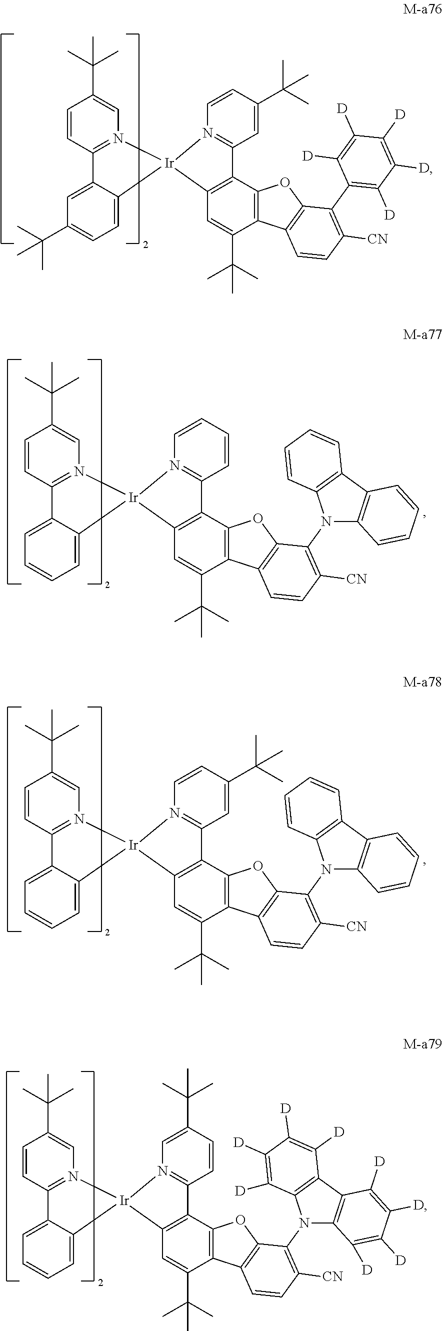

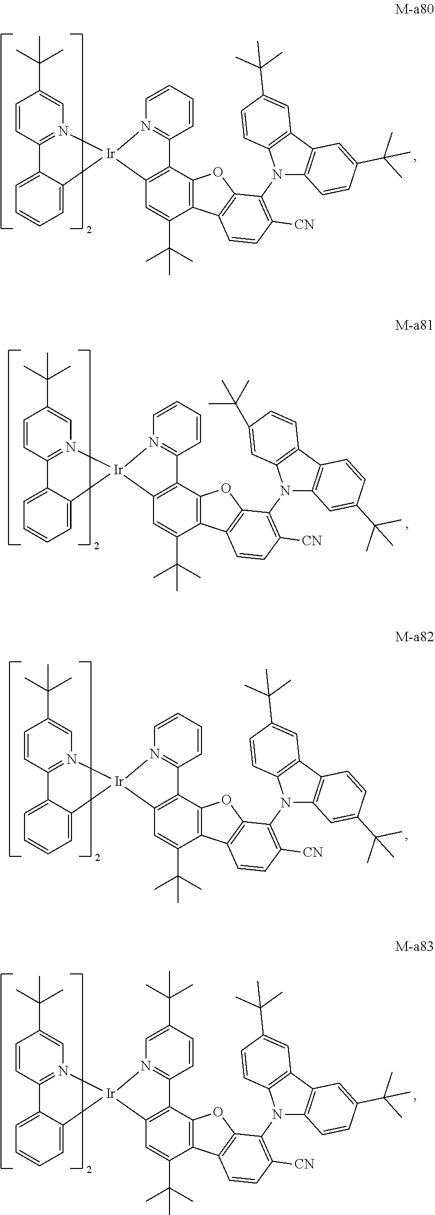

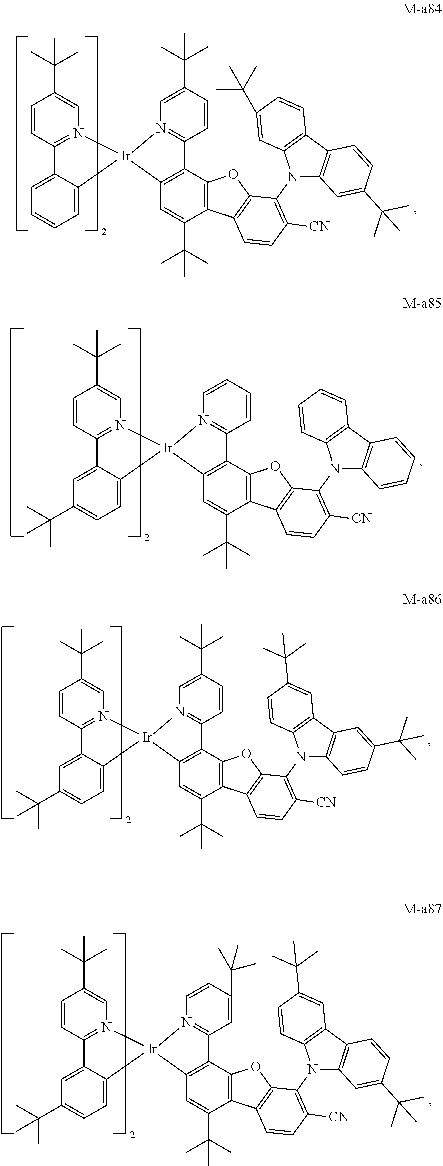

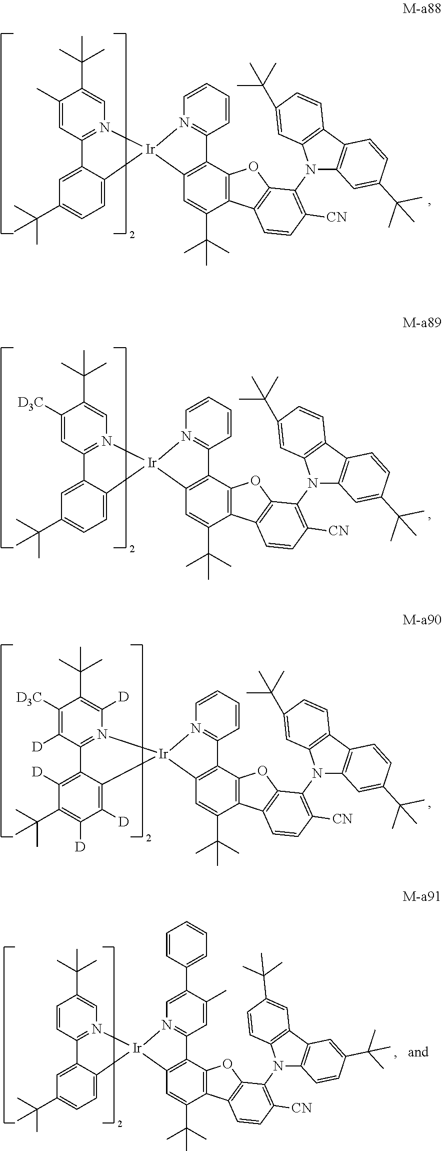

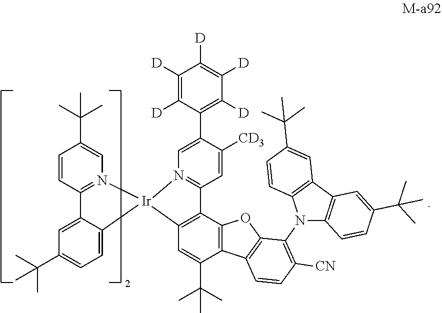

According to an embodiment of the present disclosure, the maximum emission wavelength in the photoluminescence spectrum of the fluorescent emissive material is λₘₐₓ₂, and 500 nm≤λₘₐₓ₂≤600 nm.

According to an embodiment of the present disclosure, the maximum emission wavelength in the photoluminescence spectrum of the fluorescent emissive material is λₘₐₓ₂, and 510 nm≤λₘₐₓ₂≤560 nm.

According to an embodiment of the present disclosure, the maximum emission wavelength in the photoluminescence spectrum of the metal complex is λₘₐₓ₁, the maximum emission wavelength in the photoluminescence spectrum of the fluorescent emissive material is λₘₐₓ₂, and λₘₐₓ₁≤λₘₐₓ₂ or 0 nm<λₘₐₓ₁−λₘₐₓ₂≤30 nm.

According to an embodiment of the present disclosure, λₘₐₓ₁−λₘₐₓ₂≤20 nm.

According to an embodiment of the present disclosure, λₘₐₓ₂−λₘₐₓ₁≤40 nm.

According to an embodiment of the present disclosure, λₘₐₓ₂−λₘₐₓ₁≤30 nm.

According to an embodiment of the present disclosure, λₘₐₓ₂−λₘₐₓ₁≤10 nm.

According to an embodiment of the present disclosure, 10 nm≤λₘₐₓ₂−λₘₐₓ₁≤30 nm.

According to an embodiment of the present disclosure, 0 nm<λₘₐₓ₁−λₘₐₓ₂≤20 nm.

According to an embodiment of the present disclosure, 0 nm<λₘₐₓ₁−λₘₐₓ₂≤10 nm.

According to an embodiment of the present disclosure, the weight of the fluorescent emissive material in an emissive layer of the organic electroluminescent device accounts for 0.01% to 5% of the total weight of the emissive layer.

According to an embodiment of the present disclosure, the weight of the fluorescent emissive material in the emissive layer of the organic electroluminescent device accounts for 0.05% to 3% of the total weight of the emissive layer.

According to an embodiment of the present disclosure, the weight of the fluorescent emissive material in the emissive layer of the organic electroluminescent device accounts for 0.1% to 1% of the total weight of the emissive layer.

According to an embodiment of the present disclosure, the full width at half maximum FWHM2 of the fluorescent emissive material of the organic electroluminescent device is less than or equal to 60 nm.

According to an embodiment of the present disclosure, the full width at half maximum FWHM2 of the fluorescent emissive material of the organic electroluminescent device is less than or equal to 50 nm.

According to an embodiment of the present disclosure, the full width at half maximum FWHM2 of the fluorescent emissive material of the organic electroluminescent device is less than or equal to 40 nm.

According to an embodiment of the present disclosure, the triplet energy level of the metal complex is T_{1(Emt1)}, and the triplet energy level of the fluorescent emissive material is T_{1(Emt2)}, wherein T_{1(Emt1)}>T_{1(Emt2)}.

According to an embodiment of the present disclosure, the triplet energy level of the first host compound is T₁₍ₕₒₛₜ₁₎, wherein T₁₍ₕₒₛₜ₁₎>T_{1(Emt1)}, and T₁₍ₕₒₛₜ₁₎>T_{1(Emt2)}.

According to an embodiment of the present disclosure, the triplet energy level of the first host compound is T₁₍ₕₒₛₜ₁₎, wherein T₁₍ₕₒₛₜ₁₎>T_{1(Emt1)}.

In embodiments of the present disclosure, the expression “T₁₍ₕₒₛₜ₁₎>T_{1(Emt1)}” represents that the triplet energy level of the first host compound is higher than the triplet energy level of the metal complex.

According to an embodiment of the present disclosure, T₁₍ₕₒₛₜ₁₎>T_{1(Emt1)}>T_{1(Emt2)}.

According to an embodiment of the present disclosure, the organic layer further includes a second host compound, the triplet energy level of the second host compound is T₁₍ₕₒₛₜ₂₎, T₁₍ₕₒₛₜ₂₎>T_{1(Emt1)}, and T₁₍ₕₒₛₜ₂₎>T_{1(Emt2)}.

According to an embodiment of the present disclosure, T₁₍ₕₒₛₜ₂₎>T_{1(Emt1)}>T_{1(Emt2)}.

According to an embodiment of the present disclosure, T₁₍ₕₒₛₜ₁₎>T₁₍ₕₒₛₜ₂₎>T_{1(Emt1)}>T_{1(Emt2)}.

According to an embodiment of the present disclosure, the organic electroluminescent device uses the fluorescent emissive material as a main light-emitting source.

According to an embodiment of the present disclosure, the fluorescent emissive material is a terminal emissive material of the organic electroluminescent device.

According to an embodiment of the present disclosure, the fluorescent emissive material is a delayed fluorescence material.

According to an embodiment of the present disclosure, the fluorescent emissive material is a thermally activated delayed fluorescence (TADF) material.

According to an embodiment of the present disclosure, the fluorescent emissive material is one material or a plurality of different materials.

According to an embodiment of the present disclosure, the organic electroluminescent device emits fluorescence.

According to an embodiment of the present disclosure, the organic electroluminescent device emits delayed fluorescence.

According to an embodiment of the present disclosure, the organic layer is an emissive layer.

According to an embodiment of the present disclosure, the emissive layer does not include a polymer.

According to an embodiment of the present disclosure, the electroluminescent device does not undergo post-polymerization during the preparation process.

According to another embodiment of the present disclosure, the first host compound has a structure represented by Formula X-1 or Formula X-2:

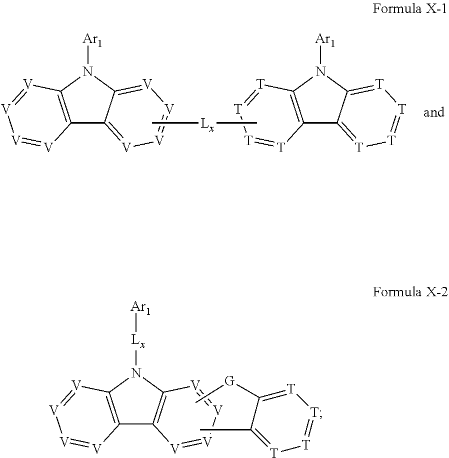

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
G is, at each occurrence identically or differently, selected from C(R_{g})₂, NR_{g}, O or S; when a plurality of R_{g} are present at the same time, the plurality of R_{g} are the same or different;
V is, at each occurrence identically or differently, selected from C, CRᵥ or N;
in Formula X-1, T is, at each occurrence identically or differently, selected from C, CR_{T} or N;
in Formula X-2, T is, at each occurrence identically or differently, selected from CR_{T} or N;
R_{g}, Rᵥ, and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof;
adjacent substituents R_{g}, Rᵥ, and R_{T} can be optionally joined to form a ring.

In this embodiment, the expression that “adjacent substituents R_{g}, Rᵥ, and R_{T} can be optionally joined to form a ring” is intended to mean that any one or more of groups of adjacent substituents, such as two substituents Rᵥ, two substituents R_{T}, two substituents R_{g}, substituents Rᵥ and R_{T}, substituents Rᵥ and R_{g}, and substituents R_{g} and R_{T}, can be joined to form a ring. Obviously, it is also possible that none of these substituents are joined to form a ring.

According to an embodiment of the present disclosure, the first host compound has a structure represented by one of Formula X-a to Formula X-p:

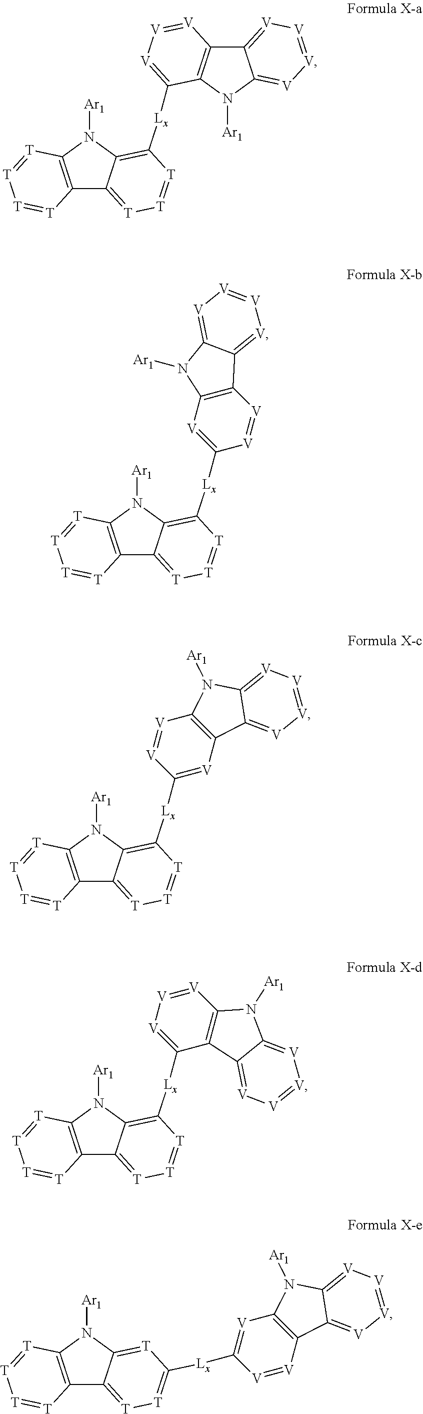

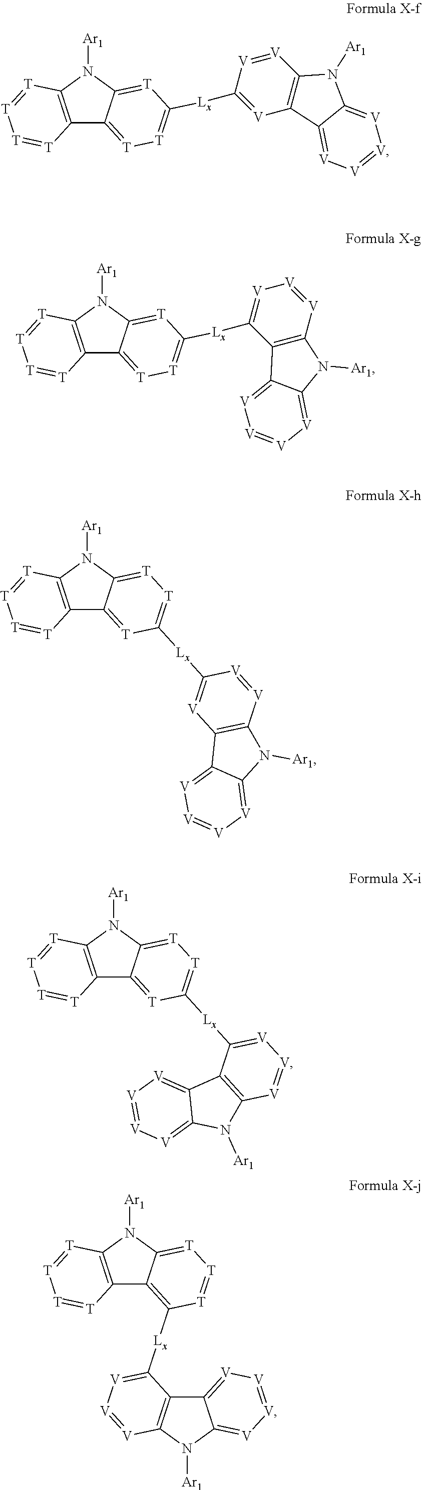

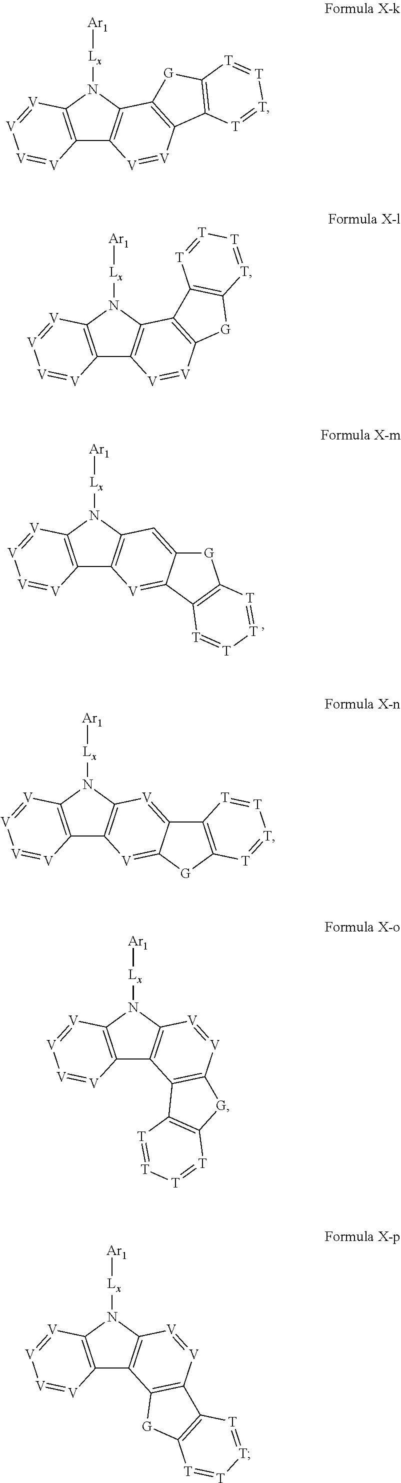

wherein
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
G is, at each occurrence identically or differently, selected from C(R_{g})₂, NR_{g}, O or S; when a plurality of R_{g} are present at the same time, the plurality of R_{g} are the same or different;
V is, at each occurrence identically or differently, selected from CRᵥ or N;
T is, at each occurrence identically or differently, selected from CR_{T} or N;
R_{g}, Rᵥ, and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof;
adjacent substituents R_{g}, Rᵥ, and R_{T} can be optionally joined to form a ring.

According to an embodiment of the present disclosure, the first host compound is selected from the group consisting of the following compounds:

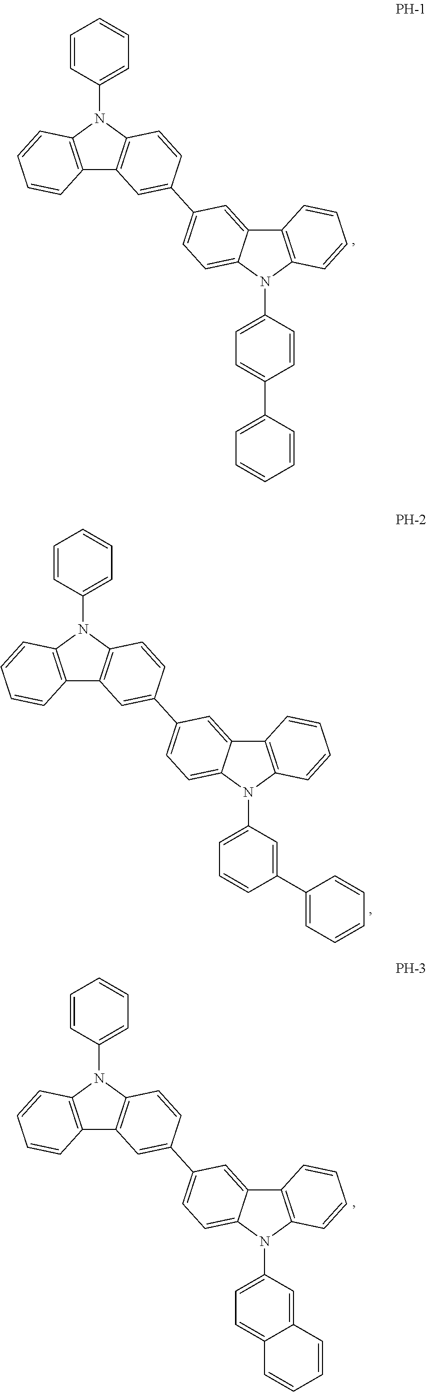 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1]

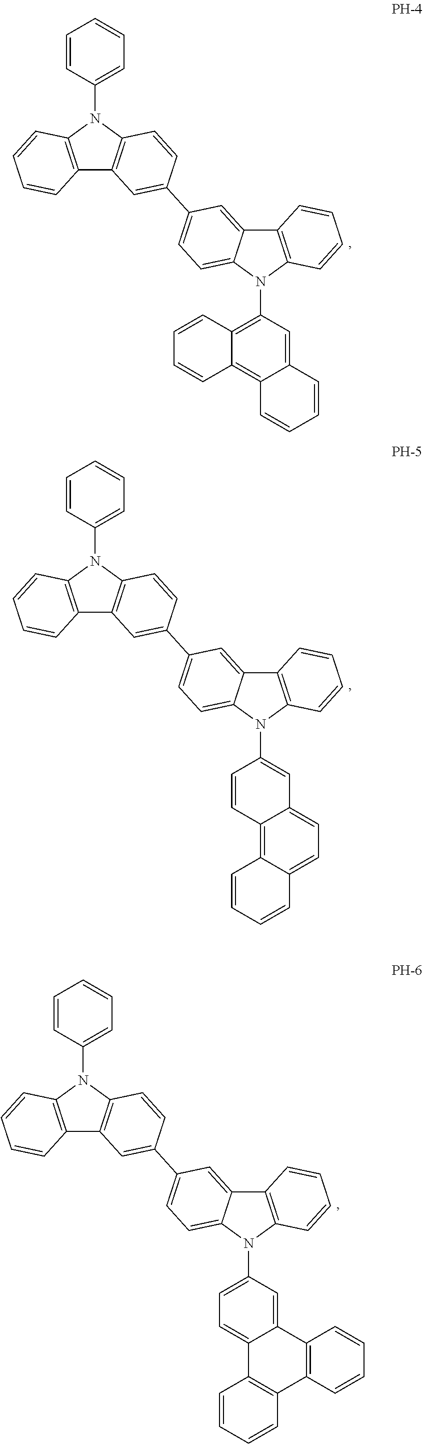 [SMILES: c1ccc(-n2c3ccccc3c3cc(-c4ccc5c(c4)c4ccccc4n5-c4cc5ccccc5c5ccccc45)ccc32)cc1 ; c1ccc(-n2c3ccccc3c3cc(-c4ccc5c(c4)c4ccccc4n5-c4ccc5c(ccc6ccccc65)c4)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

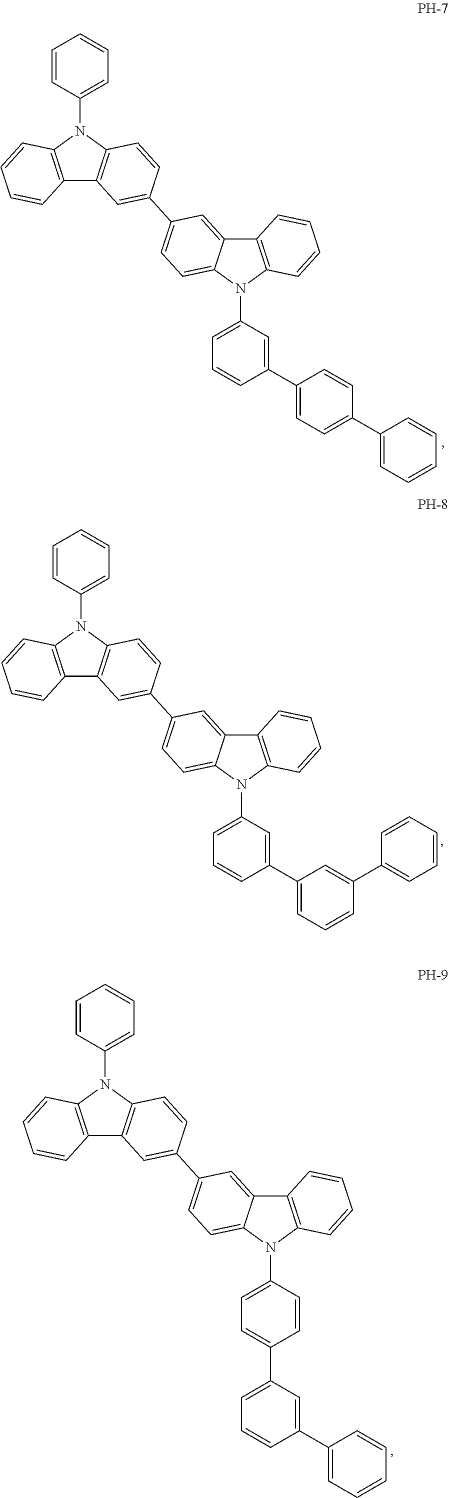 [SMILES: c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cccc(-c3ccc(-n4c5ccccc5c5cc(-c6ccc7c(c6)c6ccccc6n7-c6ccccc6)ccc54)cc3)c2)cc1]

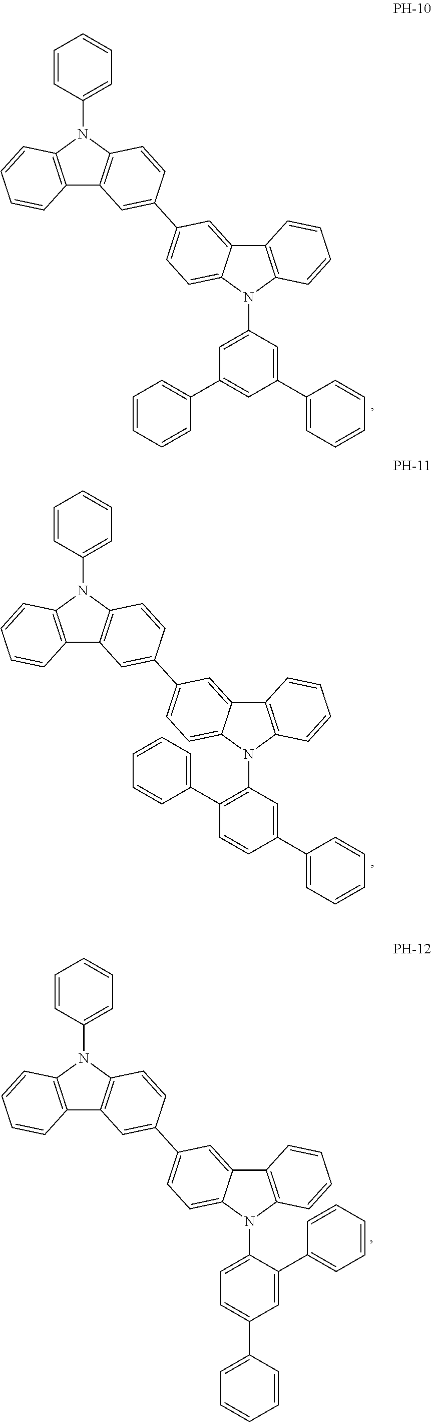 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1]

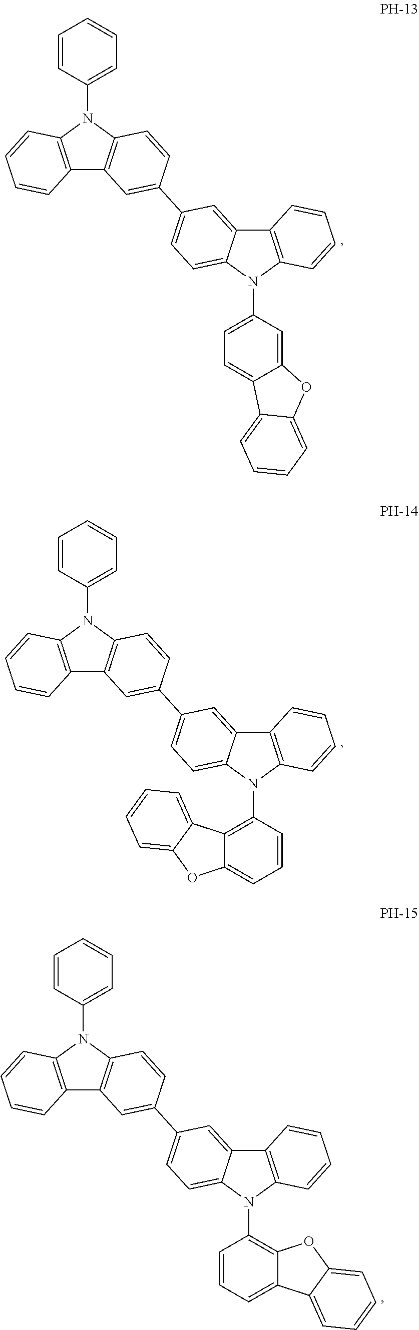 [SMILES: c1ccc(-n2c3ccccc3c3cc(-c4ccc5c(c4)c4ccccc4n5-c4ccc5c(c4)oc4ccccc45)ccc32)cc1 ; c1ccc(-n2c3ccccc3c3cc(-c4ccc5c(c4)c4ccccc4n5-c4cccc5oc6ccccc6c45)ccc32)cc1 ; c1ccc(-n2c3ccccc3c3cc(-c4ccc5c(c4)c4ccccc4n5-c4cccc5c4oc4ccccc45)ccc32)cc1]

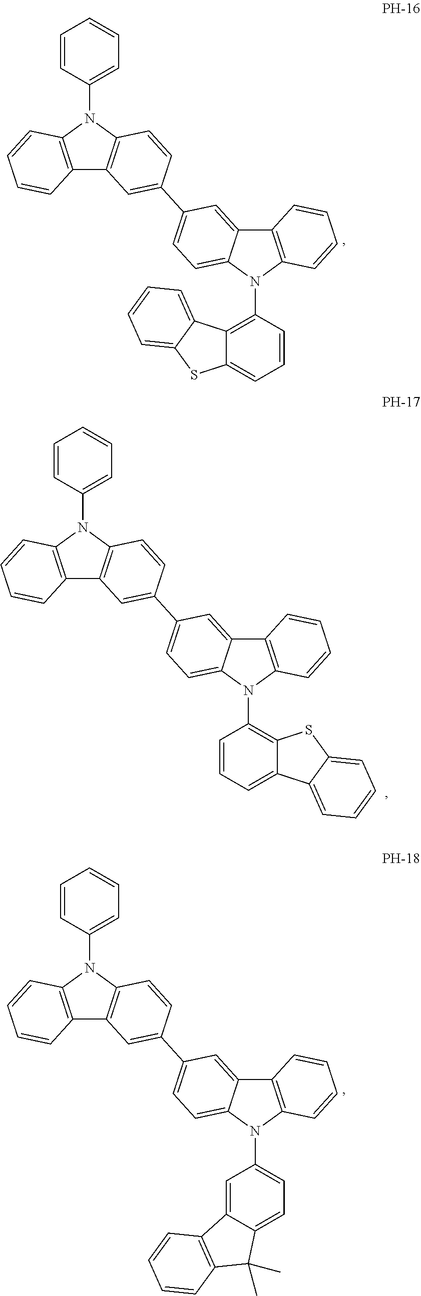 [SMILES: c1ccc(-n2c3ccccc3c3cc(-c4ccc5c(c4)c4ccccc4n5-c4cccc5sc6ccccc6c45)ccc32)cc1 ; c1ccc(-n2c3ccccc3c3cc(-c4ccc5c(c4)c4ccccc4n5-c4cccc5c4sc4ccccc45)ccc32)cc1 ; CC1(C)c2ccccc2-c2cc(-n3c4ccccc4c4cc(-c5ccc6c(c5)c5ccccc5n6-c5ccccc5)ccc43)ccc21]

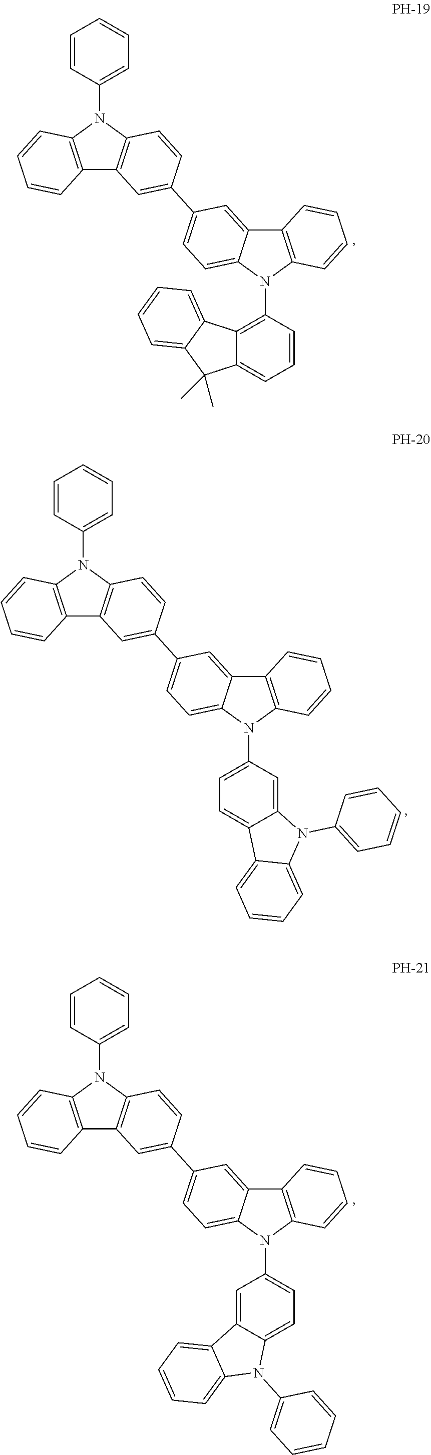 [SMILES: CC1(C)c2ccccc2-c2c(-n3c4ccccc4c4cc(-c5ccc6c(c5)c5ccccc5n6-c5ccccc5)ccc43)cccc21 ; c1ccc(-n2c3ccccc3c3cc(-c4ccc5c(c4)c4ccccc4n5-c4ccc5c6ccccc6n(-c6ccccc6)c5c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1]

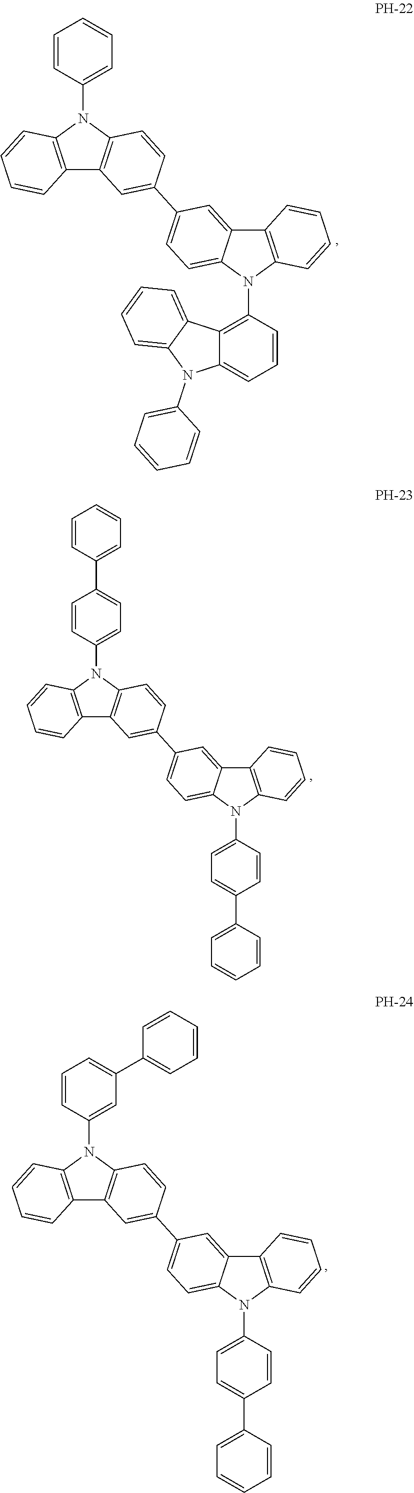 [SMILES: c1ccc(-n2c3ccccc3c3cc(-c4ccc5c(c4)c4ccccc4n5-c4cccc5c4c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

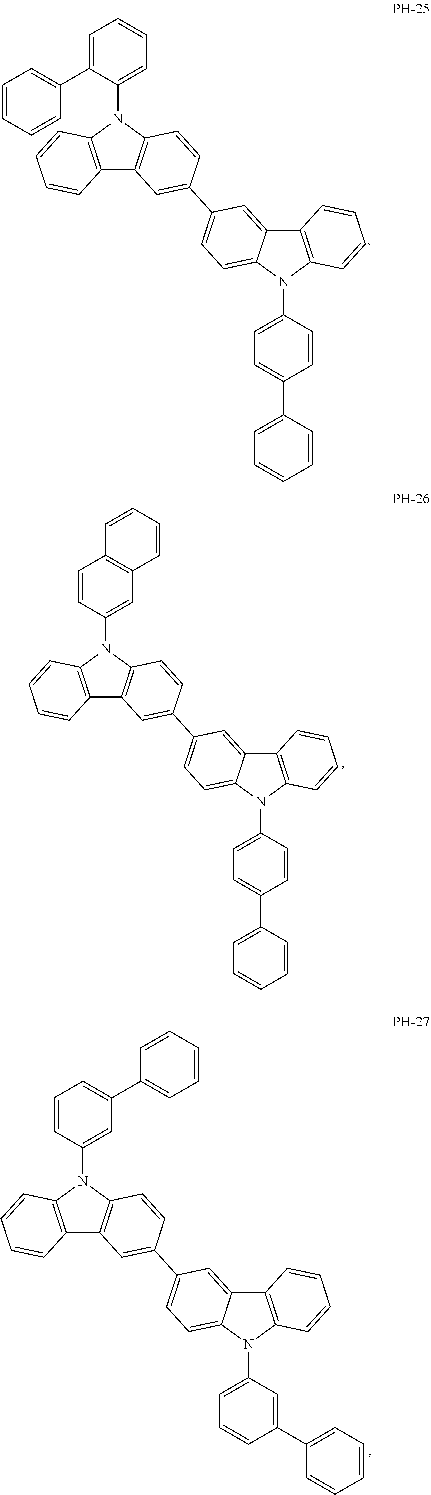 [SMILES: c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1]

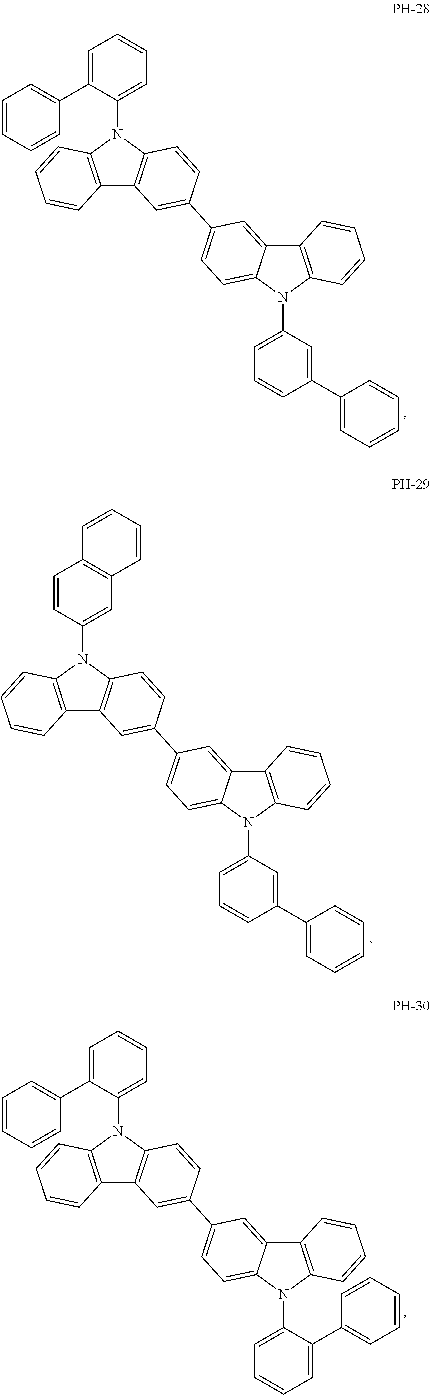 [SMILES: c1ccc(-c2cccc(-n3c4ccccc4c4cc(-c5ccc6c(c5)c5ccccc5n6-c5ccccc5-c5ccccc5)ccc43)c2)cc1 ; c1ccc(-c2cccc(-n3c4ccccc4c4cc(-c5ccc6c(c5)c5ccccc5n6-c5ccc6ccccc6c5)ccc43)c2)cc1 ; c1ccc(-c2ccccc2-n2c3ccccc3c3cc(-c4ccc5c(c4)c4ccccc4n5-c4ccccc4-c4ccccc4)ccc32)cc1]

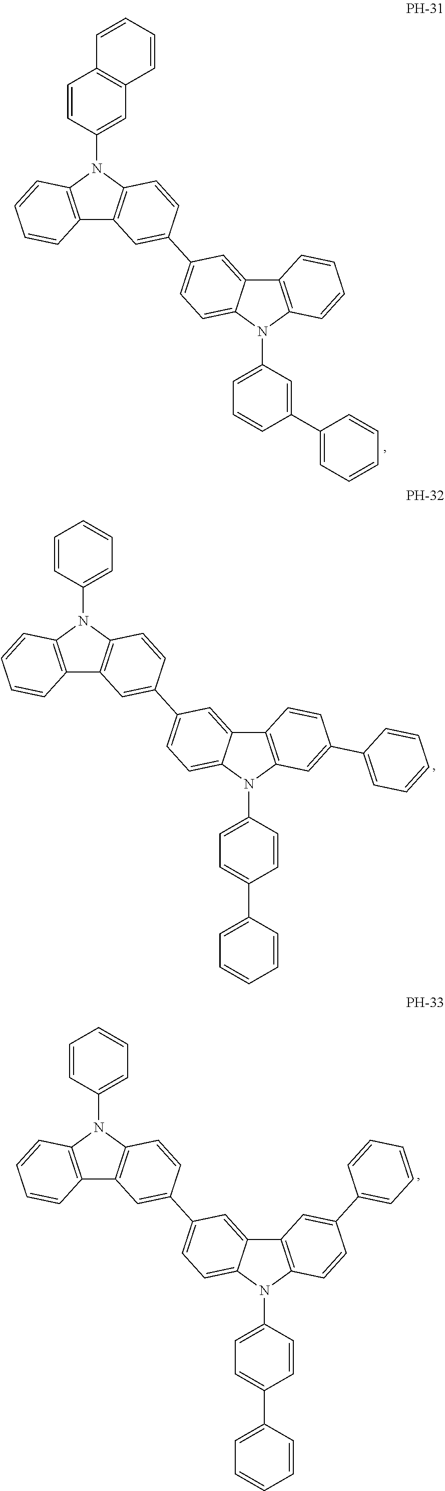 [SMILES: c1ccc(-c2cccc(-n3c4ccccc4c4cc(-c5ccc6c(c5)c5ccccc5n6-c5ccc6ccccc6c5)ccc43)c2)cc1 ; c1ccc(-c2ccc(-n3c4ccc(-c5ccc6c(c5)c5ccccc5n6-c5ccccc5)cc4c4ccc(-c5ccccc5)cc43)cc2)cc1 ; c1ccc(-c2ccc(-n3c4ccc(-c5ccccc5)cc4c4cc(-c5ccc6c(c5)c5ccccc5n6-c5ccccc5)ccc43)cc2)cc1]

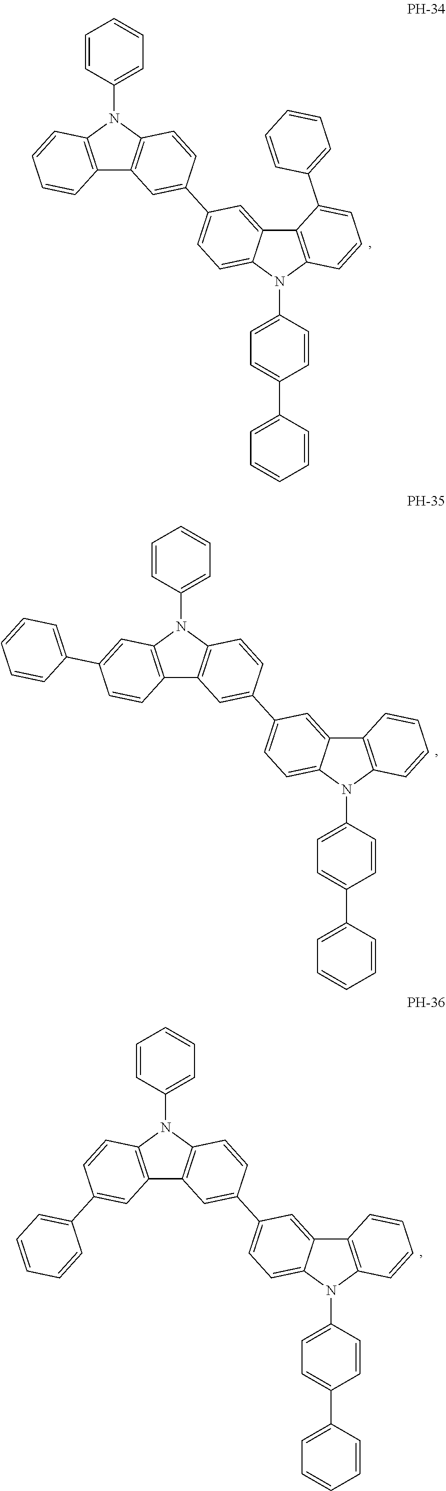 [SMILES: c1ccc(-c2ccc(-n3c4ccc(-c5ccc6c(c5)c5ccccc5n6-c5ccccc5)cc4c4c(-c5ccccc5)cccc43)cc2)cc1 ; c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc(-n3c4ccccc4c4cc(-c5ccc6c(c5)c5cc(-c7ccccc7)ccc5n6-c5ccccc5)ccc43)cc2)cc1]

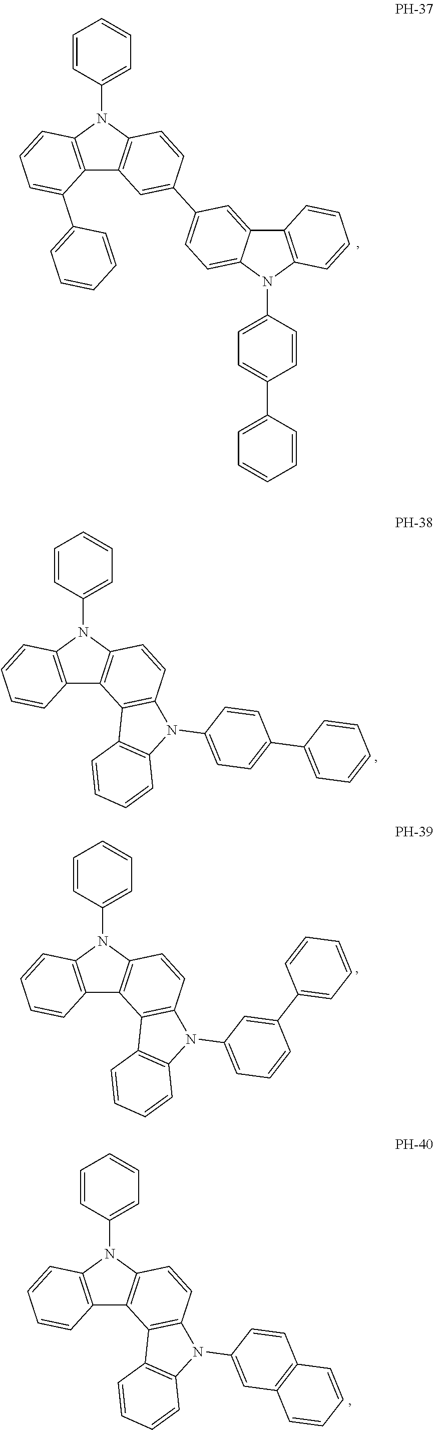

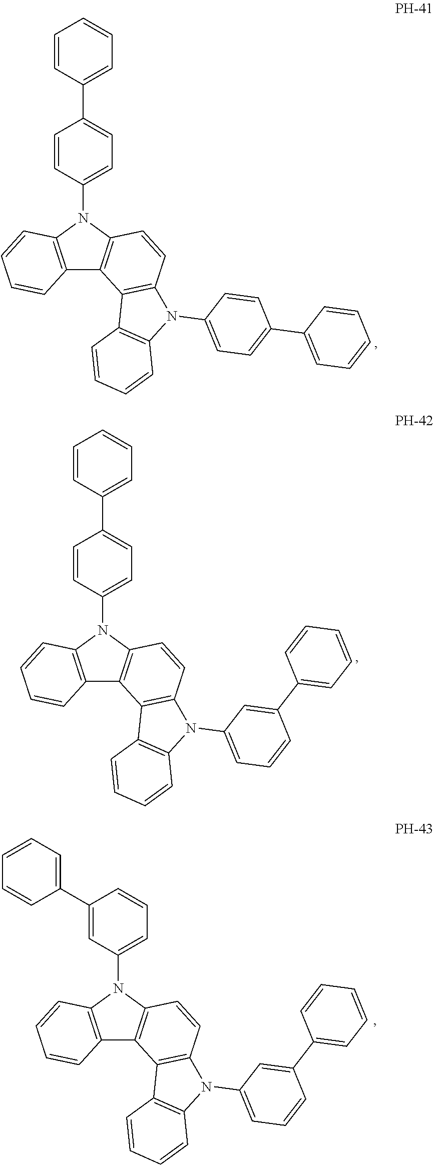

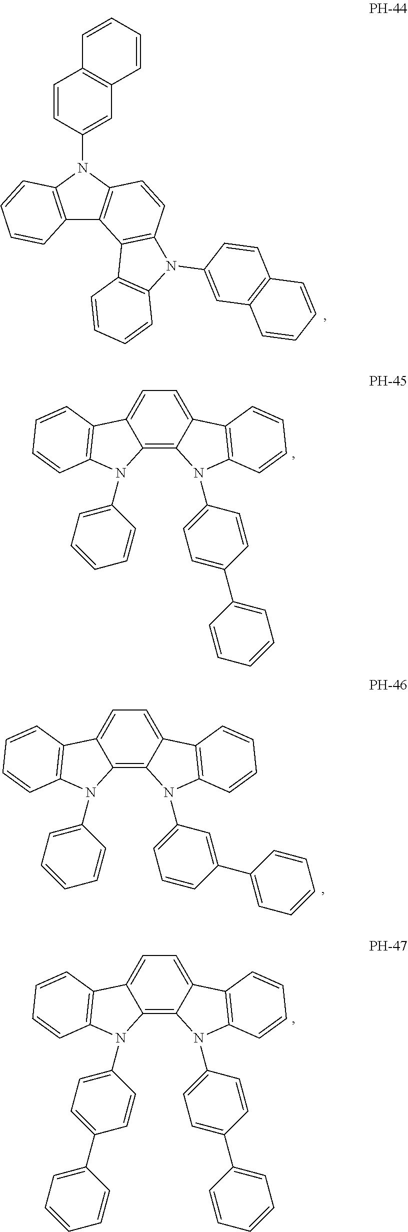 [SMILES: c1ccc2cc(-n3c4ccccc4c4c5c6ccccc6n(-c6ccc7ccccc7c6)c5ccc43)ccc2c1 ; c1ccc(-c2ccc(-n3c4ccccc4c4ccc5c6ccccc6n(-c6ccccc6)c5c43)cc2)cc1 ; c1ccc(-c2cccc(-n3c4ccccc4c4ccc5c6ccccc6n(-c6ccccc6)c5c43)c2)cc1 ; c1ccc(-c2ccc(-n3c4ccccc4c4ccc5c6ccccc6n(-c6ccc(-c7ccccc7)cc6)c5c43)cc2)cc1]

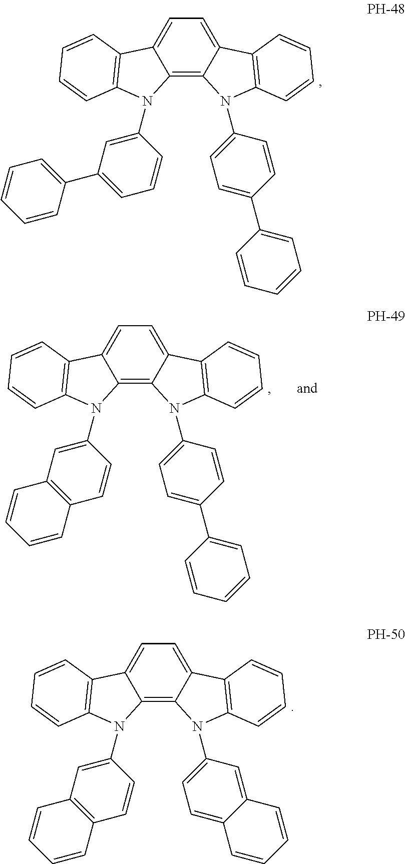 [SMILES: c1ccc(-c2ccc(-n3c4ccccc4c4ccc5c6ccccc6n(-c6cccc(-c7ccccc7)c6)c5c43)cc2)cc1 ; c1ccc(-c2ccc(-n3c4ccccc4c4ccc5c6ccccc6n(-c6ccc7ccccc7c6)c5c43)cc2)cc1 ; c1ccc2cc(-n3c4ccccc4c4ccc5c6ccccc6n(-c6ccc7ccccc7c6)c5c43)ccc2c1]

According to an embodiment of the present disclosure, the second host compound has a structure represented by Formula Y:

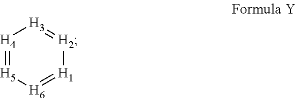

wherein,
H₁ to H₆ are, at each occurrence identically or differently, selected from C, CRₕ, or N, at least two of H₁ to H₆ are N, and at least one of H₁ to H₆ is C and joined to Formula A:

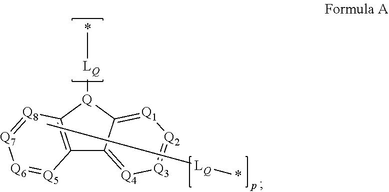

wherein,
Q is, at each occurrence identically or differently, selected from the group consisting of O, S. Se, N, NR_{Q}, CR_{Q}R_{Q}, SiR_{Q}R_{Q}, GeR_{Q}R_{Q}, and R_{Q}C═CR_{Q}; when two R_{Q} are present at the same time,
the two R_{Q} may be the same or different;
p is 0 or 1; r is 0 or 1.
when Q is selected from N, p is 0, and r is 1;
when Q is selected from the group consisting of O, S, Se, NR_{Q}, CR_{Q}R_{Q}, SiR_{Q}R_{Q}, GeR_{Q}R_{Q}, and R_{Q}C═CR_{Q}, p is 1, and r is 0;
L_{Q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
Q₁ to Q₈ are, at each occurrence identically or differently, selected from C, CR_{q} or N;
Rₕ, R_{Q}, and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
“*” represents a position where Formula A is joined to Formula Y;
adjacent substituents Rₕ, R_{Q}, and Rq can be optionally joined to form a ring.

In the present disclosure, the expression that “adjacent substituents Rₕ, R_{Q}, and R_{q} can be optionally joined to form a ring” is intended to mean that any one or more of groups of adjacent substituents, such as two substituents Rₕ, two substituents R_{Q}, two substituents R_{q}, and two substituents R_{Q} and R_{q}, can be joined to form a ring. Obviously, it is also possible that none of these substituents are joined to form a ring.

According to an embodiment of the present disclosure, the second host compound is selected from the group consisting of the following compounds:

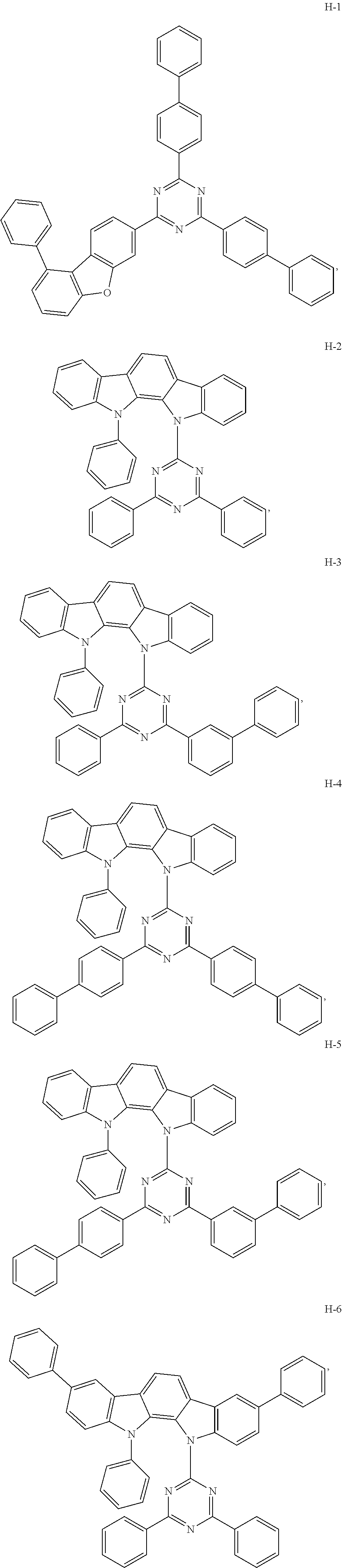

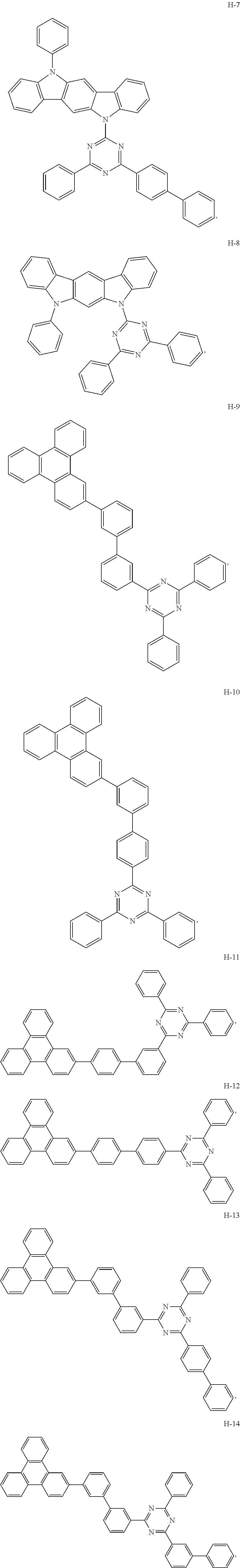

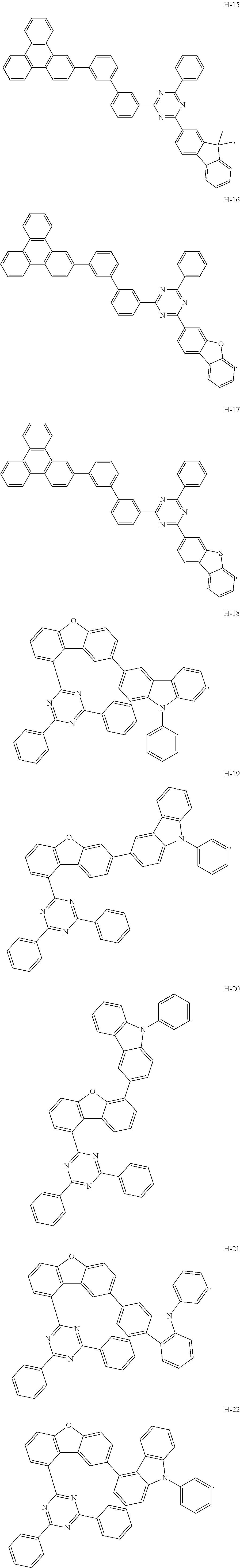

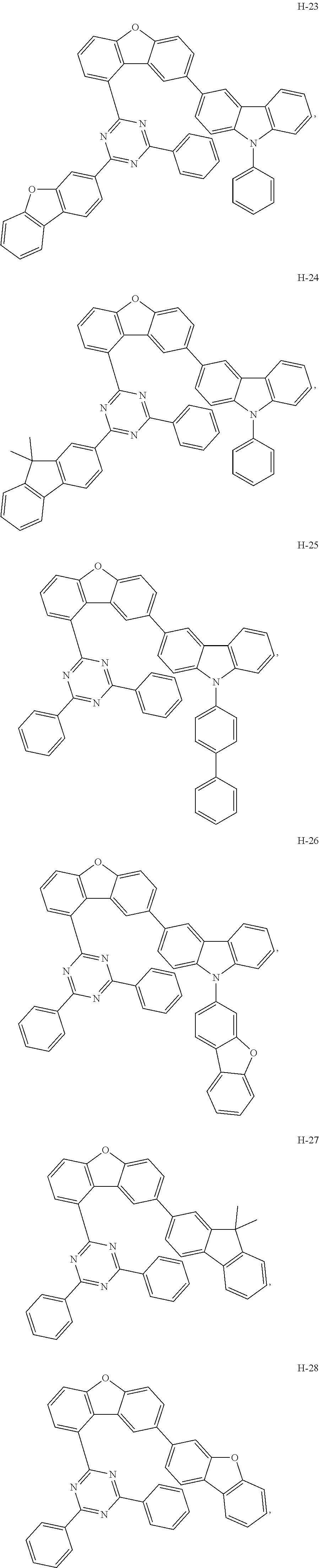

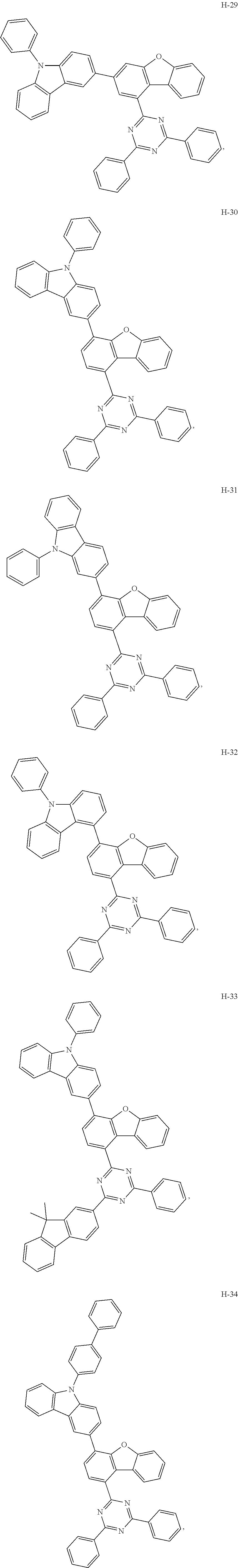

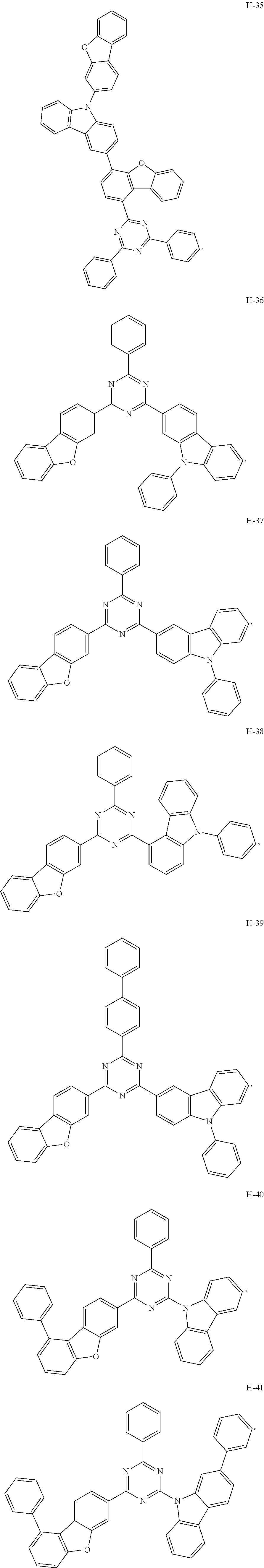

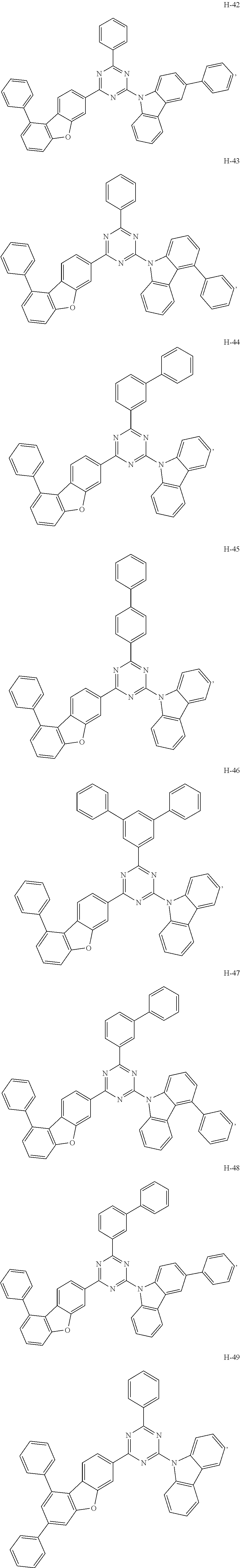

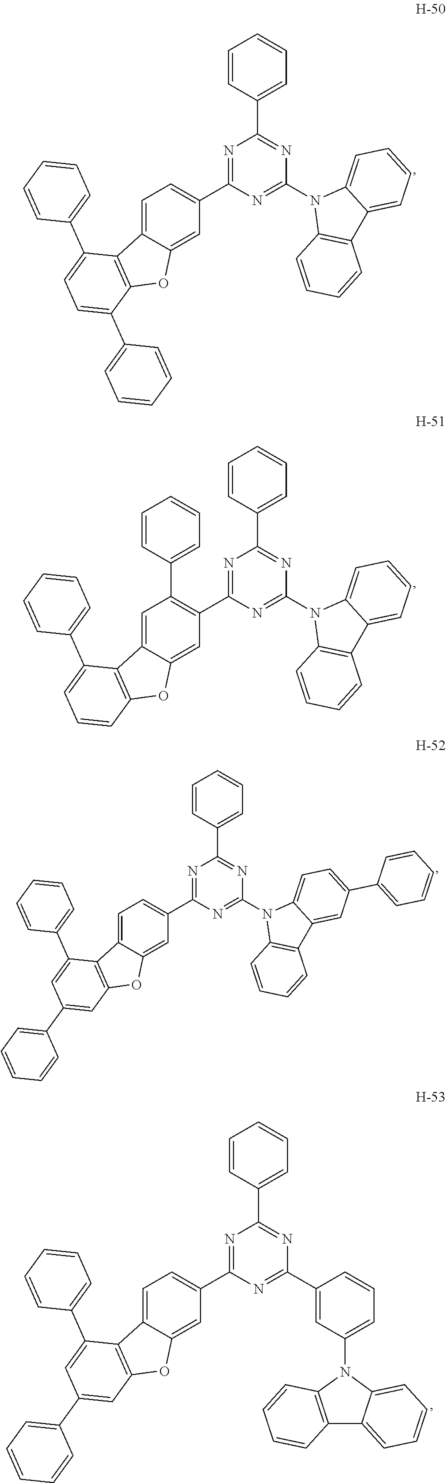 [SMILES: c1ccc(-c2nc(-c3ccc4c(c3)oc3c(-c5ccccc5)ccc(-c5ccccc5)c34)nc(-n3c4ccccc4c4ccccc43)n2)cc1 ; c1ccc(-c2nc(-c3cc4oc5cccc(-c6ccccc6)c5c4cc3-c3ccccc3)nc(-n3c4ccccc4c4ccccc43)n2)cc1 ; c1ccc(-c2cc(-c3ccccc3)c3c(c2)oc2cc(-c4nc(-c5ccccc5)nc(-n5c6ccccc6c6cc(-c7ccccc7)ccc65)n4)ccc23)cc1 ; c1ccc(-c2cc(-c3ccccc3)c3c(c2)oc2cc(-c4nc(-c5ccccc5)nc(-c5cccc(-n6c7ccccc7c7ccccc76)c5)n4)ccc23)cc1]

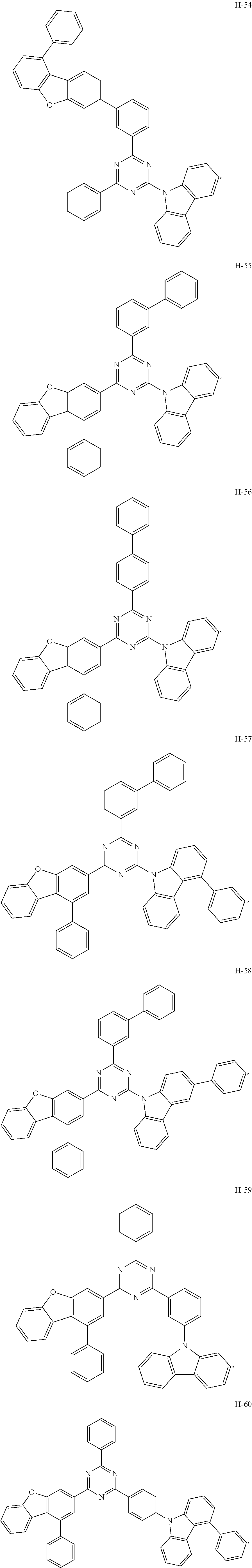

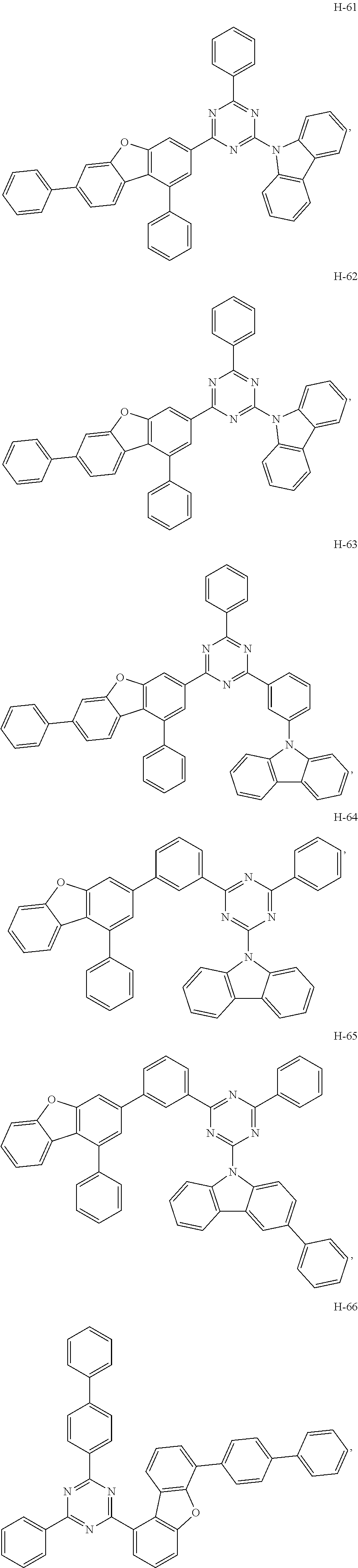

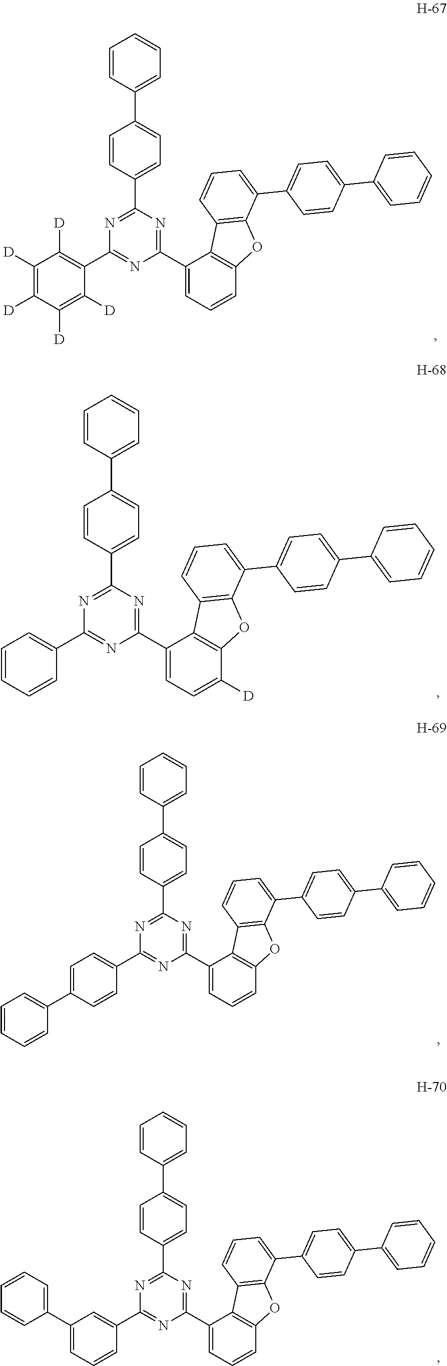 [SMILES: [2H]c1c([2H])c([2H])c(-c2nc(-c3ccc(-c4ccccc4)cc3)nc(-c3cccc4oc5c(-c6ccc(-c7ccccc7)cc6)cccc5c34)n2)c([2H])c1[2H] ; [2H]c1ccc(-c2nc(-c3ccccc3)nc(-c3ccc(-c4ccccc4)cc3)n2)c2c1oc1c(-c3ccc(-c4ccccc4)cc3)cccc12 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1]

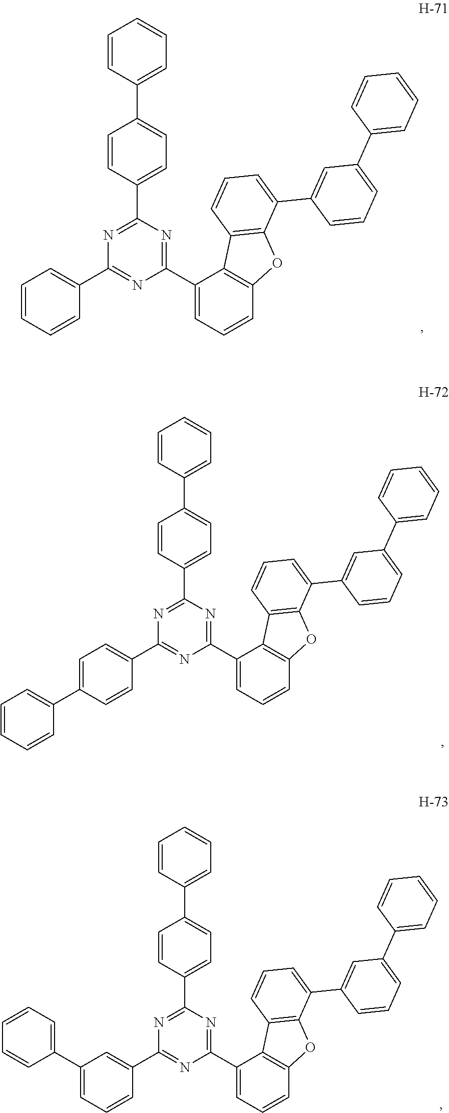 [SMILES: c1ccc(-c2ccc(-c3nc(-c4ccccc4)nc(-c4cccc5oc6c(-c7cccc(-c8ccccc8)c7)cccc6c45)n3)cc2)cc1 ; c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1 ; c1ccc(-c2ccc(-c3nc(-c4cccc(-c5ccccc5)c4)nc(-c4cccc5oc6c(-c7cccc(-c8ccccc8)c7)cccc6c45)n3)cc2)cc1]

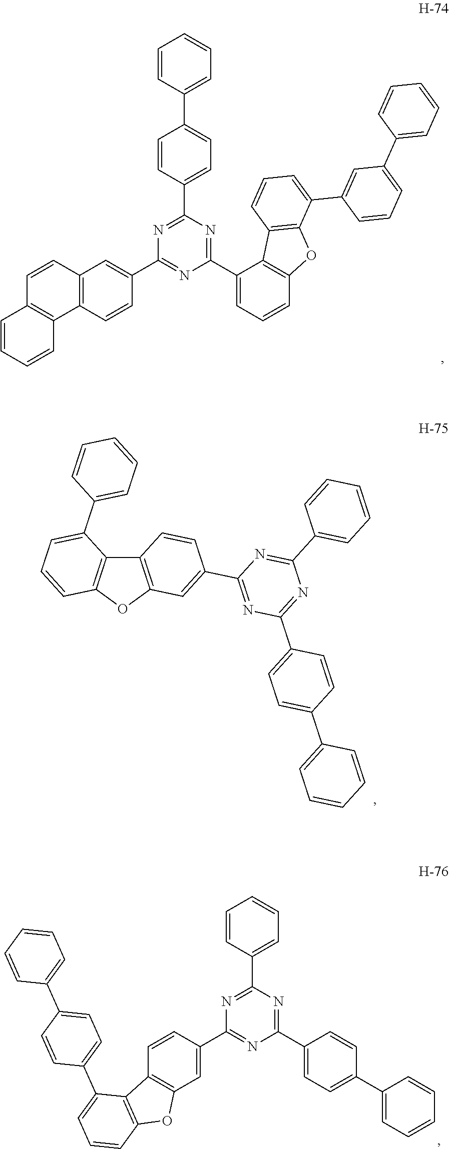 [SMILES: c1ccc(-c2ccc(-c3nc(-c4ccc5c(ccc6ccccc65)c4)nc(-c4cccc5oc6c(-c7cccc(-c8ccccc8)c7)cccc6c45)n3)cc2)cc1 ; c1ccc(-c2ccc(-c3nc(-c4ccccc4)nc(-c4ccc5c(c4)oc4cccc(-c6ccccc6)c45)n3)cc2)cc1 ; c1ccc(-c2ccc(-c3nc(-c4ccccc4)nc(-c4ccc5c(c4)oc4cccc(-c6ccc(-c7ccccc7)cc6)c45)n3)cc2)cc1]

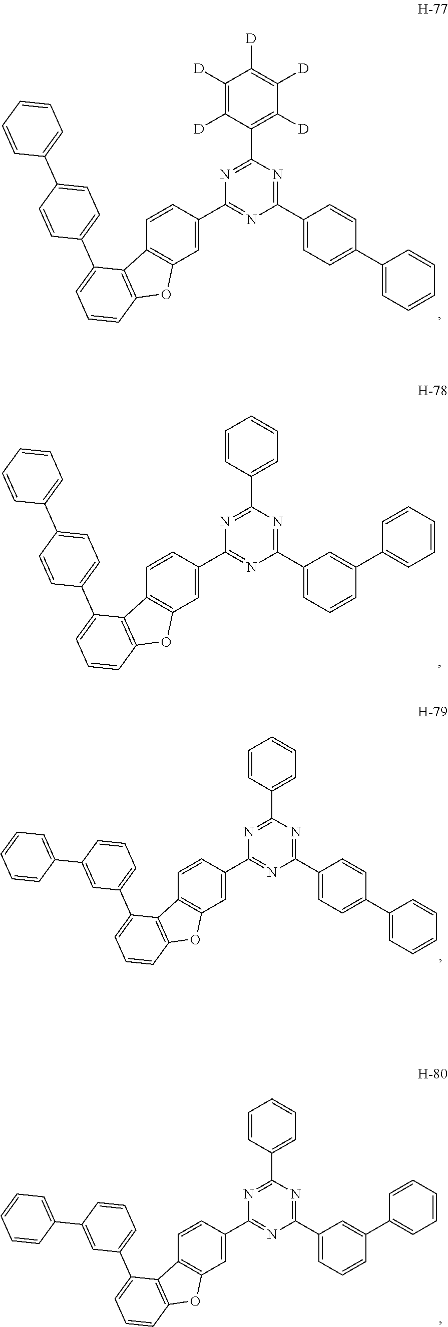 [SMILES: [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H] ; c1ccc(-c2ccc(-c3cccc4oc5cc(-c6nc(-c7ccccc7)nc(-c7cccc(-c8ccccc8)c7)n6)ccc5c34)cc2)cc1 ; c1ccc(-c2ccc(-c3nc(-c4ccccc4)nc(-c4ccc5c(c4)oc4cccc(-c6cccc(-c7ccccc7)c6)c45)n3)cc2)cc1 ; c1ccc(-c2cccc(-c3nc(-c4ccccc4)nc(-c4ccc5c(c4)oc4cccc(-c6cccc(-c7ccccc7)c6)c45)n3)c2)cc1]

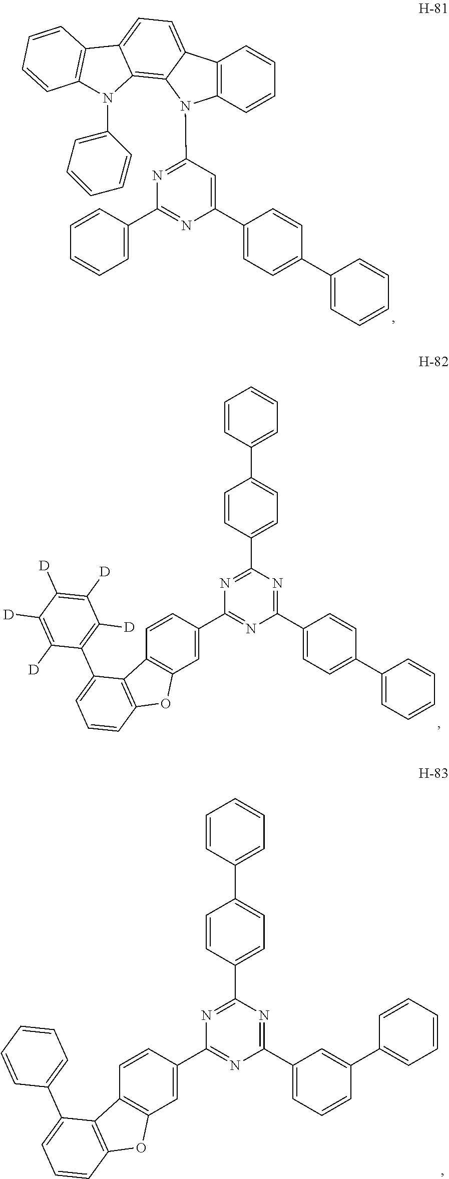 [SMILES: c1ccc(-c2ccc(-c3cc(-n4c5ccccc5c5ccc6c7ccccc7n(-c7ccccc7)c6c54)nc(-c4ccccc4)n3)cc2)cc1 ; [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H] ; c1ccc(-c2ccc(-c3nc(-c4cccc(-c5ccccc5)c4)nc(-c4ccc5c(c4)oc4cccc(-c6ccccc6)c45)n3)cc2)cc1]

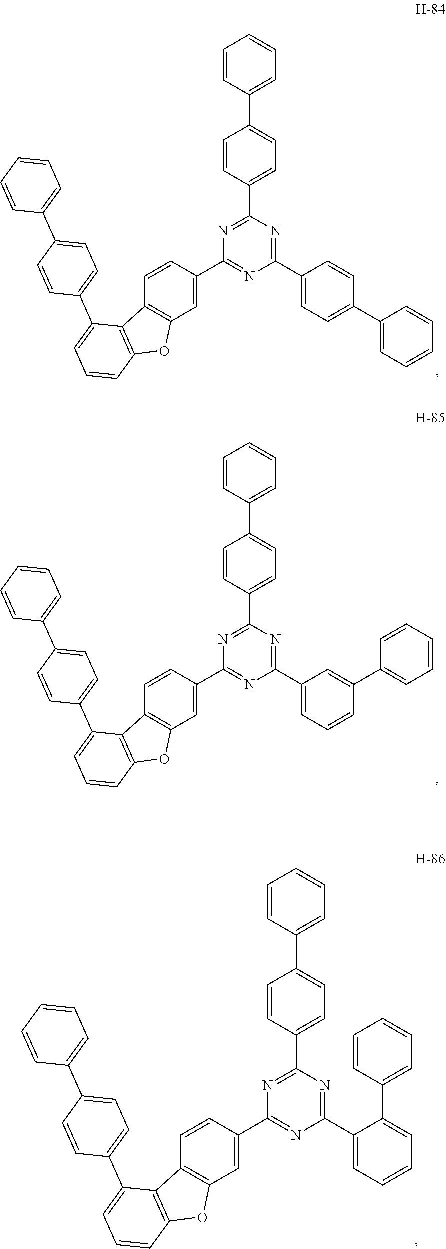 [SMILES: c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1 ; c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1 ; c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1]

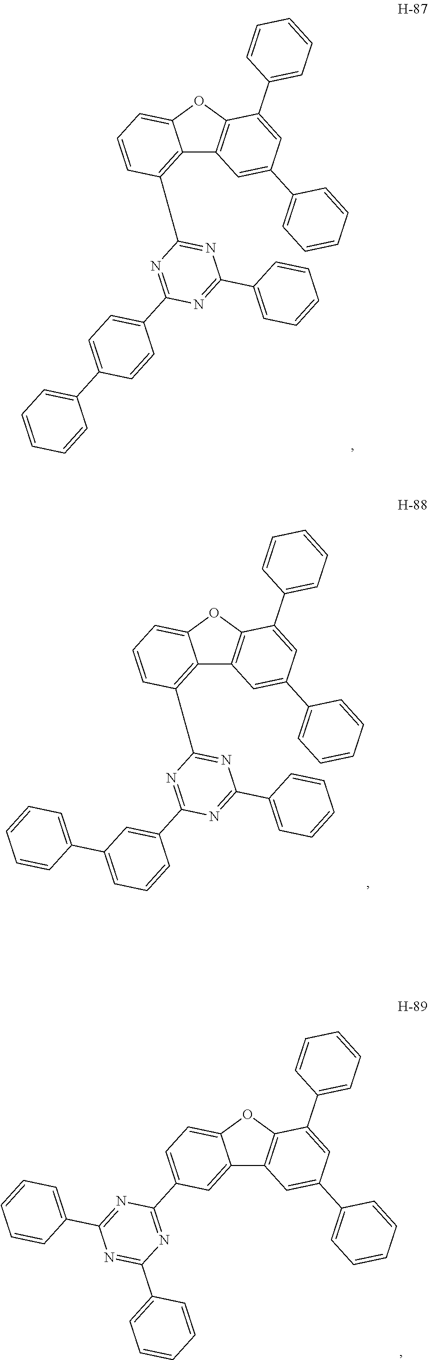 [SMILES: c1ccc(-c2ccc(-c3nc(-c4ccccc4)nc(-c4cccc5oc6c(-c7ccccc7)cc(-c7ccccc7)cc6c45)n3)cc2)cc1 ; c1ccc(-c2cccc(-c3nc(-c4ccccc4)nc(-c4cccc5oc6c(-c7ccccc7)cc(-c7ccccc7)cc6c45)n3)c2)cc1 ; c1ccc(-c2cc(-c3ccccc3)c3oc4ccc(-c5nc(-c6ccccc6)nc(-c6ccccc6)n5)cc4c3c2)cc1]

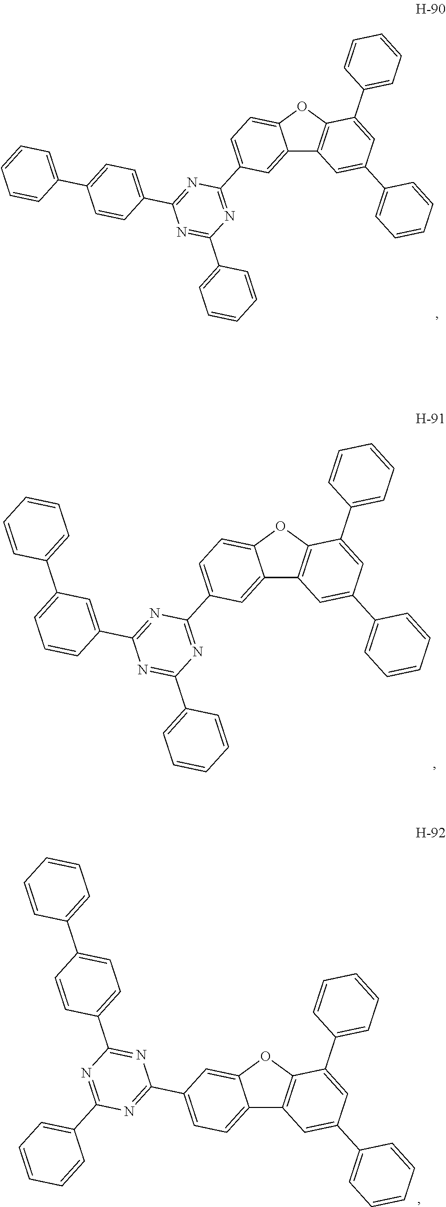 [SMILES: c1ccc(-c2ccc(-c3nc(-c4ccccc4)nc(-c4ccc5oc6c(-c7ccccc7)cc(-c7ccccc7)cc6c5c4)n3)cc2)cc1 ; c1ccc(-c2cccc(-c3nc(-c4ccccc4)nc(-c4ccc5oc6c(-c7ccccc7)cc(-c7ccccc7)cc6c5c4)n3)c2)cc1 ; c1ccc(-c2ccc(-c3nc(-c4ccccc4)nc(-c4ccc5c(c4)oc4c(-c6ccccc6)cc(-c6ccccc6)cc45)n3)cc2)cc1]

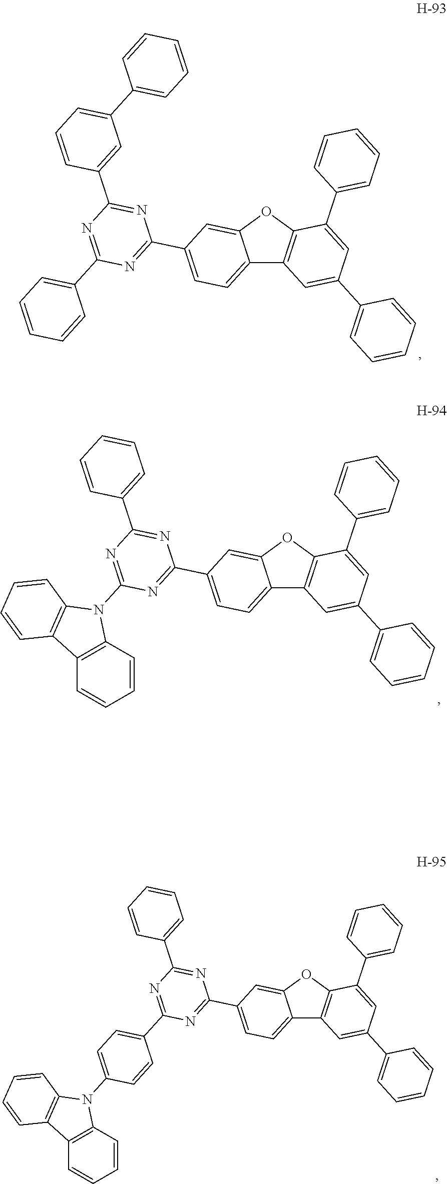 [SMILES: c1ccc(-c2cccc(-c3nc(-c4ccccc4)nc(-c4ccc5c(c4)oc4c(-c6ccccc6)cc(-c6ccccc6)cc45)n3)c2)cc1 ; c1ccc(-c2cc(-c3ccccc3)c3oc4cc(-c5nc(-c6ccccc6)nc(-n6c7ccccc7c7ccccc76)n5)ccc4c3c2)cc1 ; c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1]

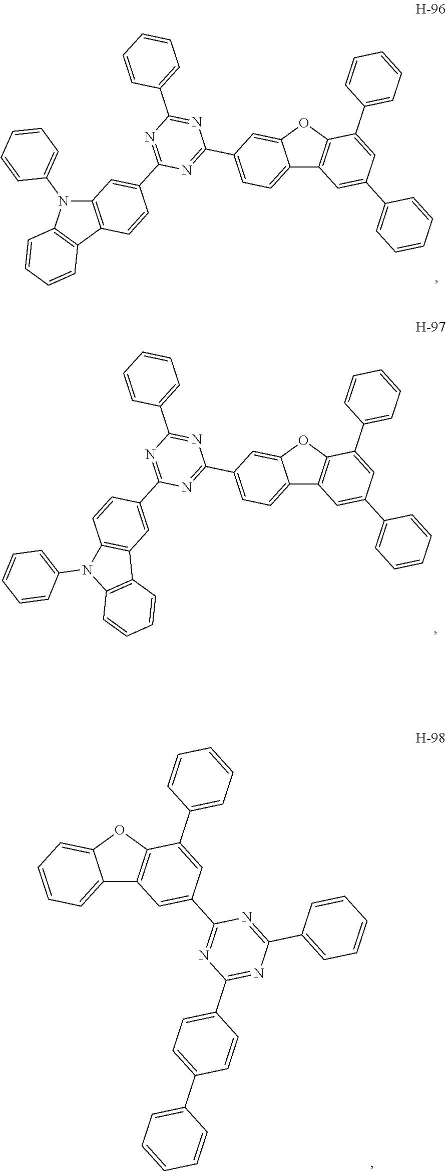 [SMILES: c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1 ; c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1 ; c1ccc(-c2ccc(-c3nc(-c4ccccc4)nc(-c4cc(-c5ccccc5)c5oc6ccccc6c5c4)n3)cc2)cc1]

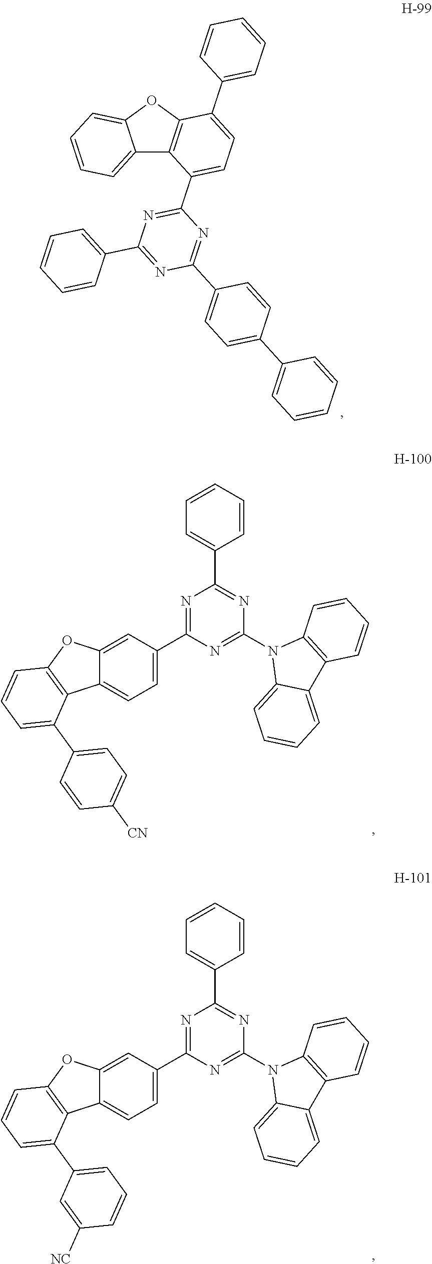 [SMILES: c1ccc(-c2ccc(-c3nc(-c4ccccc4)nc(-c4ccc(-c5ccccc5)c5oc6ccccc6c45)n3)cc2)cc1 ; N#Cc1ccc(-c2cccc3oc4cc(-c5nc(-c6ccccc6)nc(-n6c7ccccc7c7ccccc76)n5)ccc4c23)cc1 ; N#Cc1cccc(-c2cccc3oc4cc(-c5nc(-c6ccccc6)nc(-n6c7ccccc7c7ccccc76)n5)ccc4c23)c1]

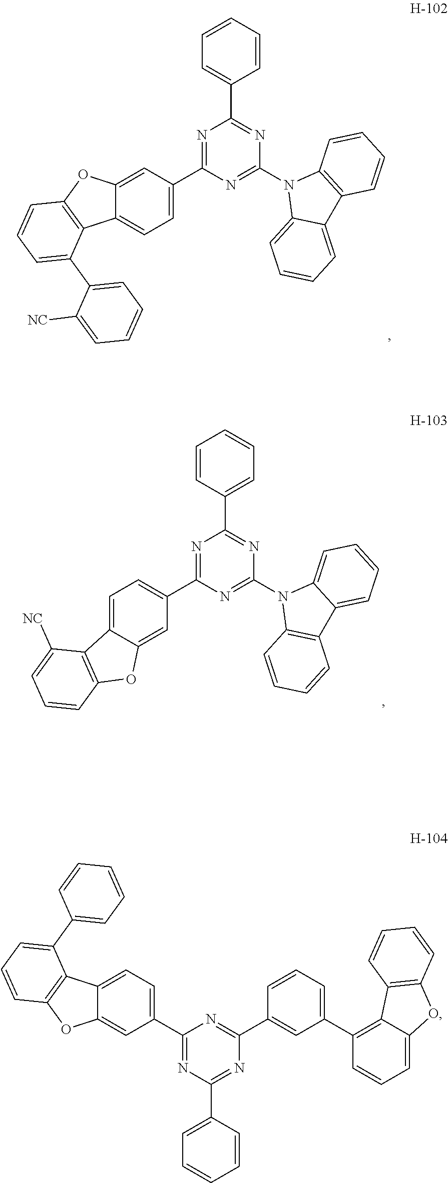 [SMILES: N#Cc1ccccc1-c1cccc2oc3cc(-c4nc(-c5ccccc5)nc(-n5c6ccccc6c6ccccc65)n4)ccc3c12 ; N#Cc1cccc2oc3cc(-c4nc(-c5ccccc5)nc(-n5c6ccccc6c6ccccc65)n4)ccc3c12 ; c1ccc(-c2nc(-c3cccc(-c4cccc5oc6ccccc6c45)c3)nc(-c3ccc4c(c3)oc3cccc(-c5ccccc5)c34)n2)cc1]

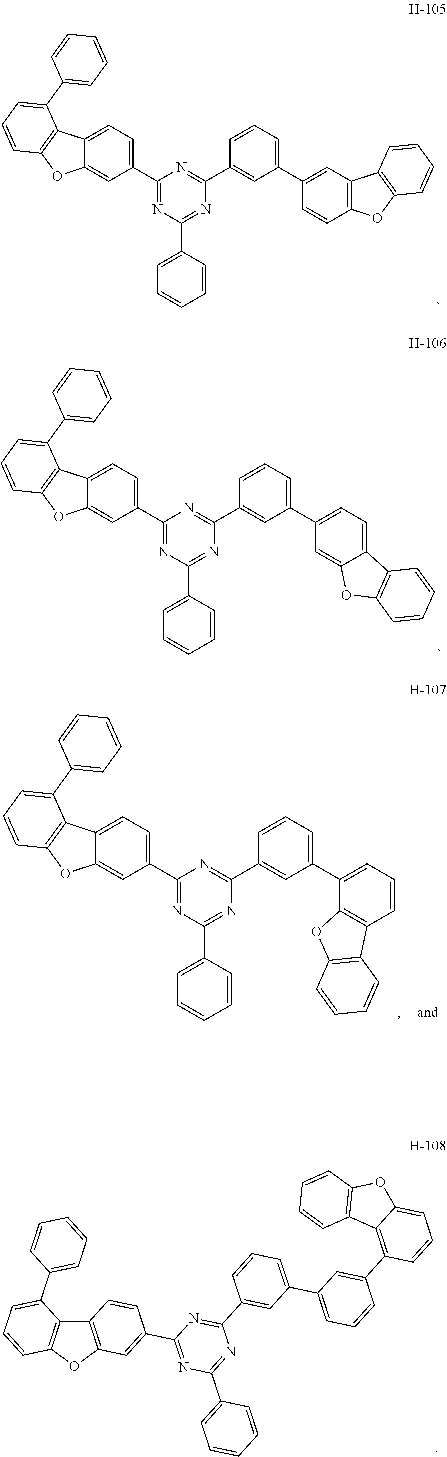 [SMILES: c1ccc(-c2nc(-c3cccc(-c4ccc5oc6ccccc6c5c4)c3)nc(-c3ccc4c(c3)oc3cccc(-c5ccccc5)c34)n2)cc1 ; c1ccc(-c2nc(-c3cccc(-c4ccc5c(c4)oc4ccccc45)c3)nc(-c3ccc4c(c3)oc3cccc(-c5ccccc5)c34)n2)cc1 ; c1ccc(-c2nc(-c3cccc(-c4cccc5c4oc4ccccc45)c3)nc(-c3ccc4c(c3)oc3cccc(-c5ccccc5)c34)n2)cc1 ; c1ccc(-c2nc(-c3cccc(-c4cccc(-c5cccc6oc7ccccc7c56)c4)c3)nc(-c3ccc4c(c3)oc3cccc(-c5ccccc5)c34)n2)cc1]

According to another embodiment of the present disclosure, a display device is further disclosed. The display device includes the organic electroluminescent device described in any one of the preceding embodiments.

According to another embodiment of the present disclosure, the use of the organic electroluminescent device described in any one of the preceding embodiments in a display device is further disclosed.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, the compounds disclosed herein may be used in combination with a wride variety of emissive dopants, hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The metal complexes and the fluorescent emissive materials used in the present disclosure can be easily obtained with reference to the preparation methods in the related art. For example, part of the metal complexes can be prepared with reference to documents such as US20200091442A1 and US20200251666A1, and the fluorescent emissive materials can be prepared with reference to documents such as Angew. Chem. Int. Ed. 2023, 62, e202304104 (DOI: 10.1002/anie.202304104). The preparation methods thereof are not repeated here. The documents listed above are merely exemplary, and other documents may be easily obtained by those skilled in the art.

### Material Synthesis Example

The method for preparing a metal complex of the present disclosure is not limited herein. Typically, the following compounds are taken as examples without limitations, and synthesis routes and preparation methods thereof are described below.

### Synthesis Example 1: Synthesis of Metal Complex M-b26

### Step 1: Synthesis of Intermediate 3

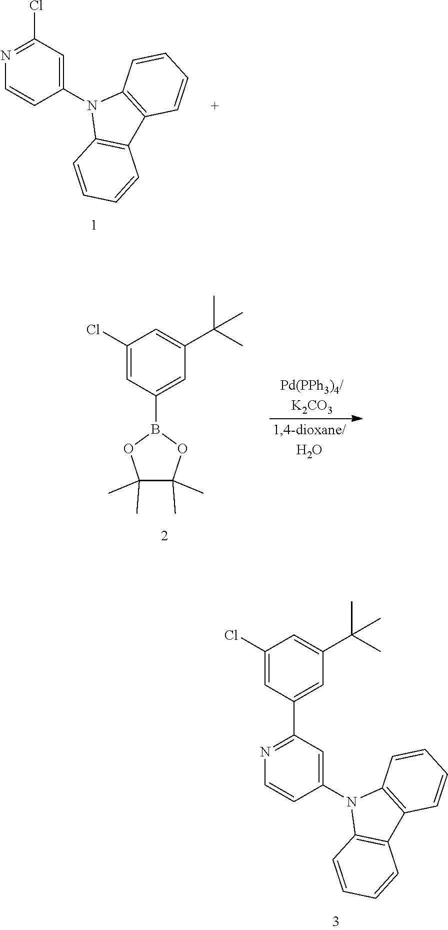 [SMILES: Clc1cc(-n2c3ccccc3c3ccccc32)ccn1 ; CC(C)(C)c1cc(Cl)cc(B2OC(C)(C)C(C)(C)O2)c1 ; CC(C)(C)c1cc(Cl)cc(-c2cc(-n3c4ccccc4c4ccccc43)ccn2)c1]

Under a nitrogen condition. Intermediate 1 (4.7 g, 16.9 mmol), Intermediate 2 (5.5 g, 18.6 mmol), Pd(PPh₃)₄ (0.78 g, 0.67 mmol), and potassium carbonate (3.5 g, 25.3 mmol) were dissolved in 1,4-dioxane (90 mL) and water (30 mL), and the reaction was heated to reflux and conducted overnight. After the reaction was completed, the reaction solution was extracted with ethyl acetate (EA) and water to obtain an organic layer. The organic layer was washed twice with an aqueous sodium chloride solution, dried over anhydrous magnesium sulfate, evaporated to dry under reduced pressure, and purified through column chromatography to obtain Intermediate 3 (6.2 g, 15.1 mmol).

### Step 2: Synthesis of Intermediate 4

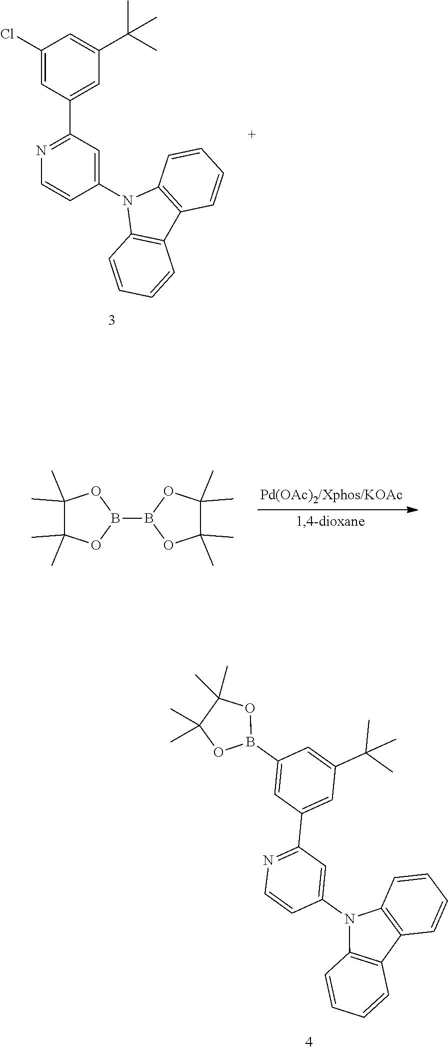

Under a nitrogen condition, Intermediate 3 (3.0 g, 7.3 mmol), bis(pinacolato)diboron (2.1 g, 8.1 mmol), Pd(OAc)₂ (0.05 g, 0.22 mmol), 2-dicyclohexylphosphino-2′,4′,6′-triisopropylbiphenyl (Xphos) (0.21 g, 0.44 mmol), and potassium acetate (1.08 g, 11.0 mmol) were dissolved in 1,4-dioxane (90 mL), and the reaction was heated to reflux and conducted overnight. After the reaction was completed, the reaction solution was extracted with EA and water to obtain an organic layer. The organic layer was washed twice with an aqueous sodium chloride solution, dried over anhydrous magnesium sulfate, and evaporated to dry under reduced pressure to obtain Intermediate 4 (3.5 g, 7.0 mmol).

### Step 3: Synthesis of Intermediate 6

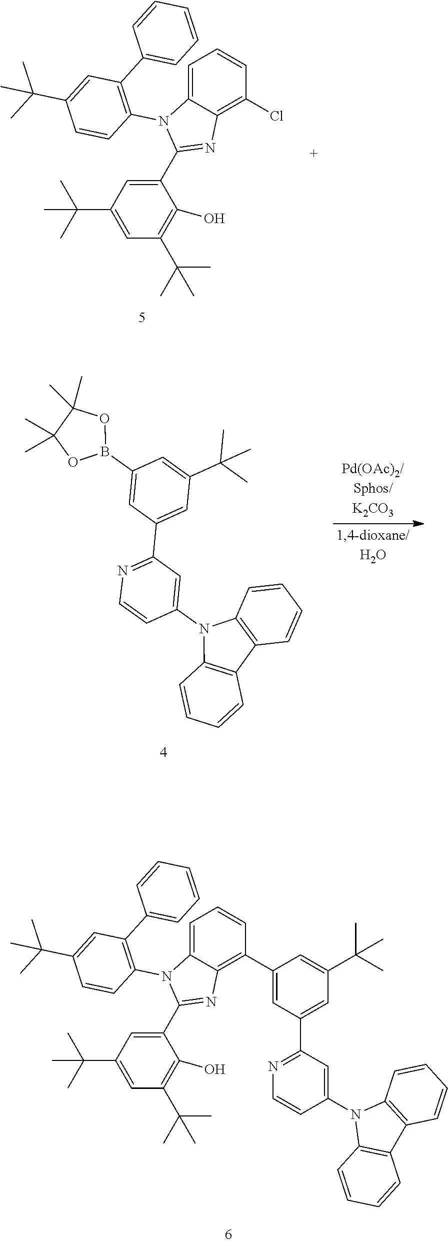 [SMILES: CC(C)(C)c1ccc(-n2c(-c3cc(C(C)(C)C)cc(C(C)(C)C)c3O)nc3c(Cl)cccc32)c(-c2ccccc2)c1 ; CC(C)(C)c1cc(B2OC(C)(C)C(C)(C)O2)cc(-c2cc(-n3c4ccccc4c4ccccc43)ccn2)c1 ; CC(C)(C)c1cc(-c2cc(-n3c4ccccc4c4ccccc43)ccn2)cc(-c2cccc3c2nc(-c2cc(C(C)(C)C)cc(C(C)(C)C)c2O)n3-c2ccc(C(C)(C)C)cc2-c2ccccc2)c1]

Under a nitrogen condition, Intermediate 4 (3.5 g, 7.0 mmol), Intermediate 5 (4.5 g, 8.0 mmol), Pd(OAc)₂ (0.05 g, 0.22 mmol), 2-dicyclohexylphosphino-2′,6′-dimethoxybiphenyl (Sphos) (0.19 g, 0.44 mmol), and potassium carbonate (1.52 g, 11.0 mmol) were dissolved in 1,4-dioxane (90 mL) and water (30 mL), and the reaction was heated to reflux and conducted overnight. After the reaction was completed, the reaction solution was extracted with EA and water to obtain an organic layer. The organic layer was washed twice with an aqueous sodium chloride solution, dried over anhydrous magnesium sulfate, evaporated to dry under reduced pressure, and purified through column chromatography to obtain Intermediate 6 (5.2 g, 5.7 mmol).

### Step 4: Synthesis of Metal Complex M-b26

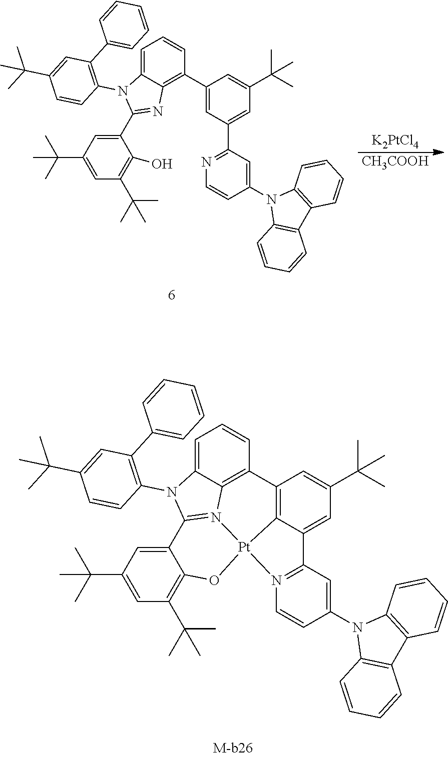

Intermediate 6 (2.98 g, 3.3 mmol), potassium chloroplatinate (1.24 g, 3.0 mmol), and acetic acid (50 mL) were sequentially added to a dry 250 mL round-bottom flask and heated to reflux for 48 hours under the protection of nitrogen. After the reaction was cooled, the water was added, and the reaction solution was filtered. The filter cake was washed twice with methanol and n-hexane separately. Then the filter cake was dissolved with dichloromethane. The organic phases were collected, concentrated under reduced pressure, and purified through column chromatography to obtain Metal Complex M-b26 as a yellow solid (1.68 g, with a yield of 51.0/). The structure of the product was confirmed as the target product with a relative molecular mass of 1097.4.

Those skilled in the art will appreciate that the above preparation methods are merely exemplary. Those skilled in the art can obtain other metal complex structures of the present disclosure through the modifications of the preparation methods.

The method for preparing an electroluminescent device is not limited herein. The preparation methods in the following examples are merely examples and are not to be construed as limiting. Based on the related art, those skilled in the art can make reasonable improvements on the preparation methods in the following examples. For example, the proportions of various materials in an emissive layer are not particularly limited. Those skilled in the art can reasonably select the proportions within a certain range based on the related art. For example, taking the total weight of the materials in the emissive layer as a reference, a host material may account for 75% to 98%, a metal complex may account for 1% to 20%, and a fluorescent emissive material may account for 1% to 5%; or the host material may account for 88% to 98%, the metal complex may account for 1% to 10%, and the fluorescent emissive material may account for 1% to 2%. Further, the host material may be two materials, wherein the ratio of the two host materials in the host material may be 99:1 to 1:99, or, the ratio may be 80:20 to 20:80; or the ratio may be 70:30 to 30:70. In the examples of the device, the characteristics of the device were also tested using conventional equipment in the art (including, but not limited to, evaporation deposition system produced by ANGSTROM ENGINEERING, optical testing system produced by SUZHOU FSTAR, life testing system produced by SUZHOU FSTAR, ellipsometer produced by BEIJING ELLITOP, etc.) by methods well known to those skilled in the art.

In the present disclosure, the triplet energy levels of the compounds were tested in the following methods.

The test method of the triplet energy level of the metal complex;

The photoluminescence (PL) spectrum data of a compound to be tested were measured using a fluorescence spectrophotometer F98 produced by SHANGHAI LENGGUANG TECHNOLOGY CO., LTD. The metal complex was dissolved in a toluene solvent to prepare a solution with a concentration of 10⁻⁵ M, nitrogen was introduced into the prepared solution for 5 minutes to remove oxygen, and the solution was added to a quartz sample tube and excited at room temperature (298 K) by light with a wavelength of 400 nm to measure the photoluminescence (PL) spectrum.

The longitudinal axis of the PL spectrum represents the phosphorescence intensity, and the horizontal axis represents the wavelength. The minimum value k, (nm) of a peak on a short wavelength side of the PL spectrum was taken, and the wavelength value was plugged into the following conversion formula F₁ to calculate the triplet energy level (referred to as triplet energy).

$$Conversion formula {F}_{1} : {T}_{1} ( eV ) = 1240 / {λ}_{1} .$$

The test method of the triplet energy level of the host compound:

The photoluminescence (PL) spectrum data of a compound to be tested were measured using a fluorescence spectrophotometer F98 produced by SHANGHAI LENGGUANG TECHNOLOGY CO., LTD. The compound was dissolved in a 2-methyltetrahydrofuran solvent to prepare a solution with a concentration of 10⁻⁵ M, nitrogen was introduced into the prepared solution for 5 minutes to remove oxygen, and the solution was added to a quartz sample tube, placed into a Dewar's vessel, cooled to 77 K, and excited by light with a wavelength of 330 nm to measure the photoluminescence (PL) spectrum.

The longitudinal axis of the PL spectrum represents the phosphorescence intensity, and the horizontal axis represents the wavelength. The minimum value λ₂ (nm) of a peak on a short wavelength side of the PL spectrum was taken, and the wavelength value was plugged into the following conversion formula F₂ to calculate the triplet energy level.

$$Conversion formula {F}_{2} : {T}_{2} ( eV ) = 1240 / {λ}_{2} .$$

The triplet energy level of the fluorescent emissive material can be tested with reference to the methods in the related art or can be obtained with reference to the test method of the host compound described above.

The triplet energy levels T₁ (eV) of the following compounds were measured through the above method. The specific results are shown in Table 1.

TABLE 1
Triplet energy level data of compounds

| Compound | |
|---|---|
| No. | T₁ (eV) |
| M-a43 | 2.353 |
| M-a48 | 2.344 |
| M-a41 | 2.362 |
| M-a12 | 2.371 |
| M-a30 | 2.357 |
| M-a85 | 2.357 |
| M-b26 | 2.366 |
| M-b1 | 2.357 |
| PH-1 | 2.731 |
| H-40 | 2.627 |

The relationship between the triplet energy level of the host material and the triplet energy level of the metal complex in the emissive layer of the organic electroluminescent device has a crucial influence on the performance of the device. It is found that when the triplet energy level of the metal complex is higher than the triplet energy level of the host compound, the energy can easily be transferred back from the triplet energy level of the metal complex to the triplet energy level of the host compound, resulting in quenching of excitons and thus leading to the reduction of luminescence efficiency of the device. The triple energy level of the host compound in the device of the present disclosure is higher than the triple energy level of the metal complex so that the energy can be better transferred from the host compound to the metal complex, thereby improving the energy transfer efficiency, laying a good foundation for the subsequent transfer of energy from the metal complex to the fluorescent emissive material, better facilitating the energy transfer in the emissive layer, and thus obtaining a high-performance organic electroluminescent device.

### Device Example

### Device Example 1

First, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms (Å) per second at a vacuum degree of about 10⁻⁸ torr. Compound HT and Compound HT1 were co-evaporated (at a weight ratio of 97:3) as a hole injection layer (HIL). Compound HT was evaporated as a hole transport layer (HTL). Compound PH-23 was evaporated as an electron blocking layer (EBL). Then, a first host compound PH-1, a second host compound H-40, a metal complex M-a43, and a fluorescent emissive material BD-26 were co-evaporated (at a weight ratio of 56:37:6:1) as an emissive layer (EML). On the EML, Compound HB was evaporated as a hole blocking layer (HBL). On the HBL, Compound ET and 8-hydroxyquinolinolato-lithium (Liq) were co-evaporated (at a weight ratio of 40:60) as an electron transport layer (ETL). Finally, 8-hydroxyquinolinolato-lithium (Liq) was deposited as an electron injection layer with a thickness of 1 nm, and aluminum was deposited as a cathode with a thickness of 120 nm. The device was transferred back to the glovebox and encapsulated with a glass lid and a moisture getter to complete the device.

### Device Example 2

The implementation in Device Example 2 was the same as the implementation in Device Example 1 except that in the emissive layer (EML), the metal complex M-a43 was replaced with a metal complex M-a48.

### Device Example 3

The implementation in Device Example 3 was the same as the implementation in Device Example 1 except that in the emissive layer (EML), the metal complex M-a43 was replaced with a metal complex M-a41.

### Device Example 4

The implementation in Device Example 4 was the same as the implementation in Device Example 1 except that in the emissive layer (EML), the metal complex M-a43 was replaced with a metal complex M-a12.

### Device Example 5

The implementation in Device Example 5 was the same as the implementation in Device Example 1 except that in the emissive layer (EML), the metal complex M-a43 was replaced with a metal complex M-a30 and the weight ratio among the first host compound PH-1, the second host compound H-40, the metal complex M-a30 of the present disclosure, and the fluorescent emissive material BD-26 was 46.5:46.5:6:1.

### Device Example 8

The implementation in Device Example 8 was the same as the implementation in Device Example 1 except that in the emissive layer (EML), the metal complex M-a43 was replaced with a metal complex M-a85 and the weight ratio among the first host compound PH-1, the second host compound H-40, the metal complex M-a85 of the present disclosure, and the fluorescent emissive material BD-26 was 56:37:6:1.

### Device Comparative Example 1

The implementation in Device Comparative Example 1 was the same as the implementation in Device Example 1 except that in the emissive layer (EML), the metal complex M-a43 was replaced with a metal complex GD1.

### Device Comparative Example 2

The implementation in Device Comparative Example 2 was the same as the implementation in Device Example 1 except that the first host compound PH-1, the second host compound H-40, and the fluorescent emissive material BD-26 were co-evaporated as the emissive layer (EML) at a weight ratio of 59:40:1.

### Device Comparative Example 3

The implementation in Device Comparative Example 3 was the same as the implementation in Device Example 1 except that the first host compound PH-1, the second host compound H-40, and the metal complex M-a43 of the present disclosure were co-evaporated as the emissive layer (EML) at a weight ratio of 56:38:6.

### Device Comparative Example 4

The implementation in Device Comparative Example 4 was the same as the implementation in Device Example 2 except that the first host compound PH-1, the second host compound H-40, and the metal complex M-a48 of the present disclosure were co-evaporated as the emissive layer (EML) at a weight ratio of 56:38:6.

### Device Comparative Example 5

The implementation in Device Comparative Example 5 was the same as the implementation in Device Example 3 except that the first host compound PH-1, the second host compound H-40, and the metal complex M-a41 of the present disclosure were co-evaporated as the emissive layer (EML) at a weight ratio of 56:38:6.

### Device Comparative Example 6

The implementation in Device Comparative Example 6 was the same as the implementation in Device Example 4 except that the first host compound PH-1, the second host compound H-40, and the metal complex M-a12 of the present disclosure were co-evaporated as the emissive layer (EML) at a weight ratio of 56:38:6.

### Device Comparative Example 7

The implementation in Device Comparative Example 7 was the same as the implementation in Device Example 5 except that the first host compound PH-1, the second host compound H-40, and a metal complex M-a30 of the present disclosure were co-evaporated as the emissive layer (EML) at a weight ratio of 47:47:6.

### Device Comparative Example 11

The implementation in Device Comparative Example 11 was the same as the implementation in Device Example 8 except that the first host compound PH-1, the second host compound H-40 and a metal complex M-a85 of the present disclosure were co-evaporated as the emissive layer (EML) at a weight ratio of 56.4:37.6:6.

Detailed structures and thicknesses of layers of the devices are shown in the following table 2. A layer using more than one material is obtained by doping different compounds at their weight ratio as recorded.

TABLE 2
Part of device structures in Examples 1 to S and 8 and Comparative Examples 1 to 7 and 11

| Device ID | HIL | HTL | EBL | EML | HBL | ETL |
|---|---|---|---|---|---|---|
| Example 1 | Compound | Compound | Compound | Compound | Compound | Compound |
| | HT:Compound | HT | PH-23 | PH-1:Compound | HB | ET.Liq |
| | HTI | (350 Å) | (50 Å) | H-40:Metal | (50 Å) | (40:60) |
| | (97:3) | | | Complex | | (350 Å) |
| | (100 Å) | | | M-a43:Compound | | |
| | | | | BD-26 | | |
| | | | | (56:37:6:1) | | |
| | | | | (400 Å) | | |
| Example 2 | Compound | Compound | Compound | Compound | Compound | Compound |
| | HT:Compound | HT | PH-23 | PH-1:Compound | HB | ET.Liq |
| | HTI | (350 Å) | (50 Å) | H-40:Metal | (50 Å) | (40:60) |
| | (97:3) | | | Complex | | (350 Å) |
| | (100 Å) | | | M-a48:Compound | | |
| | | | | BD-26 | | |
| | | | | (56:37:6:1) | | |
| | | | | (400 Å) | | |
| Example 3 | Compound | Compound | Compound | Compound | Compound | Compound |
| | HT:Compound | HT | PH-23 | PH-1:Compound | HB | ET:Liq |
| | HT1 | (350 Å) | (50 Å) | H-40:Metal | (50 Å) | (40:60) |
| | (97:3) | | | Complex | | (350 Å) |
| | (100 Å) | | | M-a41:Compound | | |
| | | | | BD-26 | | |
| | | | | (56:37:6:1) | | |
| | | | | (400 Å) | | |
| Example 4 | Compound | Compound | Compound | Compound | Compound | Compound |
| | HT:Compound | HT | PH-23 | PH-1:Compound | HB | ET:Liq |
| | HTI | (350 Å) | (50 Å) | H-40:Metal | (50 Å) | (40:60) |
| | (97:3) | | | Complex | | (350 Å) |
| | (100 Å) | | | M-a12:Compound | | |
| | | | | BD-26 | | |
| | | | | (56:37:6:1) | | |
| | | | | (400 Å) | | |
| Example 5 | Compound | Compound | Compound | Compound | Compound | Compound |
| | HT:Compound | HT | PH-23 | PH-1:Compound | HB | ET:Liq |
| | HTI | (350 Å) | (50 Å) | H-40:Metal | (50 Å) | (40:60) |
| | (97:3) | | | Complex | | (350 Å) |
| | (100 Å) | | | M-a30:Compound | | |
| | | | | BD-26 | | |
| | | | | (46.5:46.5:6:1) | | |
| | | | | (400 Å) | | |
| Example 8 | Compound | Compound | Compound | Compound | Compound | Compound |
| | HT:Compound | HT | PH-23 | PH-1:Compound | HB | ET:Liq |
| | HTI | (350 Å) | (50 Å) | H-40:Metal | (50 Å) | (40:60) |
| | (97:3) | | | Complex | | (350 Å) |
| | (100 Å) | | | M-a85:Compound | | |
| | | | | BD-26 | | |
| | | | | (56:37:6:1) | | |
| | | | | (400 Å) | | |
| Comparative | Compound | Compound | Compound | Compound | Compound | Compound |
| Example 1 | HT:Compound | HT | PH-23 | PH-1:Compound | HB | ET:Liq |
| | HTI | (350 Å) | (50 Å) | H-40:Metal | (50 Å) | (40:60) |
| | (97:3) | | | Complex | | (350 Å) |
| | (100 Å) | | | GD1:Compound | | |
| | | | | BD-26 | | |
| | | | | (56:37:6:1) | | |
| | | | | (400 Å) | | |
| Comparative | Compound | Compound | Compound | Compound | Compound | Compound |
| Example 2 | HT:Compound | HT | PH-23 | PH-1:Compound | HB | ET:Liq |
| | HTI | (350 Å) | (50 Å) | H-40:Compound | (50 Å) | (40:60) |
| | (97:3) | | | BD-26 | | (350 Å) |
| | (100 Å) | | | (59:40:1) | | |
| | | | | (400 Å) | | |
| Comparative | Compound | Compound | Compound | Compound | Compound | Compound |
| Example 3 | HT:Compound | HT | PH-23 | PH-1:Compound | HB | ET:Liq |
| | HT1 | (350 Å) | (50 Å) | H-40:Metal | (50 Å) | (40:60) |
| | (97:3) | | | Complex M-a43 | | (350 Å) |
| | (100 Å) | | | (56:38:6) | | |
| | | | | (400 Å) | | |
| Comparative | Compound | Compound | Compound | Compound | Compound | Compound |
| Example 4 | HT:Compound | HT | PH-23 | PH-1:Compound | HB | ET:Liq |
| | HTI | (350 Å) | (50 Å) | H-40:Metal | (50 Å) | (40:60) |
| | (97:3) | | | Complex M-a48 | | (350 Å) |
| | (100 Å) | | | (56:38:6) | | |
| | | | | (400 Å) | | |
| Comparative | Compound | Compound | Compound | Compound | Compound | Compound |
| Example 5 | HT:Compound | HT | PH-23 | PH-1:Compound | HB | ET:Liq |
| | HTI | (350 Å) | (50 Å) | H-40:Metal | (50 Å) | (40:60) |
| | (97:3) | | | Complex M-a41 | | (350 Å) |
| | (100 Å) | | | (56:38:6) | | |
| | | | | (400 Å) | | |
| Comparative | Compound | Compound | Compound | Compound | Compound | Compound |
| Example 6 | HT:Compound | HT | PH~23 | PH-1:Compound | HB | ET:Liq |
| | HT1 | (350 Å) | (50 Å) | H-40:Metal | (50 A) | (40:60) |
| | (97:3) | | | Complex M-a12 | | (350 Å) |
| | (100 Å) | | | (56:38:6) | | |
| | | | | (400 Å) | | |
| Comparative | Compound | Compound | Compound | Compound | Compound | Compound |
| Example 7 | HT:Compound | HT | PH-23 | PH-1:Compound | HB | ET:Liq |
| | HT1 | (350 Å) | (50 Å) | H-40:Metal | (50 Å) | (40:60) |
| | (97:3) | | | Complex M-a30 | | (350 Å) |
| | (100 Å) | | | (47:47:6) | | |
| | | | | (400 Å) | | |
| Comparative | Compound | Compound | Compound | Compound | Compound | Compound |
| Example 11 | HT:Compound | HT | PH-23 | PH-1:Compound | HB | ET:Liq |
| | HTI | (350 Å) | (50 Å) | H-40:Metal | (50 Å) | (40:60) |
| | (97:3) | | | Complex M-a85 | | (350 Å) |
| | (100 Å) | | | (56.4:37.6:6) | | |

(400 Å)

The materials used in the devices have the following structures:

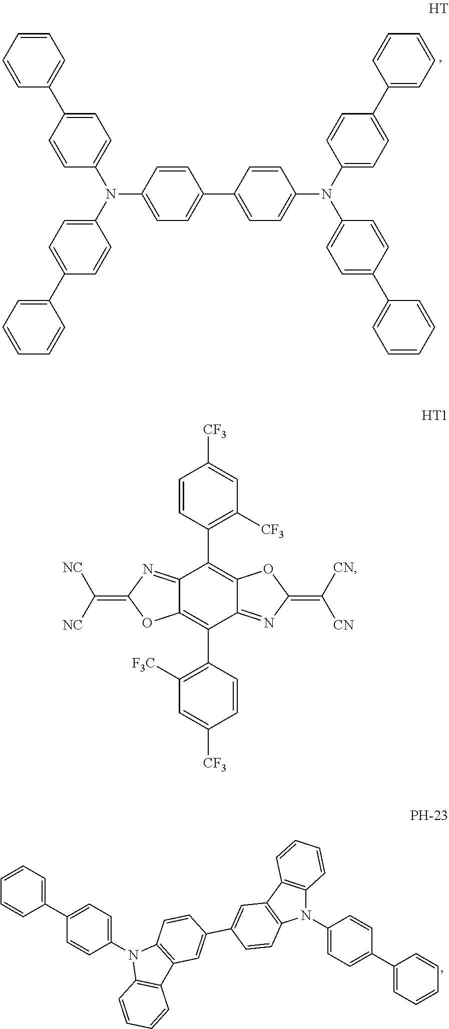 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(-n3c4ccccc4c4cc(-c5ccc6c(c5)c5ccccc5n6-c5ccc(-c6ccccc6)cc5)ccc43)cc2)cc1]

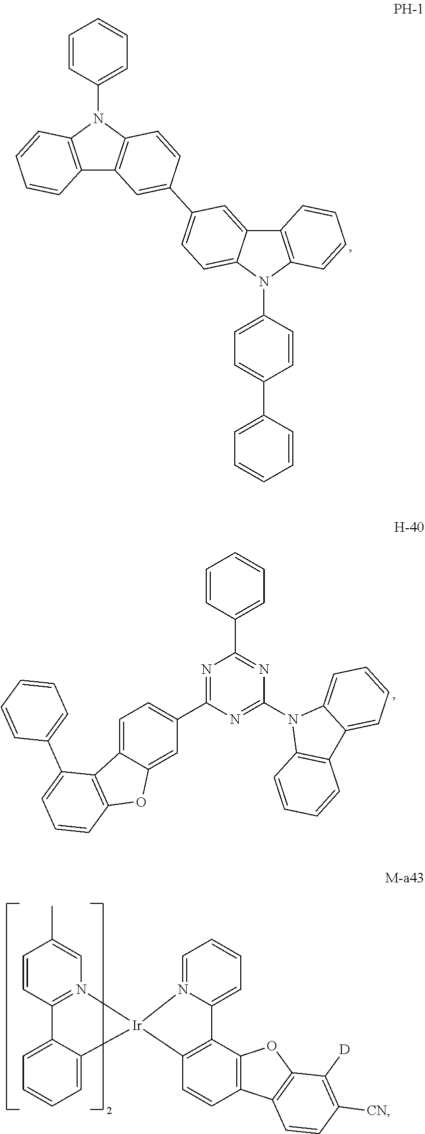

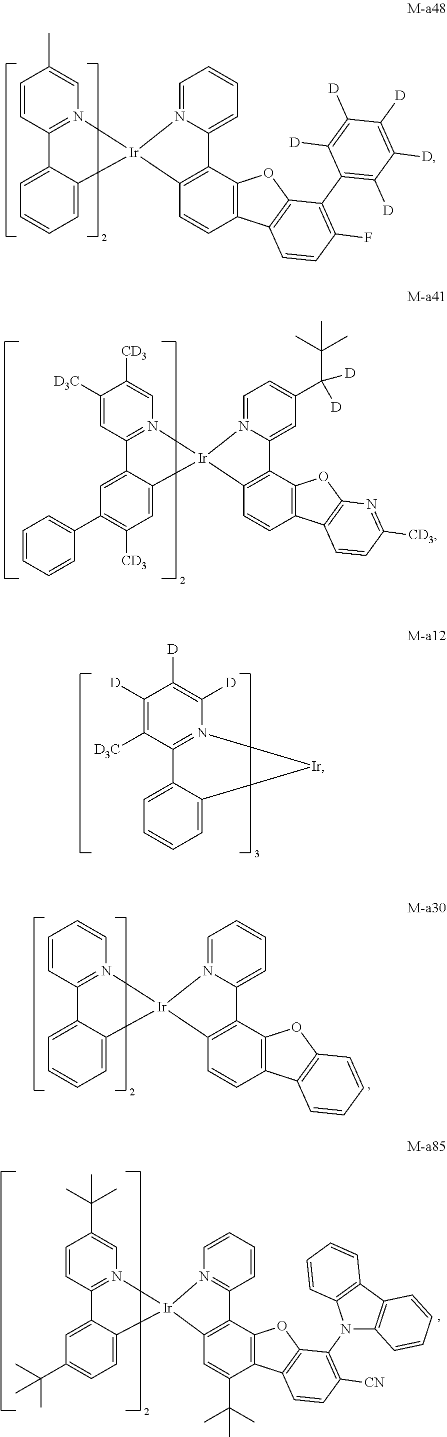

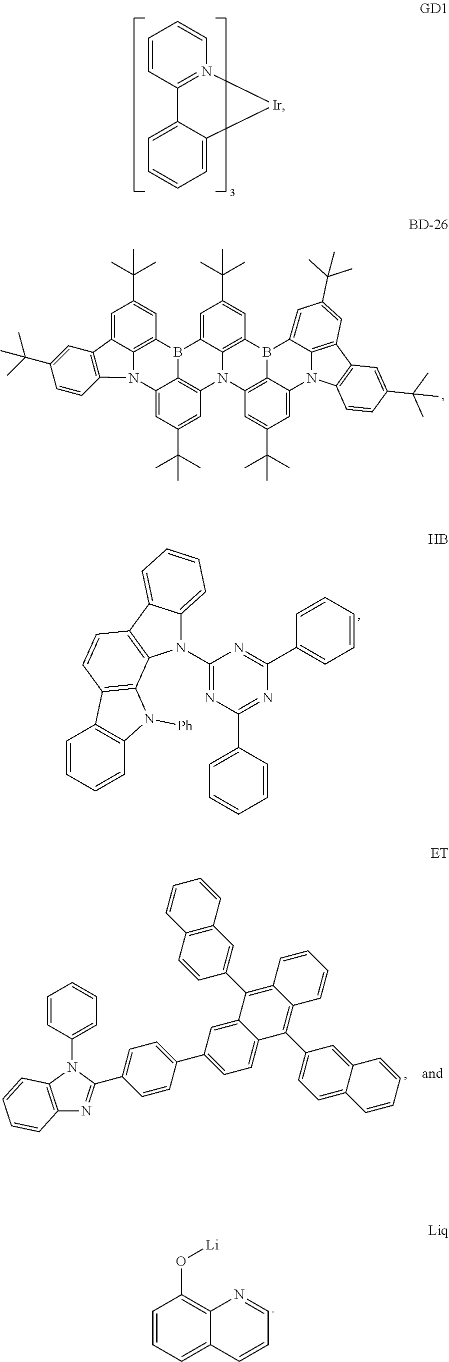

The CIE data, the maximum emission wavelengths (λₘₐₓ) the full widths at half maximum (FWHM)(the drive voltages (V), and the power efficiency (PE) of the devices were measured at a constant brightness of 1000 cd/cm², and the lifetimes LT97 of the devices were measured at an initial brightness of 10000 cd/cm². These data were recorded and presented in Table 3.

TABLE 3
Device data of Examples 1 to 5 and 8 and
Comparative Examples 1 to 7 and 11

| | | λₘₐₓ | FWHM | Voltage | PE | LT97 |
|---|---|---|---|---|---|---|
| Device ID | CIE (x, y) | (nm) | (nm) | (V) | (lm/W) | (h) |
| Example 1 | (0.357, 0.633) | 549 | 34.1 | 2.59 | 164.9 | 1936 |
| Example 2 | (0.357, 0.633) | 548 | 33.7 | 2.80 | 153.1 | 1421 |
| Example 3 | (0.354, 0.635) | 548 | 33.9 | 3.00 | 143.6 | 1069 |
| Example 4 | (0.357, 0.632) | 548 | 33.8 | 3.30 | 122.0 | 1291 |
| Example 5 | (0.355, 0.634) | 548 | 33.9 | 3.35 | 121.4 | 2152 |
| Example 8 | (0.356, 0.634) | 549 | 33.5 | 2.77 | 156.1 | 1129 |
| Comparative | (0.351, 0.636) | 548 | 33.4 | 3.43 | 118.7 | 1102 |
| Example 1 | | | | | | |
| Comparative | (0.351, 0.637) | 548 | 32.7 | 2.93 | 96.8 | 41 |
| Example 2 | | | | | | |
| Comparative | (0.337, 0.637) | 529 | 42.1 | 2.66 | 112.0 | 986 |
| Example 3 | | | | | | |
| Comparative | (0.346, 0.626) | 529 | 58.7 | 2.89 | 100.8 | 871 |
| Example 4 | | | | | | |
| Comparative | (0.331, 0.636) | 525 | 56.2 | 3.12 | 105.2 | 503 |
| Example 5 | | | | | | |
| Comparative | (0.345, 0.616) | 524 | 74.1 | 3.47 | 62.6 | 261 |
| Example 6 | | | | | | |
| Comparative | (0.333, 0.633) | 525 | 58.6 | 3.46 | 69.4 | 598 |
| Example 7 | | | | | | |
| Comparative | (0.307, 0.658) | 527 | 32.1 | 2.83 | 117.7 | 771 |
| Example 11 | | | | | | |

Examples 1 to 4 and 8 differ from Comparative Example 1 only in that the structures of the metal complexes used in the emissive layers of the devices are different. As can be seen from the data in Table 3, compared to the device of Comparative Example 1, the devices in Examples 1 to 4 and 8 of the present disclosure in which a metal complex including a specific ligand Lₐ is used as a phosphorescence sensitizer in the emissive layer to sensitize the fluorescent emissive material BD-26 exhibit superior overall performance. For example, the drive voltages are reduced by 0.84 V, 0.63 V, 0.43 V, 0.13 V, and 0.66 V, respectively, and the PE is improved by 38.9%, 29.0%, 21.0%, 2.8%, and 31.5%, respectively. Furthermore, in terms of lifetime, it can be seen that although the lifetime of the device of Comparative Example 1 is at a relatively high level, the devices of Examples 3 and 8 of the present disclosure maintain lifetimes that are substantially comparable to the lifetime in Comparative Example 1, and the devices of Examples 1, 2, and 4 achieve unexpectedly significant improvements of 75.7%, 28.9%, and 17%, respectively.

The above data indicate that, compared to devices which do not use the metal complex of the present disclosure including the specific ligand Lₐ as a phosphorescence sensitizer, the devices of the present disclosure in which the metal complex including the specific ligand Lₐ is used as a phosphorescence sensitizer in the emissive layer to sensitize the fluorescent emissive material having a specific structure of Formula 1-1 exhibit superior overall performance. Not only can the drive voltage be reduced, but also the PE and/or the device lifetime can be improved.

Examples 1 to 4 and 8 differ from Comparative Example 2 only in that the devices of Examples 1 to 4 and 8 use the metal complex including the ligand Lₐ having a structure represented by Formula 1 as a phosphorescence sensitizer while the device of Comparative Example 2 does not use any phosphorescence sensitizer. As can be seen from the data in Table 3, the luminescence spectra of the devices of Examples 1 to 4 and 8 are substantially the same as the luminescence spectrum in Comparative Example 2, and their full widths at half maximum are all very narrow, indicating that the devices of Examples 1 to 4 and 8 achieve fluorescence emission as well. However, compared to the common fluorescent device of Comparative Example 2, the sensitized fluorescent devices of the present disclosure achieve significant improvements in the PE and the lifetime. Specifically, the PE is improved by 70.4%, 58.2%, 48.3%, 26.0%, and 61.3%, respectively, and the lifetime is significantly improved by 46.2 times, 33.7 times, 25.1 times, 30.5 times, and 27.5 times, respectively.

The above data indicate that, compared to the common fluorescent device not using a phosphorescent sensitizer in the emissive layer, the sensitized fluorescent device of the present disclosure has very excellent performance. Not only can the narrow full width at half maximum of the spectrum be maintained, but also the PE and the lifetime of the device can be significantly improved. Particularly, the lifetime is improved by as much as 25 times or more, which is very good at making up for the deficiencies of the common fluorescent device.

Examples 1 to 5 and 8 differ from Comparative Examples 3 to 7 and 11 only in that the devices of Examples 1 to 5 and 8 each use both a metal complex and a fluorescent emissive material of the present disclosure and emit fluorescence while the devices of Comparative Examples 3 to 7 and 11 each only use the corresponding metal complex, do not use the fluorescent emissive material, and emit phosphorescence. With the comparison between Example 1 and Comparative Example 3, the comparison between Example 2 and Comparative Example 4, the comparison between Example 3 and Comparative Example 5, the comparison between Example 4 and Comparative Example 6, the comparison between Example 5 and Comparative Example 7, and the comparison between Example 8 and Comparative Example 11, the sensitized fluorescent devices of Examples 1 to 5 and 8 of the present disclosure exhibit unexpectedly excellent performance in various aspects. For example, these sensitized fluorescent devices have a lower drive voltage, a higher PE, a longer lifetime, and/or a narrower full width at half maximum. The above data indicate that the sensitized fluorescent device of the present disclosure has superior device performance compared to the common phosphorescent device.

### Device Example 6

The implementation in Device Example 6 was the same as the implementation in Device Example 1 except that in the emissive layer (EML), the metal complex M-a43 was replaced with a metal complex M-b26 and the weight ratio among the first host compound PH-1, the second host compound H-40, the metal complex M-b26, and the fluorescent emissive material BD-26 was 45.5:45.5:8:1.

### Device Example 7

The implementation in Device Example 7 was the same as the implementation in Device Example 6 except that in the emissive layer (EML), the metal complex M-b26 was replaced with a metal complex M-b1 and the weight ratio among the first host compound PH-1, the second host compound H-40, the metal complex M-b1, and the fluorescent emissive material BD-26 was 55:36:8:1.

### Device Comparative Example 8

The implementation in Device Comparative Example 8 was the same as the implementation in Device Example 6 except that the first host compound PH-1, the second host compound H-40, and the fluorescent emissive material BD-26 were co-evaporated as the emissive layer (EML) at a weight ratio of 49.5:49.5:1.

### Device Comparative Example 9

The implementation in Device Comparative Example 9 was the same as the implementation in Device Example 6 except that the first host compound PH-1, the second host compound H-40, and the metal complex M-b26 of the present disclosure were co-evaporated as the emissive layer (EML) at a weight ratio of 46:46:8.

### Device Comparative Example 10

The implementation in Device Comparative Example 10 was the same as the implementation in Device Example 7 except that the first host compound PH-1, the second host compound H-40, and the fluorescent emissive material BD-26 were co-evaporated as the emissive layer (EML) at a weight ratio of 59-40:1.

Detailed structures and thicknesses of layers of the devices are shown in the following table. A layer using more than one material is obtained by doping different compounds at their weight ratio as recorded.

TABLE 4
Part of device structures in Examples 6 to 7 and Comparative Examples 8 to 10

| Device ID | HIL | HTL | EBL | EML | HBL | ETL |
|---|---|---|---|---|---|---|
| Example 6 | Compound | Compound | Compound | Compound | Compound | Compound |
| | HT:Compound | HT | PH-23 | PH-1:Compound | HB | ET:Liq |
| | HTI | (350 Å) | (50 Å) | H-40:Metal | (50 Å) | (40:60) |
| | (97:3) | | | Complex | | (350 Å) |
| | (100 Å) | | | M-b26:Compound | | |
| | | | | BD-26 | | |
| | | | | (45.5:45.5:8:1) | | |
| | | | | (400 Å) | | |
| Example 7 | Compound | Compound | Compound | Compound | Compound | Compound |
| | HT:Compound | HT | PH-23 | PH-1:Compound | HB | ET:Liq |
| | HTI | (350 A) | (50 A) | H-40:Metal | (50 Å) | (40:60) |
| | (97:3) | | | Complex | | (350 Å) |
| | (100 Å) | | | M-b1:Compound | | |
| | | | | BD-26 | | |
| | | | | (55:36:8:1) | | |
| | | | | (400 Å) | | |
| Comparative | Compound | Compound | Compound | Compound | Compound | Compound |
| Example 8 | HT:Compound | HT | PH~23 | PH-1:Compound | HB | ET:Liq |
| | HT1 | (350 Å) | (50 Å) | H-40:Compound | (50 A) | (40:60) |
| | (97:3) | | | BD-26 | | (350 Å) |
| | (100 Å) | | | (49.5:49.5:1) | | |
| | | | | (400 Å) | | |
| Comparative | Compound | Compound | Compound | Compound | Compound | Compound |
| Example 9 | HT:Compound | HT | PH-23 | PH-1:Compound | HB | ET:Liq |
| | HTI | (350 Å) | (50 Å) | H-40:Metal | (50 Å) | (40:60) |
| | (97:3) | | | Complex M-b26 | | (350 Å) |
| | (100 Å) | | | (46:46:8) | | |
| | | | | (400 Å) | | |
| Comparative | Compound | Compound HT | Compound | Compound | Compound | Compound |
| Example 10 | HT:Compound | (350 Å) | PH-23 | PH-1:Compound | HB | ET.Liq |
| | HTI | | (50 Å) | H-40:Compound | (50 Å) | (40:60) |
| | (97:3) | | | BD-26 | | (350 Å) |
| | (100 Å) | | | (59:40:1) | | |
| | | | | (400 Å) | | |

The new materials used in the devices have the following structure:

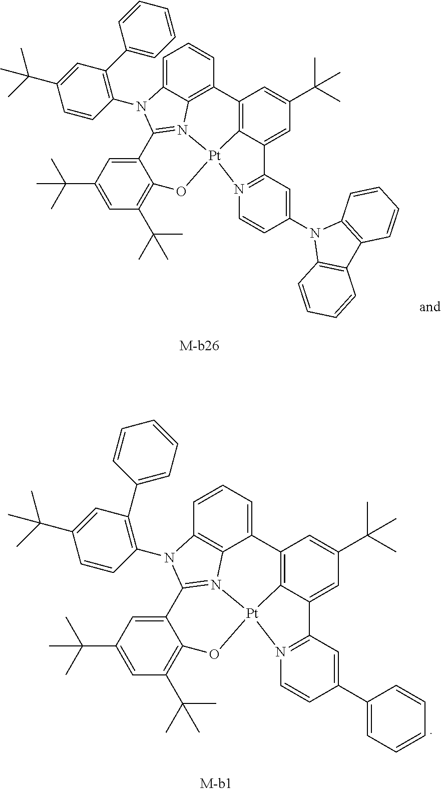

The CIE data, the maximum emission wavelengths (λₘₐₓ), the full widths at half maximum (FWHM), the drive voltages (V), the current efficiency (CE), the power efficiency (PE) and the external quantum efficiency (EQE) of the devices were measured at a constant current of 15 mA/cm², and the lifetimes LT97 of the devices were measured at an initial brightness of 1000 cd/cm². These data were recorded and presented in Table 5.

TABLE S
Device data of Examples 6 to 7 and Comparative Examples 8 and 10

| | | λₘₐₓ | FWHM | Voltage | CE | PE | EQE | LT97 |
|---|---|---|---|---|---|---|---|---|
| Device ID | CIE (x, y) | (nm) | (nm) | (V) | (cd/A) | (lm/W) | (%) | (h) |
| Example 6 | (0.350, 0.636) | 548 | 34.0 | 3.79 | 125.5 | 103.9 | 28.9 | 1025 |
| Example 7 | (0.354, 0.635) | 548 | 33.5 | 3.84 | 123.0 | 100.5 | 28.0 | 836 |
| Comparative | (0.355, 0.632) | 549 | 33.0 | 3.75 | 79.4 | 66.4 | 18.3 | 66 |
| Example 8 | | | | | | | | |
| Comparative | (0.316, 0,632) | 524 | 62.1 | 3.99 | 88.1 | 69.4 | 23.8 | 248 |
| Example 9 | | | | | | | | |
| Comparative | (0.349, 0,636) | 548 | 32.9 | 3.90 | 68 | 55 | 15.6 | 41 |
| Example 10 | | | | | | | | |

Example 6 differs from Comparative Example 8 only in that in addition to the fluorescent emissive material, the metal complex M-b26 including a specific ligand Lₐ of the present disclosure is further used as a phosphorescent sensitizer in the emissive layer in Example 6.

As can be seen from the data in Table 5, the maximum emission wavelengths in Example 6 and Comparative Example 8 are almost the same, which indicates that the light emitted by the device of Example 6 comes from the fluorescent emissive material BD-26. However, compared with the common fluorescent device of Comparative Example 8, the device of Example 6 of the present disclosure can further achieve significant improvements in device efficiency and lifetime while maintaining a narrow full width at half maximum and a low voltage that are substantially comparable to the full width at half maximum and the voltage in Comparative Example 8. Specifically, the CE, the PE, and the EQE are significantly improved by 58.1%, 56.5%, and 57.9%, respectively, and the lifetime is significantly improved by 14.5 times.

Example 6 differs from Comparative Example 9 only in that the device of Example 6 uses a metal complex of the present disclosure to sensitize a fluorescent emissive material having a specific structure of the present disclosure and emits fluorescence while the device of Comparative Example 9 only uses the metal complex in the emissive layer, does not use the fluorescent emissive material, and emits phosphorescence. Compared to the phosphorescent device of Comparative Example 9, the sensitized fluorescent device of Example 6 exhibits unexpectedly excellent performance in various aspects and has a higher CE, a higher PE, a higher EQE, a narrower full width at half maximum, and a lower voltage. Particularly, the lifetime of the sensitized fluorescent device of Example 6 is 4.1 times longer than the lifetime of the phosphorescent device of Comparative Example 9.

Example 7 differs from Comparative Example 10 only in that in addition to the fluorescent emissive material, the metal complex M-b1 of the present disclosure is further used as a phosphorescent sensitizer in the emissive layer in Example 7.

Similarly, as can be seen from the data in Table 5, the maximum emission wavelengths in Example 7 and Comparative Example 10 are almost the same, which indicates that the light emitted by the device of Example 7 comes from the fluorescent emissive material. Compared to the device of Comparative Example 10, the device of Example 7 also further achieves significant improvements in device efficiency and lifetime while maintaining a narrow full width at half maximum and a low voltage. Specifically, the CE, the PE, and the EQE are significantly improved by 80.9%, 82.7%, and 79.5%, respectively, and the lifetime is improved by 19.4 times.

The above results indicate that, compared to the common fluorescent device not including a phosphorescent sensitizer and the common phosphorescent device not including a fluorescent emissive material, the device of the present disclosure uses the metal complex including a specific ligand Lₐ having a structure of Formula 1 in the emissive layer as a phosphorescence sensitizer to efficiently sensitize the fluorescent emissive material having a specific structure of Formula 1-1 of the present disclosure. The device of the present disclosure can not only maintain a low drive voltage and a narrow full width at half maximum, but also significantly improve the device efficiency and the lifetime, showing unique advantages.

In summary, by using the metal complex including a specific ligand Lₐ having a structure of Formula 1 in the emissive layer as a phosphorescence sensitizer to efficiently sensitize the fluorescent emissive material having a specific structure of Formula 1-1 of the present disclosure, the device of the present disclosure exhibits excellent device performance, can further achieve significant improvements in device efficiency and/or lifetime while maintaining a relatively low drive voltage and a relatively narrow full width at half maximum, and has extremely wide application prospects.

It is to be understood that various embodiments described herein are merely illustrative and not intended to limit the scope of the present disclosure. Therefore, it is apparent to the persons skilled in the art that the present disclosure as claimed may include variations of specific embodiments and preferred embodiments described herein. Many of the materials and structures described herein may be replaced with other materials and structures without departing from the spirit of the present disclosure. It is to be understood that various theories as to why the present disclosure works are not intended to be limiting.

What is claimed is:

1. An organic electroluminescent device, comprising:
an anode,
a cathode, and
an organic laver disposed between the anode and the cathode, wherein the organic layer at least comprises a first host compound, a metal complex, and a fluorescent emissive material;
wherein a triplet energy level of the first host compound is greater than a triplet energy level of the metal complex;
the first host compound is a small molecule compound;
the metal complex comprises a metal M and a ligand Lₐ coordinated to the metal M, wherein the metal M is selected from a metal with a relative atomic mass greater than 40, and Lₐ has a structure represented by Formula 1: 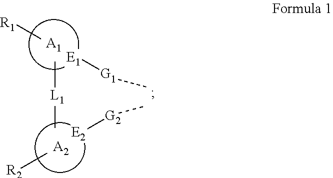
wherein,
the ring A₁ and the ring A₂ are selected from an aromatic ring having 6 to 30 ring atoms, a heteroaromatic ring having 5 to 30 ring atoms or a combination thereof;
E₁ and E₂ are, at each occurrence identically or differently, selected from C or N;
G₁ and G₂ are, at each occurrence identically or differently, selected from a single bond, O, S or NR′;
L₁ is, at each occurrence identically or differently, selected from the group consisting of: a single bond, BR″, CR″R″, NR″, O, SiR″R″, PR″, S, GeR″R″, Se, substituted or unsubstituted vinylene, ethynylene, substituted or unsubstituted arylene having 6 to 30 carbon atoms, substituted or unsubstituted heteroarylene having 3 to 30 carbon atoms, and combinations thereof; when two R″ are present at the same time, the two R″ are the same or different;
R₁ and R₂ represent, at each occurrence identically or differently, mono-substitution, multiple substitutions or non-substitution;
R₁, R₂, R′, and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
when the metal M is selected from Ir, L₁ is selected from a single bond, G₁ and G₂ are selected from a single bond, one of the ring A₁ and the ring A₂ is selected from a benzene ring, and the other of the ring A₁ and the ring A₂ is selected from a pyridine ring, R₁ and R₂ represent, at each occurrence identically or differently, mono-substitution or multiple substitutions, and at least one of R₁ and R₂ is selected from deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, or a combination thereof;
adjacent substituents R₁, R₂, R′ and R″ can be optionally joined to form a ring;
the fluorescent emissive material has a structure represented by Formula 1-1: 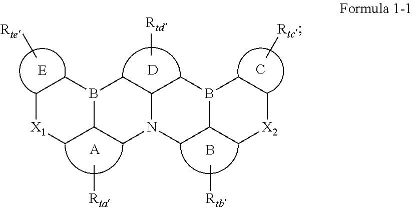
wherein the ring A, the ring B, the ring C, the ring D, and the ring E are, at each occurrence identically or differently, selected from an unsaturated carbocyclic ring having 5 to 30 carbon atoms or an unsaturated heterocyclic ring having 3 to 30 carbon atoms;
X₁ and X₂ are selected from O, S, Se, BR_{E}, NR_{E}, CR_{E}R_{E} or SiR_{E}R_{E}; when two R_{E} are present at the same time, the two R_{E} are the same or different;
Rₜₐ′, R_{tb}′, R_{tc}′, R_{td}′, Rₜₑ′, and R_{E} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BRₜ″Rₜ″, and combinations thereof;
Rₜ″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₜₐ′, R_{tb}′, R_{tc}′, R_{td}′, Rₜₑ′, Rₜ″ and R_{E} can be optionally joined to form a ring.

2. The organic electroluminescent device according to claim 1, wherein the ring A the ring B, the ring C, the ring D, and the ring E are, at each occurrence identically or differently, selected from a five-membered unsaturated carbocyclic ring, an aromatic ring having 6 to 30 carbon atoms or a heteroaromatic ring having 3 to 30 carbon atoms;
preferably the ring A, the ring B, the ring C, the ring D, and the ring E are, at each occurrence identically or differently, selected from a five-membered unsaturated carbocyclic ring, an aromatic ring having 6 to 18 carbon atoms or a heteroaromatic ring having 3 to 18 carbon atoms;
more preferably, the ring A, the ring B, the ring C, the ring D, and the ring E are, at each occurrence identically or differently, selected from a benzene ring, a pyridine ring, a naphthalene ring, a, phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring or a combination thereof.

3. The organic electroluminescent device according to claim 1, wherein X₁ and X₂ are, at each occurrence identically or differently, selected from O, S, Se or NR_{E}; preferably, X₁ and X₂ are, at each occurrence identically or differently, selected from O or NR_{E}.

4. The organic electroluminescent device according to claim 1, wherein the fluorescent emissive material has a structure represented by Formula 2-1, Formula 2-2, Formula 2-3, Formula 2-4, Formula 2-5 or Formula 2-6: 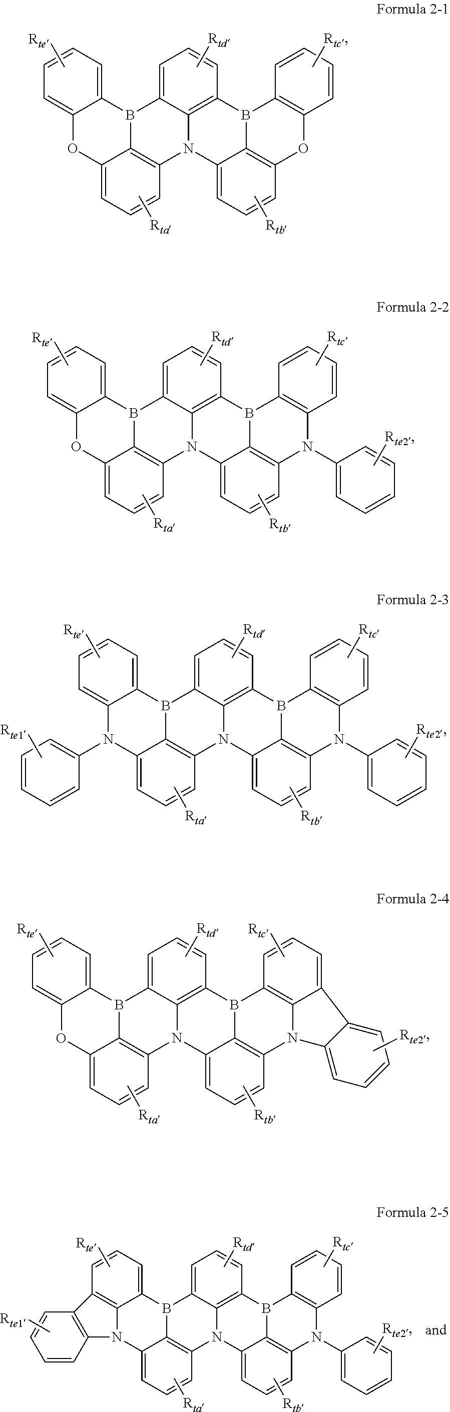 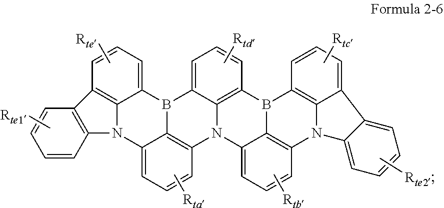
wherein Rₜₐ′, R_{tb}′, R_{tc}′, R_{td}′, Rₜₑ′, Rₜₑ₁′, and Rₜₑ₂′ represent, at each occurrence identically or differently, mono-substitution, multiple substitutions or non-substitution;
Rₜₐ′, R_{tb}′, R_{tc}′, R_{td}′, Rₜₑ′, Rₜₑ₁′, and Rₜₑ₂′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atom is, substituted or unsubstituted arylalkyl having to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BRₜ″Rₜ″, and combinations thereof;
Rₜ″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₜₐ′, R_{tb}′, R_{tc}′, R_{td}′, Rₜₑ′, Rₜₑ₁′, and Rₜₑ₂′ can be optionally joined to form a ring.

5. The organic electroluminescent device according to claim 4, wherein Rₜₐ′, R_{tb}′, R_{tc}′, R_{td}′, Rₜₑ′, Rₜ″, Rₜₑ₁′, and Rₜₑ₂′ are, at each occurrence identically or differently, selected from the group consisting of: hydrogen, deuterium, halogen, a cyano group, a hydroxyl group, a sulfanyl group, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, substituted or unsubstituted aryl having 6 to 24 carbon atoms, substituted or unsubstituted heteroaryl having 3 to 12 carbon atoms, substituted or unsubstituted alkylsilyl having 3 to 6 carbon atoms, substituted or unsubstituted arylsilyl having 6 to 12 carbon atoms, substituted or unsubstituted alkylgermanyl having 3 to 6 carbon atoms, substituted or unsubstituted arylgermanyl having 6 to 12 carbon atoms, substituted or unsubstituted amino having 0 to 12 carbon atoms, and combinations thereof:
preferably, Rₜₐ′, R_{tb}′, R_{tc}′, R_{td}′, Rₜₑ′, Rₜ″, Rₜₑ₁′, and Rₜₑ₂′ are, at each occurrence identically or differently, selected from the group consisting of: hydrogen, deuterium, fluorine, cyano, hydroxyl, sulfanyl, methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, tetraphenyl, triphenylene, tetraphenylene, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, diphenylamino, dibenzofurylphenylamino, and combinations thereof.

6. The organic electroluminescent device according to claim 4, wherein at least one of Rₜₐ′, R_{tb}′, R_{tc}′, R_{td}′, Rₜₑ′, Rₜ″, Rₜₑ₁′, and Rₜₑ₂′ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, at least one of Rₜₐ′, R_{tb}′, R_{tc}′, R_{td}′, Rₜₑ′, Rₜ″, Rₜₑ₁′, and Rₜₑ₂′ is, at each occurrence identically or differently, selected from the group consisting of deuterium, halogen, a cyano group, a hydroxyl group, a sulfanyl group, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, substituted or unsubstituted aryl having 6 to 24 carbon atoms, substituted or unsubstituted heteroaryl having 3 to 12 carbon atoms, substituted or unsubstituted alkylsilyl having 3 to 6 carbon atoms, substituted or unsubstituted arylsilyl having 6 to 12 carbon atoms, substituted or unsubstituted alkylgermanyl having 3 to 6 carbon atoms, substituted or unsubstituted arylgermanyl having 6 to 12 carbon atoms, substituted or unsubstituted amino having 0 to 12 carbon atoms, and combinations thereof;
more preferably, at least one of Rₜₐ′, R_{tb}′, R_{tc}′, R_{td}′, Rₜₑ′, Rₜ″, Rₜₑ₁′, and Rₜₑ₂′ is, at each occurrence identically or differently, selected from the group consisting of deuterium, fluorine, cyano, hydroxyl, sulfanyl, methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, tetraphenyl, triphenylene, tetraphenylene, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, diphenylamino, dibenzofurylphenylamino, and combinations thereof.

7. The organic electroluminescent device according to claim 1, wherein the fluorescent emissive material is selected from the group consisting of Compound BD-1 to Compound BD-54: 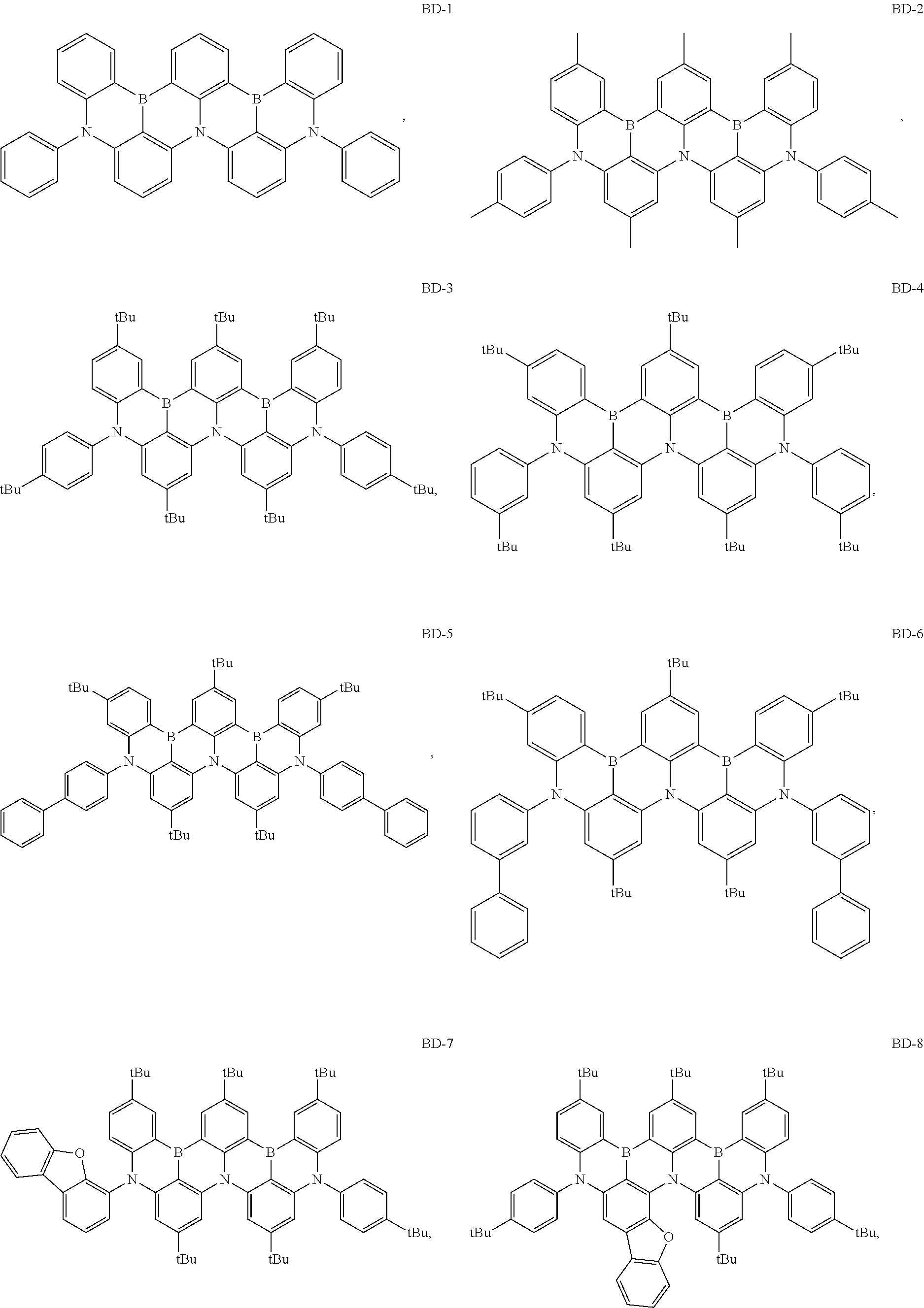 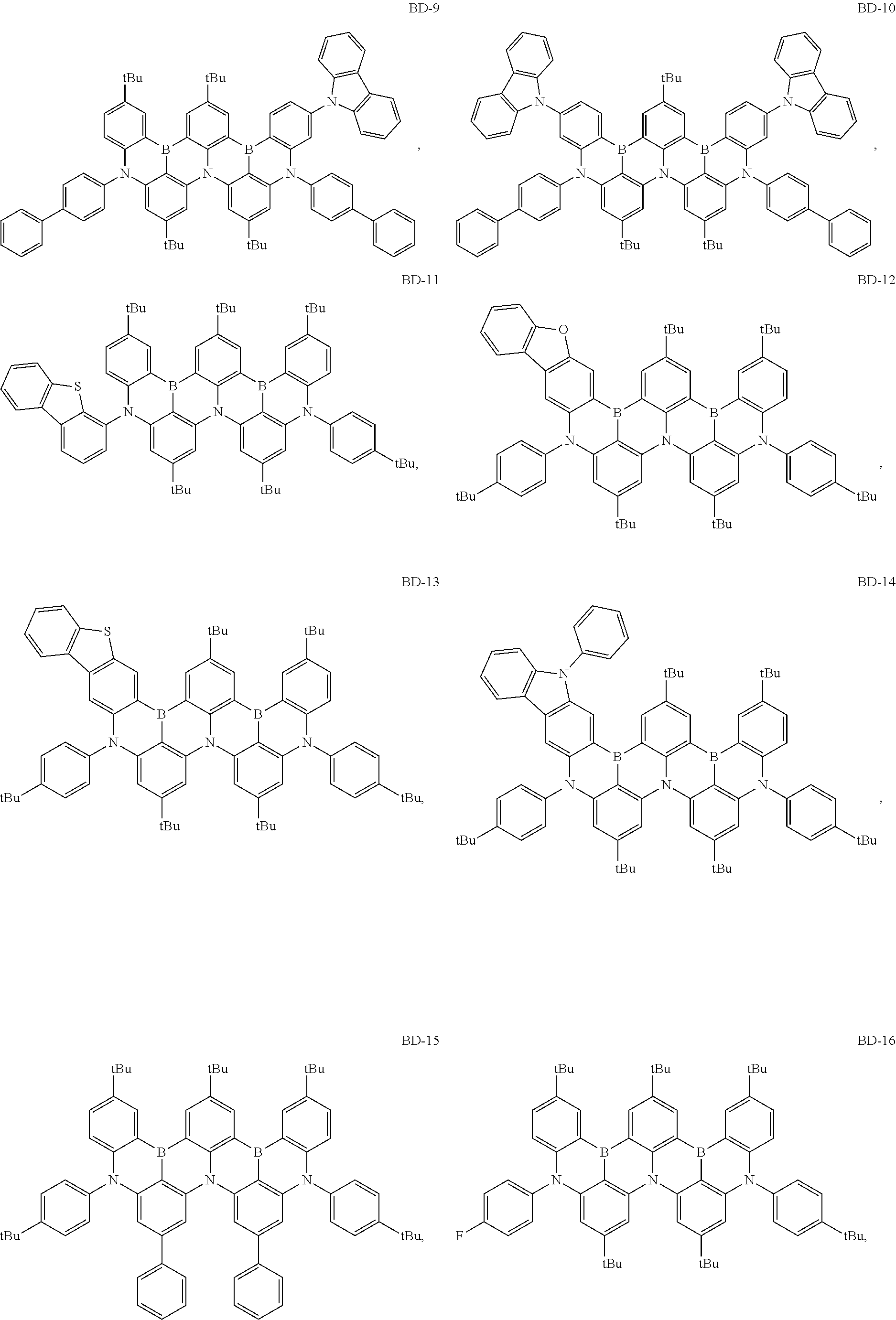 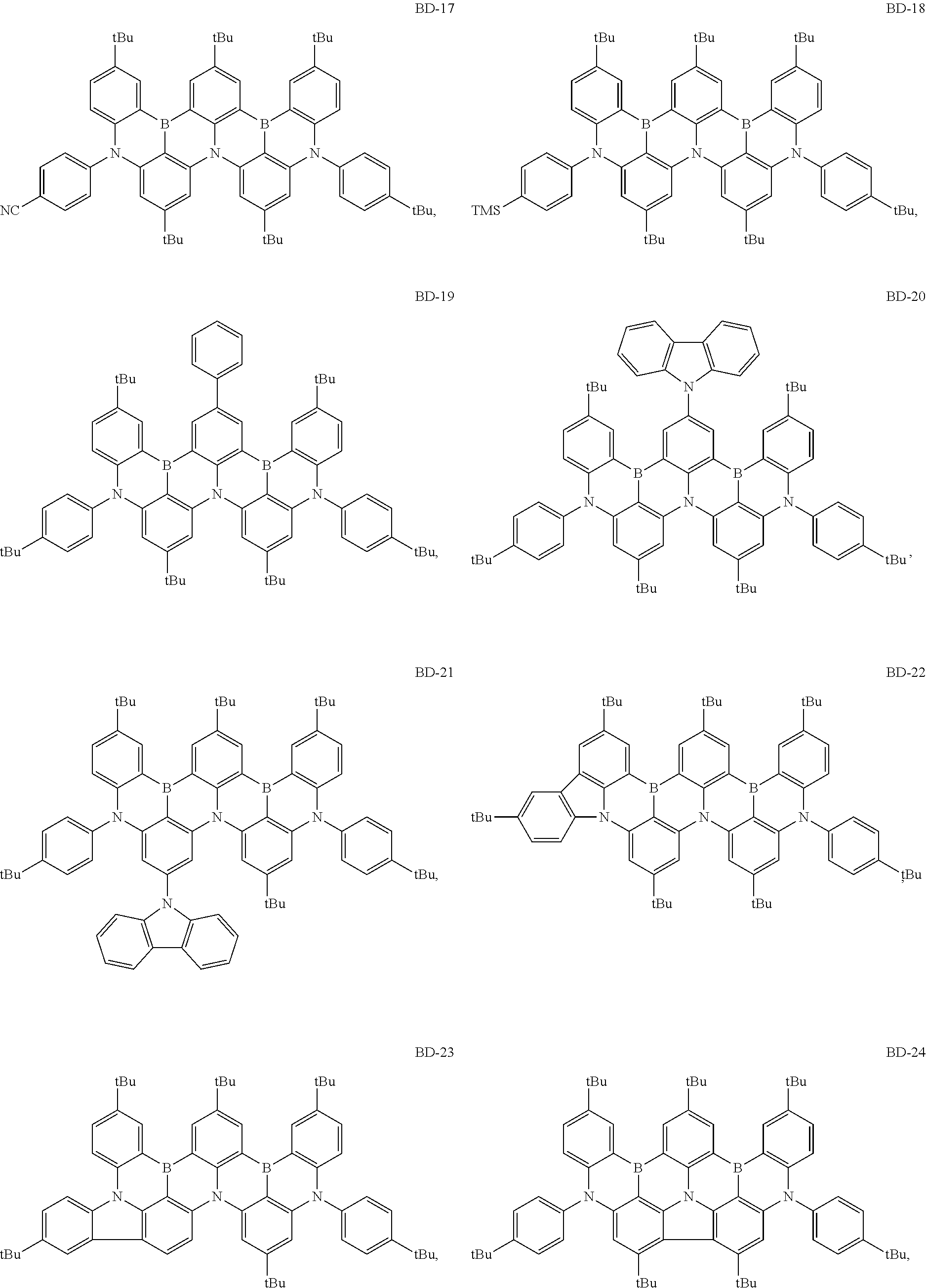 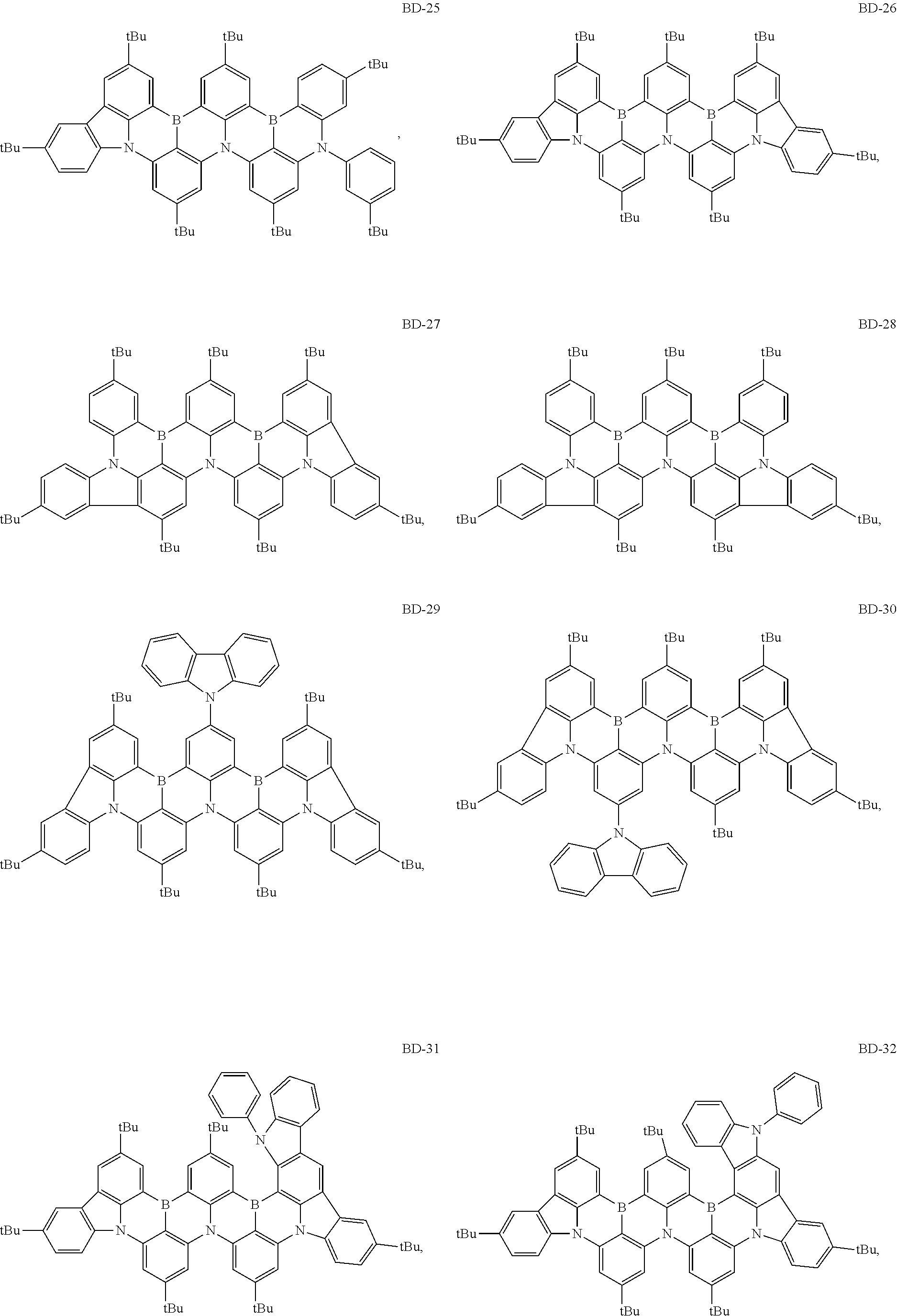 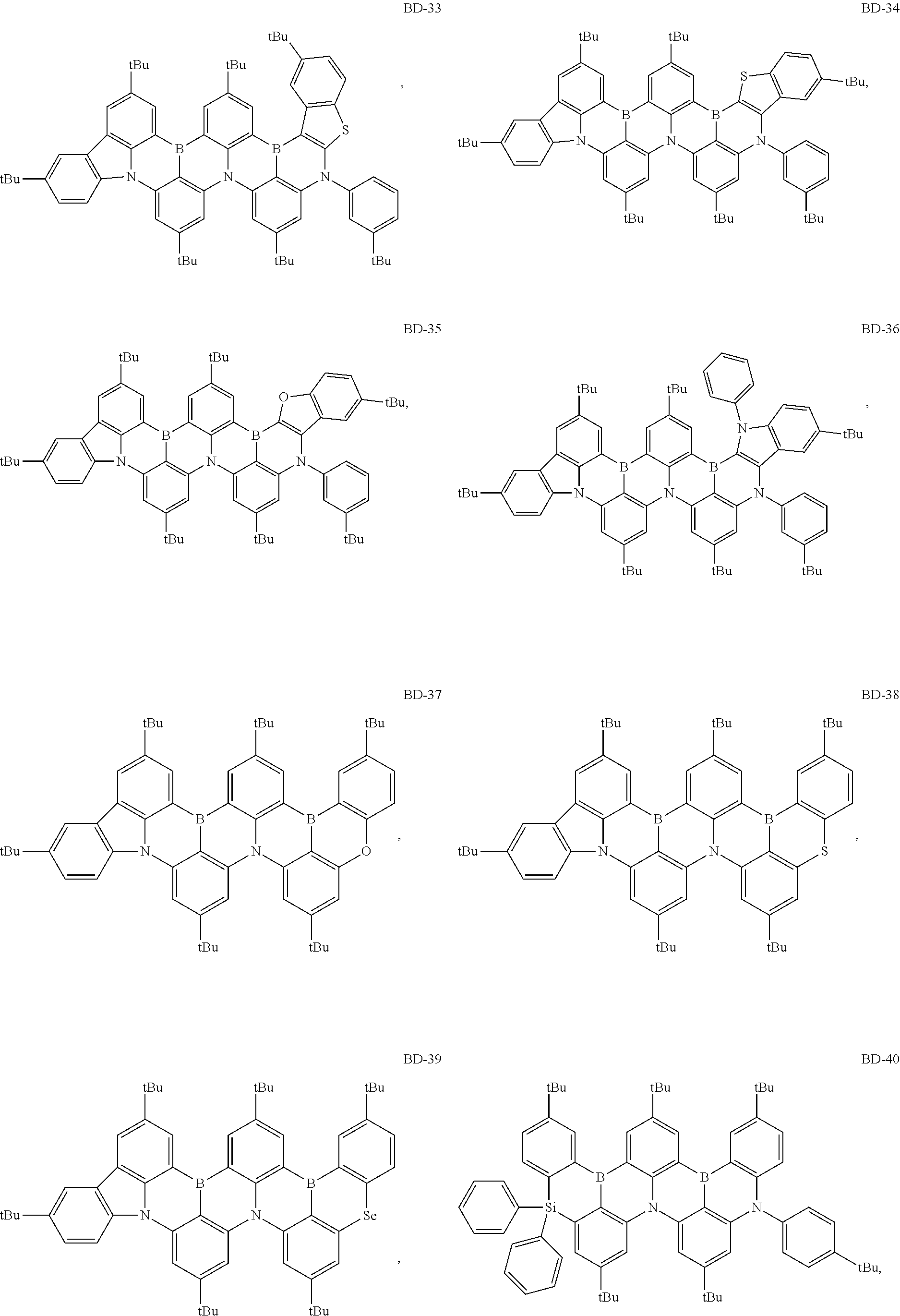 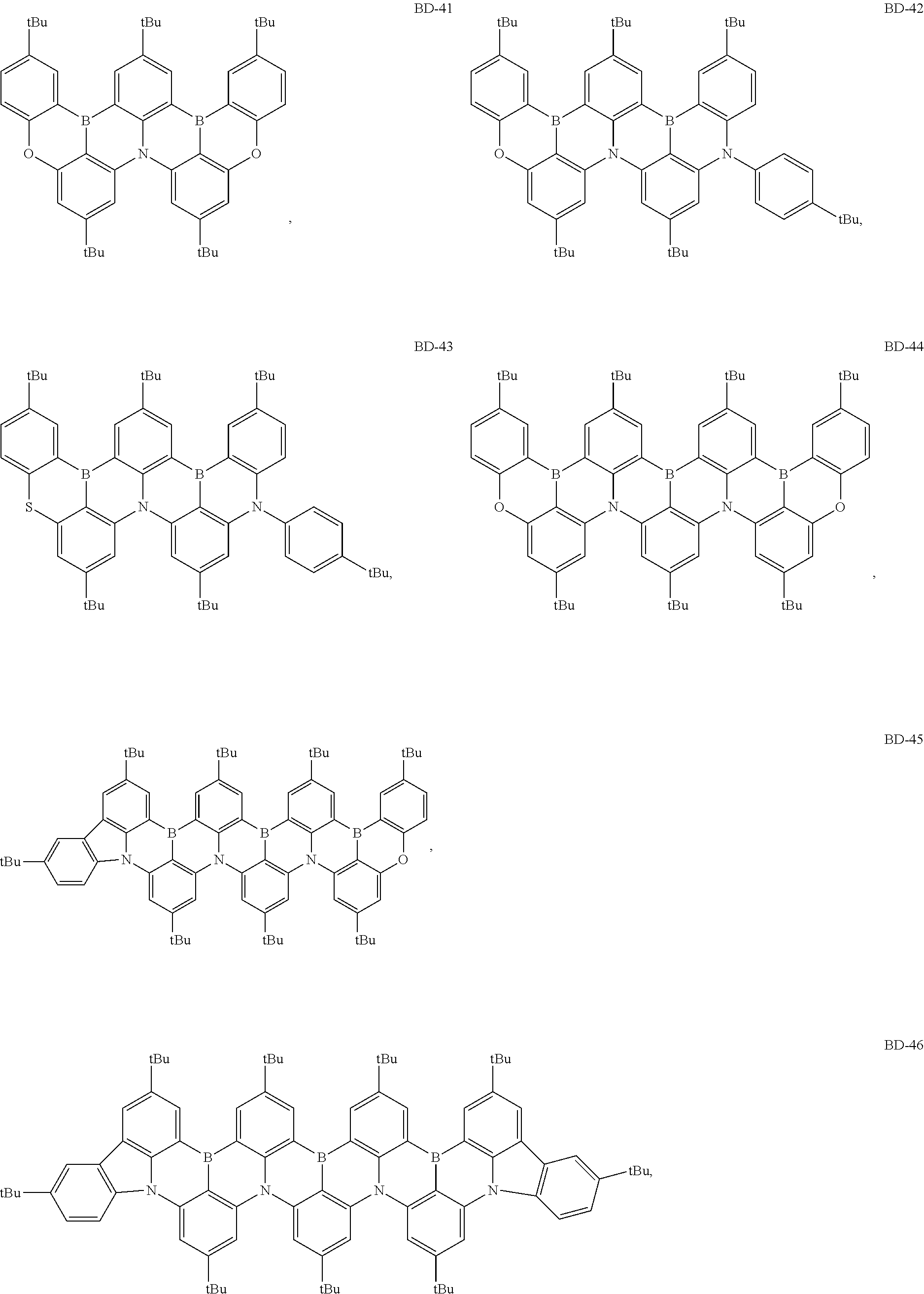 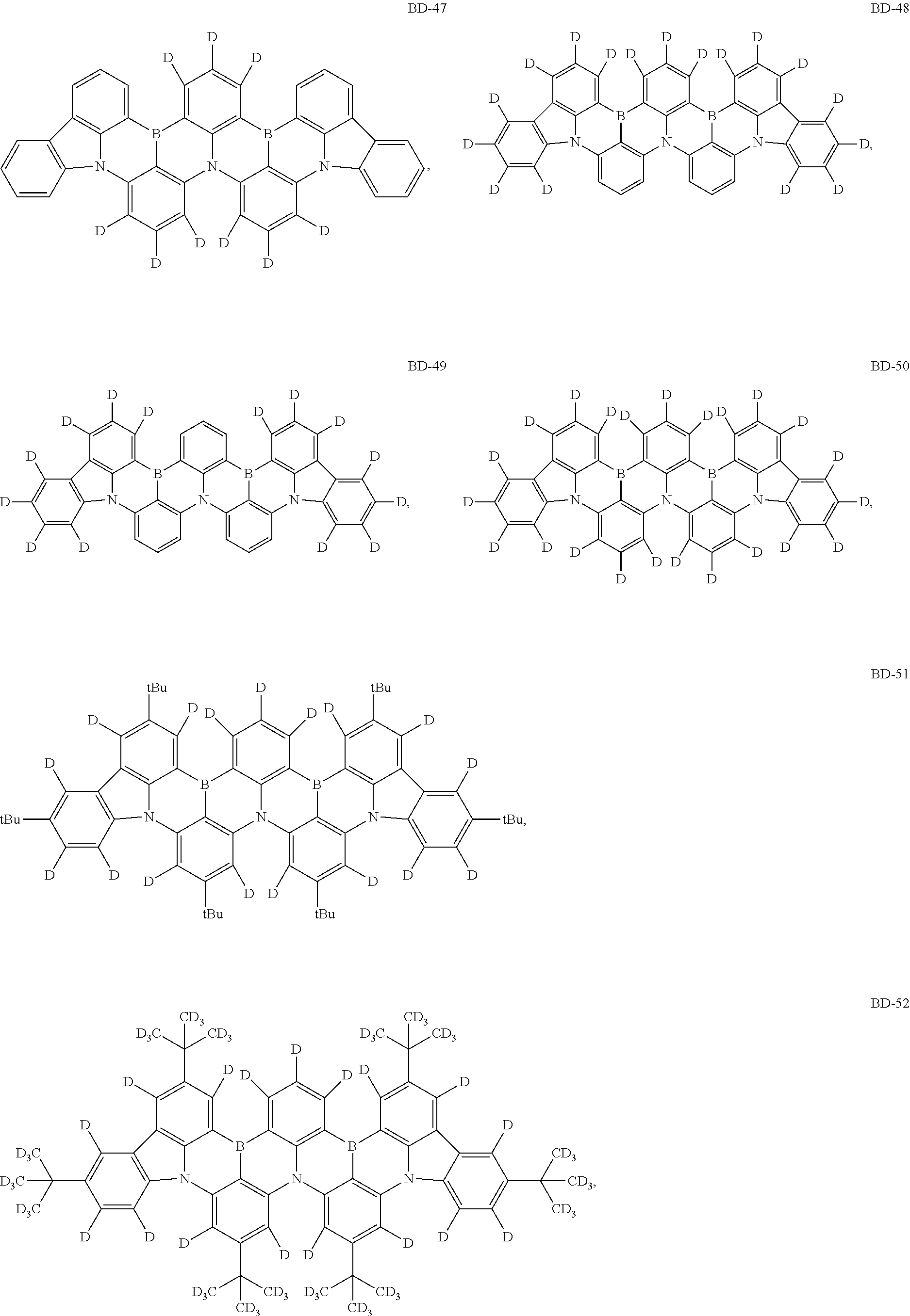 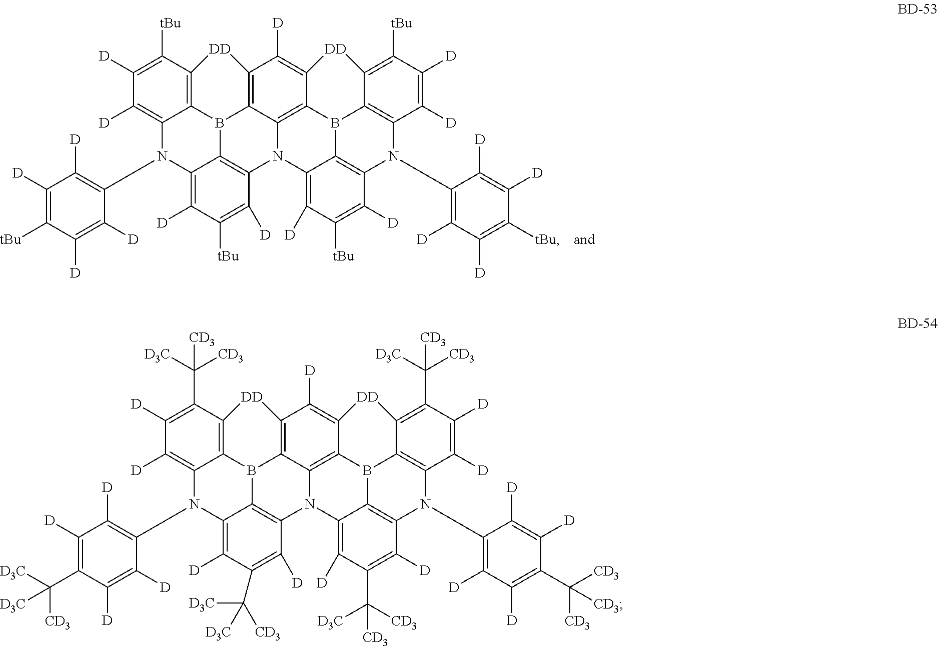
wherein -tBu represents t-butyl;
optionally, hydrogens in Compound BD-1 to Compound BD-54 can be partially or fully substituted with deuterium.

8. The organic electrolumuinescent device according to claim 1, wherein the metal complex has a general formula of M(Lₐ)ₘ(L_{b})ₙ(L_{c})_{q}, Lₐ, L_{b}, and L_{c} are a first ligand, a second ligand, and a third ligand coordinated to the metal M, respectively, and Lₐ is the same as or different from L_{c} or L_{b}; wherein Lₐ, L_{b}, and L_{c} can be optionally joined to form a multidentate ligand;
the metal M is selected from a metal with a relative atomic mass greater than 40; preferably, the metal M is selected from the group consisting of Cu, Ag, Au, Ru, Rh, Pd, Os, Ir, and Pt; more preferably, the metal M is selected from Pt or Ir;
m is selected from 1, 2 or 3, n is selected from 0, 1 or 2, q is selected from 0, 1 or 2, and m+n+q is equal to an oxidation state of the metal M; when m is greater than or equal to 2, a plurality of Lₐ are the same or different; when n is equal to 2, two L_{b} are the same or different; when q is equal to 2, two L_{c} are the same or different;
L_{b} and L_{c} are, at each occurrence identically or differently selected from a structure represented by any one of the group consisting of: 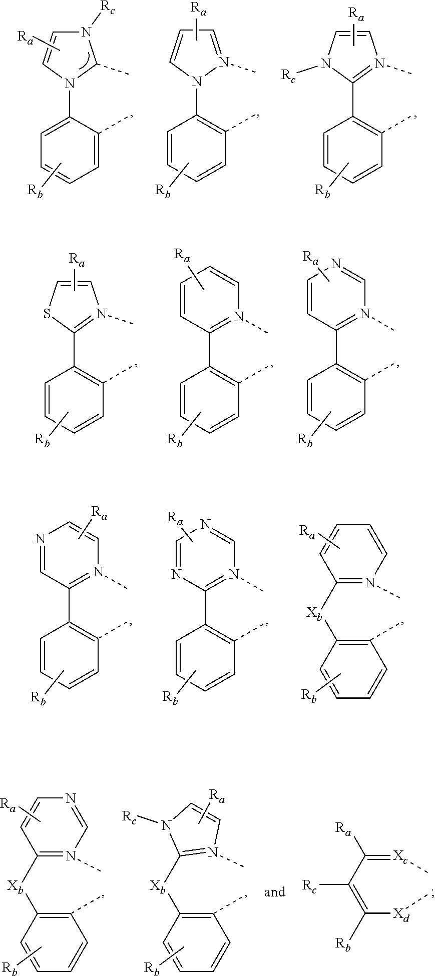
wherein,
X_{b} is, at each occurrence identically or differently selected from the group consisting of: O, S, Se, NR_{N1}, and CR_{C1}R_{C2};
X_{c} and X_{d} are, at each occurrence identically or differently, selected from the group consisting of O, S, Se, and NR_{N2};
Rₐ and R_{b} represent, at each occurrence identically or differently, mono-substitution, multiple substitutions or non-substitution;
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ, R_{b}, R_{c}, R_{N1}, R_{N2}, R_{C1} and R_{C2} can be optionally joined to form a ring.

9. The organic electroluminescent device according to claim 8, wherein the metal complex has a general structure of Ir(Lₐ)ₘ(L_{b})₃₋ₘ and has a structure represented by Formula M-a: 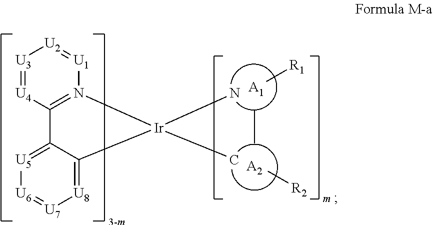
wherein,
m is selected from 1, 2 or 3; when m is selected from 1, two L_{b} are the same or different; when in is selected from 2 or 3, a plurality of Lₐ are the same or different;
the ring A₁ is selected from a heteroaromatic ring having 5 to 30 ring atoms;
the ring A₂ is selected from an aromatic ring having 6 to 30 ring atoms, a heteroaromatic ring having 5 to 30 ring atoms or a combination thereof;
U₁ to U₈ are, at each occurrence identically or differently, selected from CRᵤ or N;
R₁ and R₂ represent, at each occurrence identically or differently, mono-substitution, multiple substitutions or non-substitution;
R₁, R₂, and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alknyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
when the ring A₁ is selected from a pyridine ring and the ring A₂ is selected from a benzene ring, at least one of R₁ and R₂ is selected from deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alknyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, or a combination thereof;
adjacent substituents R₁, R₂, and Rᵤ can be optionally joined to form a ring.

10. The organic electroluminescent device according to claim 9, wherein the ring A₁ is, at each occurrence identically or differently, selected from any one of the following structures: 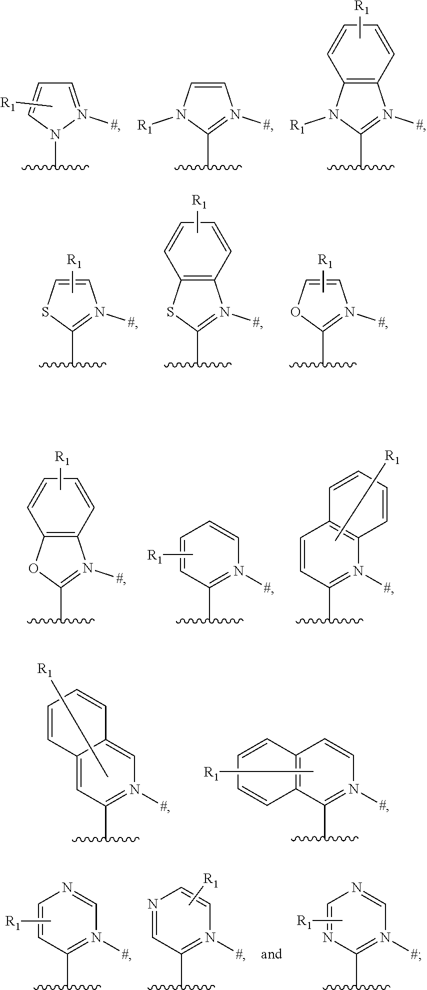
the ring A₂ is, at each occurrence identically or differently selected from any one of the following structures: 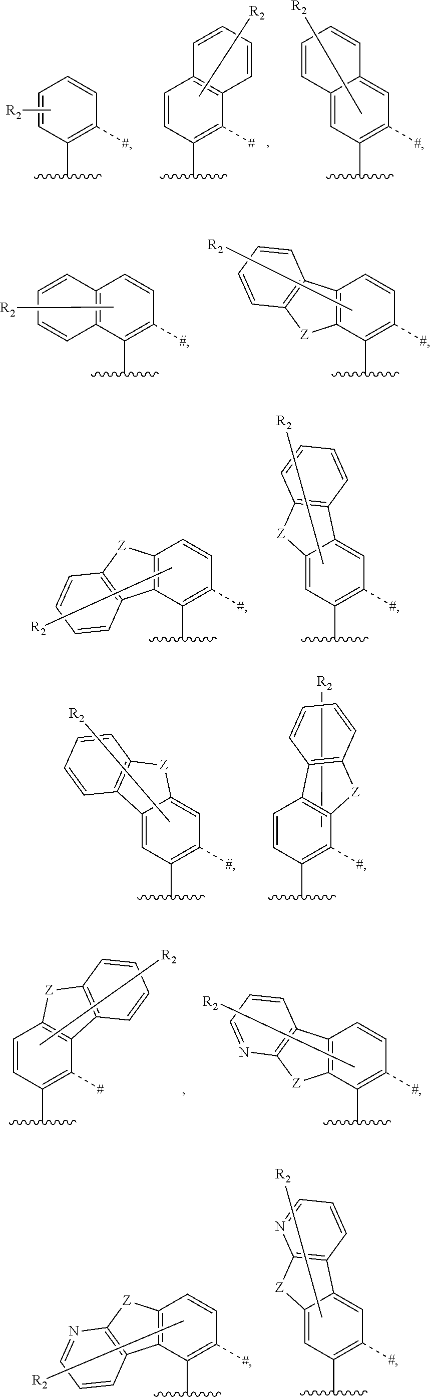 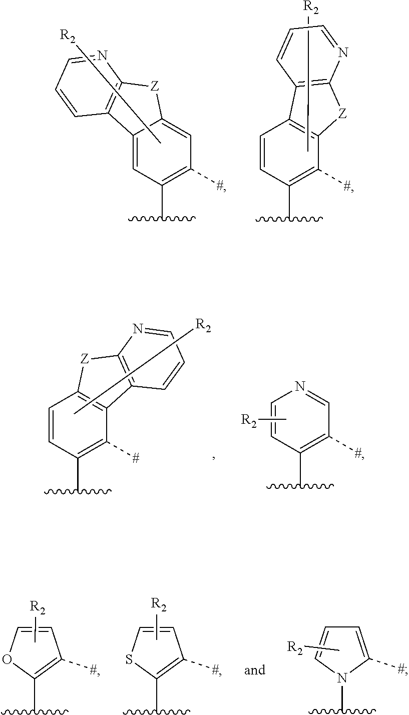
wherein
Z is selected from the group consisting of O, S, Se, NR, CRR, SiRR, and GeRR;
R₁ and R₂ represent, at each occurrence identically or differently, mono-substitution, multiple substitutions or non-substitution; when a plurality of R₁ or R₂ are present in any structure, the plurality of R₁ or R₂ are the same or different;
R₁, R₂ and R are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₂ and R can be optionally joined to form a ring;
“™” represents a position where the metal Ir is joined, and 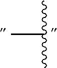
represents a position where the ring A₁ or the ring A₂ is joined;
preferably, the ring A₁ is, at each occurrence identically or differently, selected from 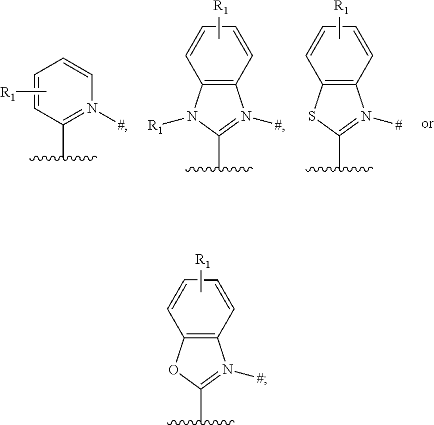
the ring A₂ is selected from

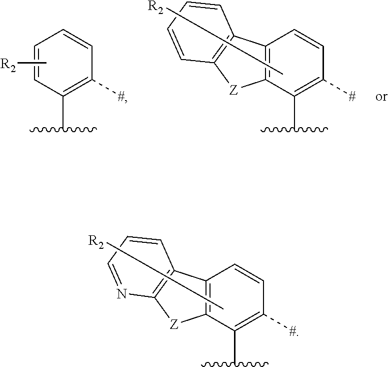

11. The organic electroluminescent device according to claim 8, wherein the metal complex has a general structure of Ir(Lₐ)ₘ(L_{b})₃₋ₘ and has a structure represented by Formula M-a-0: 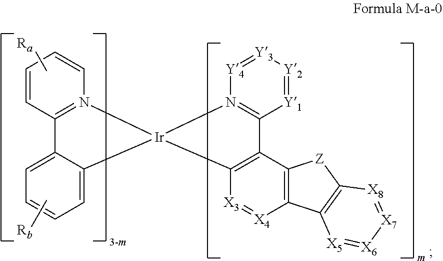
wherein,
m is selected from 1, 2 or 3; when m is selected from 1, two L_{b} are the same or different; when in is selected from 2 or 3, two or three L₁ are the same or different;
Z is selected from the group consisting of O, S, Se, NR, CRR, SiRR, and GeRR; when a plurality of R are present at the same time, the plurality of R are the same or different;
X₃ to X₈ are, at each occurrence identically or differently, selected from CR′₂ or N;
Y′₁ to Y′₄ are, at each occurrence identically or differently, selected from CR′₁ or N;
Rₐ and R_{b} represent, at each occurrence identically or differently, mono-substitution, multiple substitutions or non-substitution;
R′₁, R′₂, R, Rₐ, and R_{b}, are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alknyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R′₁, R′₂, R, Rₐ, and R_{b} can be optionally joined to form a ring.

12. The organic electroluminescent device according to claim 11, wherein Z is selected from O, S, Se, NR or CRR; preferably, Z is selected from O or S.

13. The organic electroluminescent device according to claim 11, wherein Y′₁ to Y′₄ are, at each occurrence identically or differently, selected from CR′₁, X₃ to X₇ are, at each occurrence identically or differently, selected from CR′₂, and X₈ is selected from N or CR₂; R′₁ and R′₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group, and combinations thereof.

14. The organic electroluminescent device according to claim 11, wherein at least one of X₃ to X₈ is CR′₂, and R′₂ is selected from a cyano group or fluorine;
preferably, X₇ is selected from CR′₂, and R′₂ is selected from a cyano group or fluorine; or X₈ is selected from CR′₂, and R′₂ is selected from a cyano group.

15. The organic electroluminescent device according to claim 1, wherein the metal complex has a structure represented by Formula M-b: 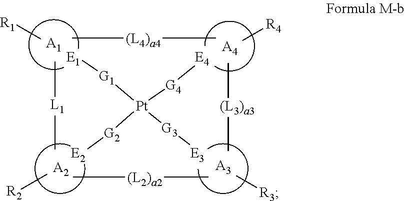
wherein the ring A₁ to the ring A₄ are, at each occurrence identically or differently, selected from an aromatic ring having 6 to 30 ring atoms, a heteroaromatic ring having 5 to 30 ring atoms or a combination thereof;
E₁ to E₄ are, at each occurrence identically or differently, selected from C or N;
G₁ to G₄ are, at each occurrence identically or differently, selected from a single bond, O, S or NR′;
L₁ to L₄ are, at each occurrence identically or differently, selected from the group consisting of: a single bond, BR″, CR″R′, NR″, O, SiR″R″, PR″, S, GeR″R″, Se, substituted or unsubstituted vinylene, ethynylene, substituted or unsubstituted arylene having 6 to 30 carbon atoms, substituted or unsubstituted heteroarylene having 3 to 30 carbon atoms, and combinations thereof; when two R″ are present at the same time, the two R″ are the same or different;
a₂ to a₄ are, at each occurrence identically or differently, selected from 0 or 1, and at least one of a₂ to a₄ is selected from 1;
R₁ to R₄ represent, at each occurrence identically or differently, mono-substitution, multiple substitutions or non-substitution;
R₁ to R₄, R′, and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ to R₄, R′, and R″ can be optionally joined to form a ring.

16. The organic electroluminescent device according to claim 1, wherein the metal complex has a structure represented by Formula M-b-1: 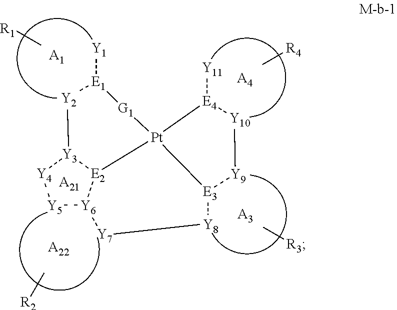
wherein,
the ring A₁, the ring A₂₂, the ring A₃, and the ring A₄ are, at each occurrence identically or differently, selected from an aromatic ring having 6 to 30 ring atoms, a heteroaromatic ring having 5 to 30 ring atoms or a combination thereof;
the ring A₂₁ is selected from a heteroaromatic ring having 5 ring atoms;
E₁ to E₄ are, at each occurrence identically or differently, selected from C or N;
G₁ is, at each occurrence identically or differently, selected from O or S;
Y₁, Y₄, and Y₁₁ are, at each occurrence identically or differently, selected from CR″′, N, NR″′, O or S;
Y₂, Y₃, and Y₅ to Y₁₀ are, at each occurrence identically or differently, selected from C or N;
R₁ to R₄ represent, at each occurrence identically or differently, mono-substitution, multiple substitutions or non-substitution;
R₁ to R₄ and R″′ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ to R₄ and R″′ can be optionally joined to form a ring.

17. The organic electroluminescent device according to claim 16, wherein G₁ is selected from O;
the ring A₁, the ring A₂₂, the ring A₃, and the ring A₄ are, at each occurrence identically or differently, selected from an aromatic ring having 6 to 18 ring atoms, a heteroaromatic ring having 5 to 18 ring atoms or a combination thereof; the ring A₂₁ is, at each occurrence identically or differently, selected from a heteroaromatic ring having 5 ring atoms;
preferably, in Formula M-b-1, the ring A₁, the ring A₂₂, and the ring A₃ are selected from a benzene ring, the ring A₄ is selected from a pyridine ring, and the ring A₂₁ is selected from an imidazole ring.

18. The organic electroluminescent device according to claim 16, wherein in Formula M-b-1, Y₂, Y₃, and Y₅ to Y₁₀ are, at each occurrence identically or differently, selected from C; Y₁ and Y₁₁ are, at each occurrence identically or differently, selected from CR″′; Y₄ is, at each occurrence identically or differently, selected from NR′″, O or S; R″′ is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
preferably, Y₄ is, at each occurrence identically or differently, selected from NR″ and R′″ is, at each occurrence identically or differently, selected from substituted or unsubstituted aryl having 6 to 30 carbon atoms, substituted or unsubstituted heteroaryl having 3 to 30 carbon atoms or a combination thereof.

19. The organic electroluminescent device according to claim 15, wherein R₁ to R₄ are, at each occurrence identically or differently, selected from the group consisting of: hydrogen, deuterium, halogen, substituted or unsubstituted alkyl having t to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, a hydroxyl group, a sulfanyl group, and combinations thereof;
preferably, at least one R₁, at least one R₂, at least one R₃ or at least one R₄ is, at each occurrence identically or differently, selected from deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, a cyano group or a combination thereof.

20. The organic electroluminescent device according to claim 1, wherein the metal complex is selected from the group consisting of M-a1 to M-a64 and M-b1 to M-b62, and specific structures of M-a1 to M-a64 and M-b1 to M-b62 are as follows:

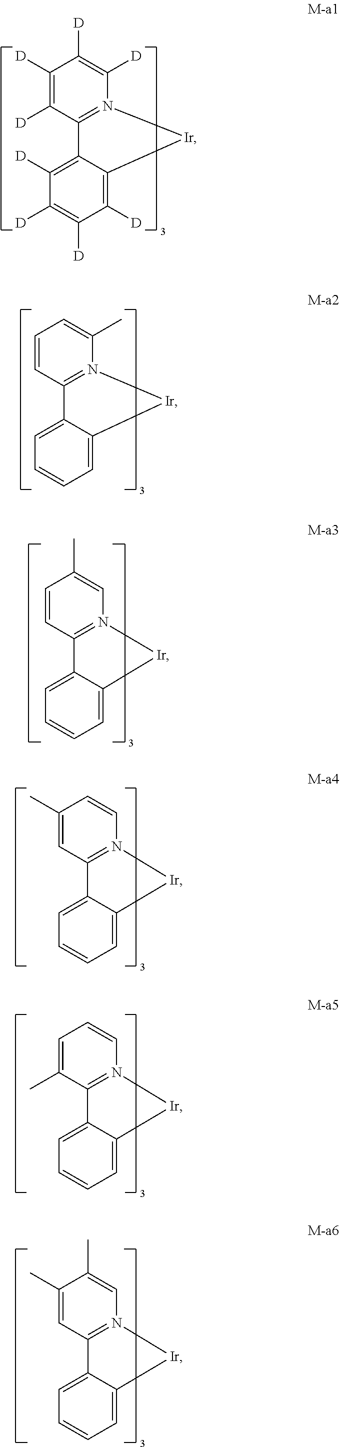

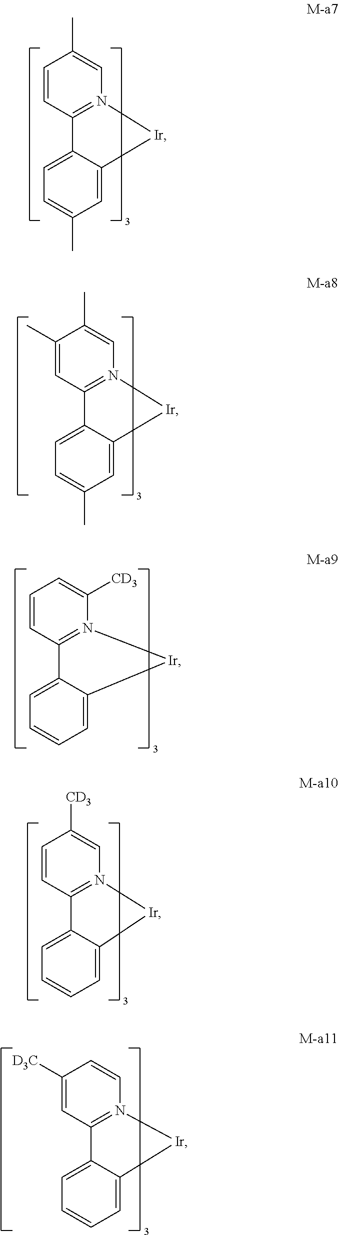

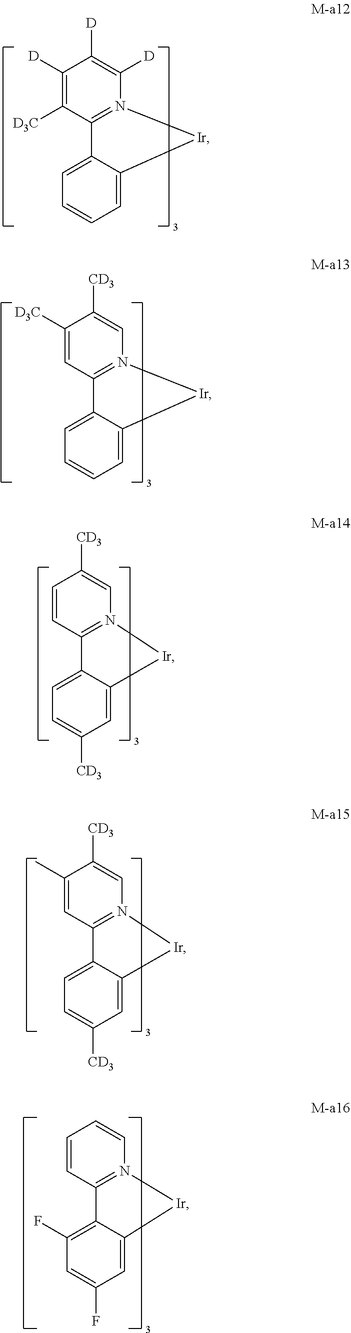

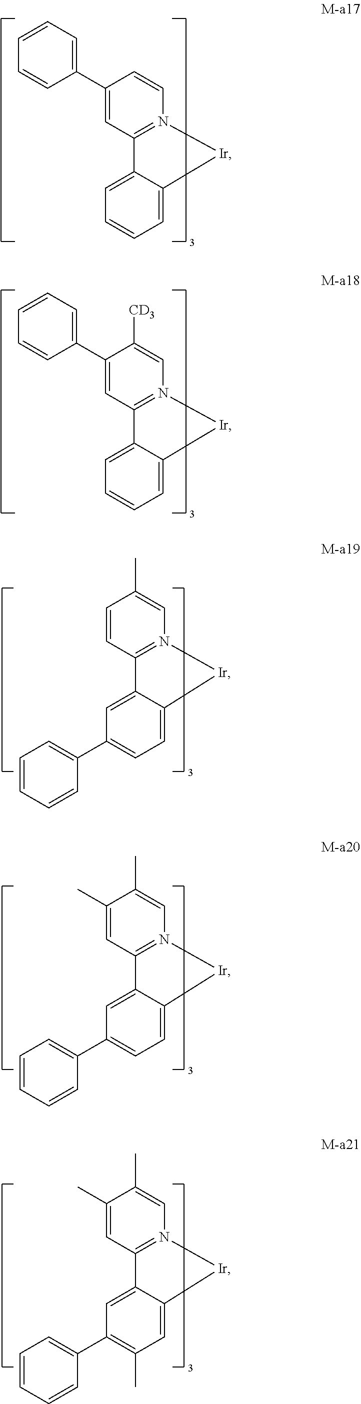

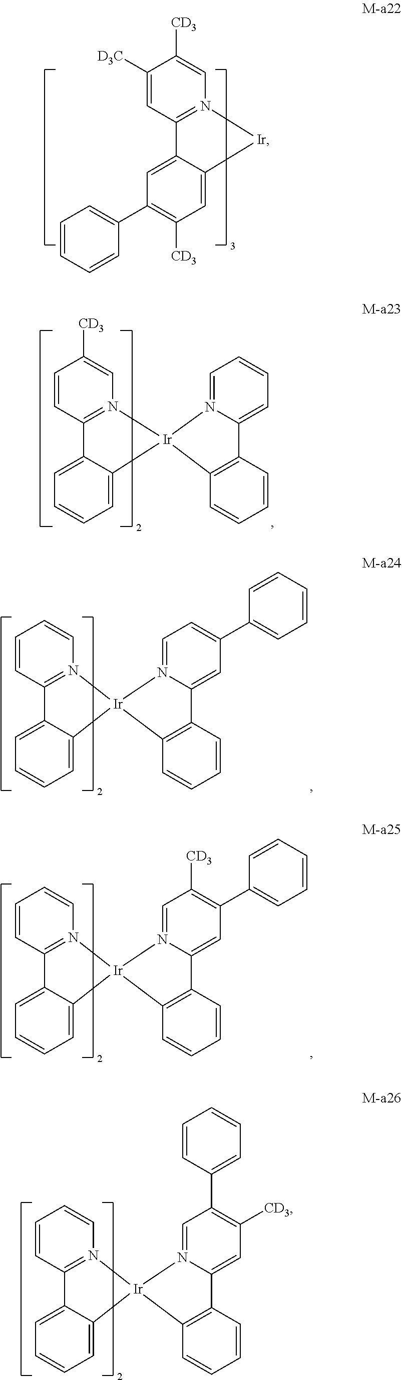

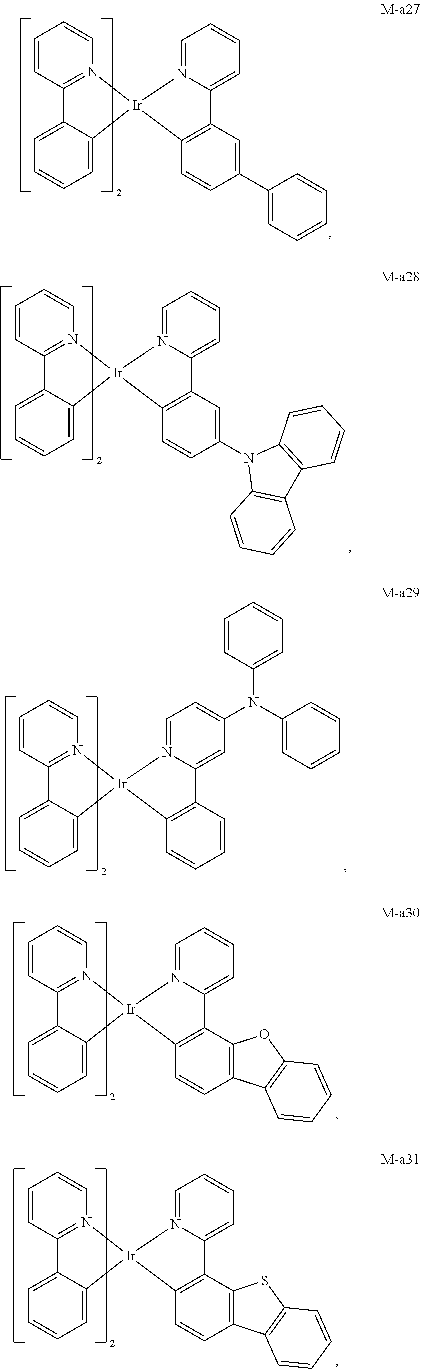

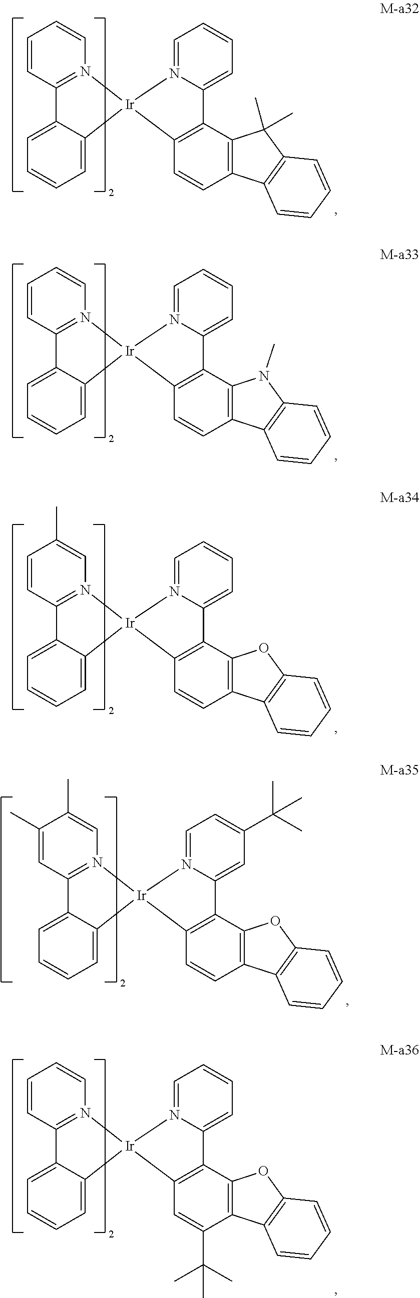

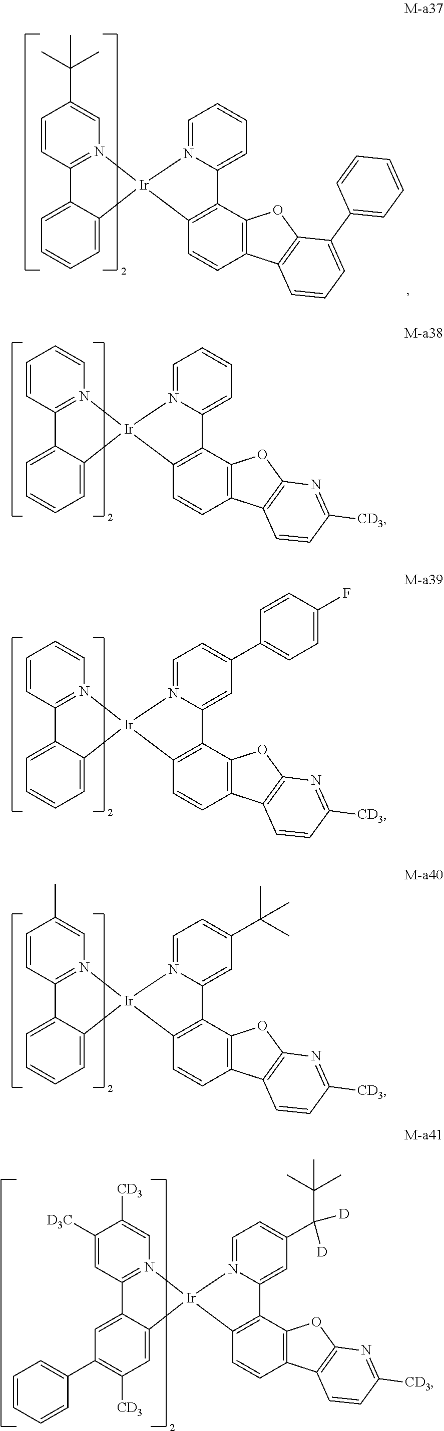

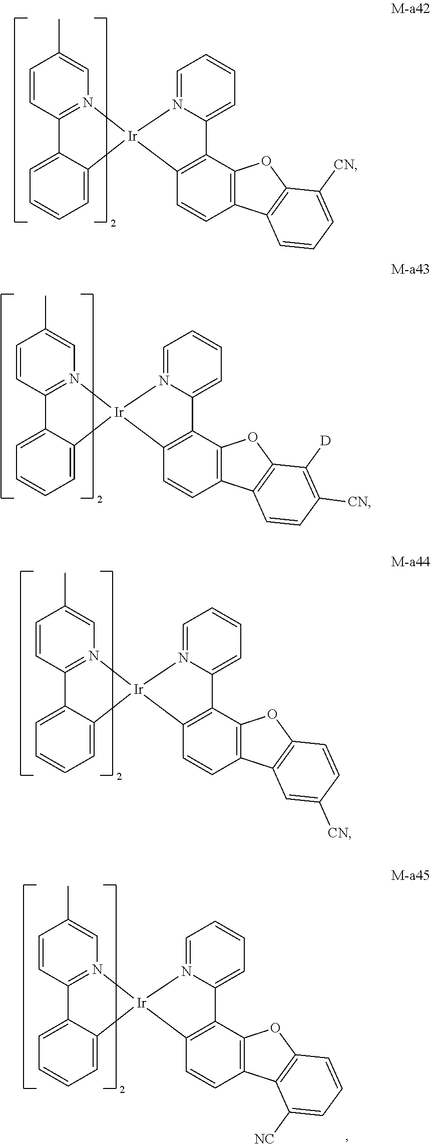

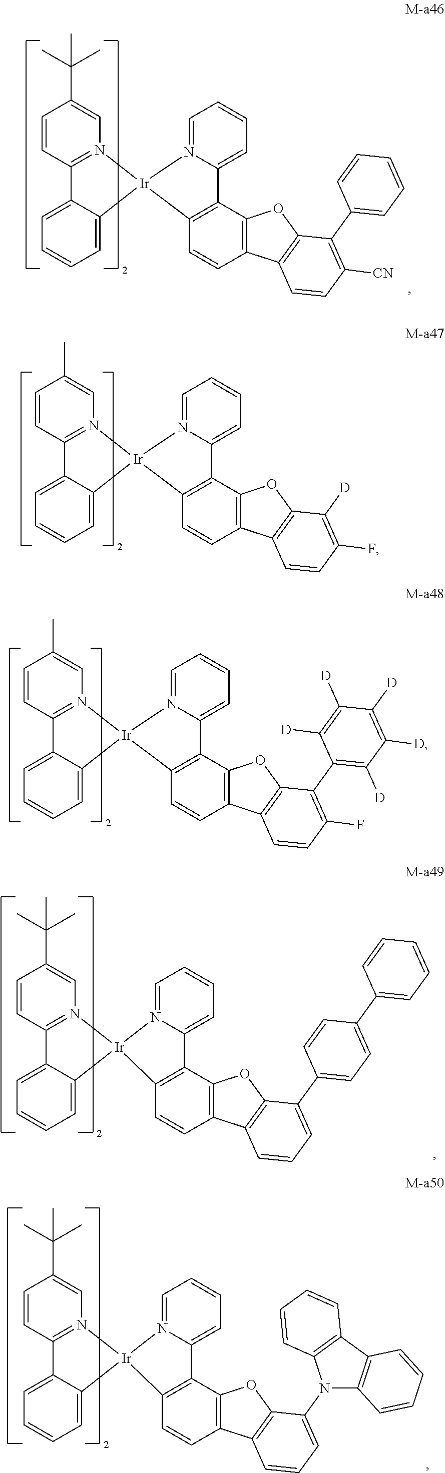

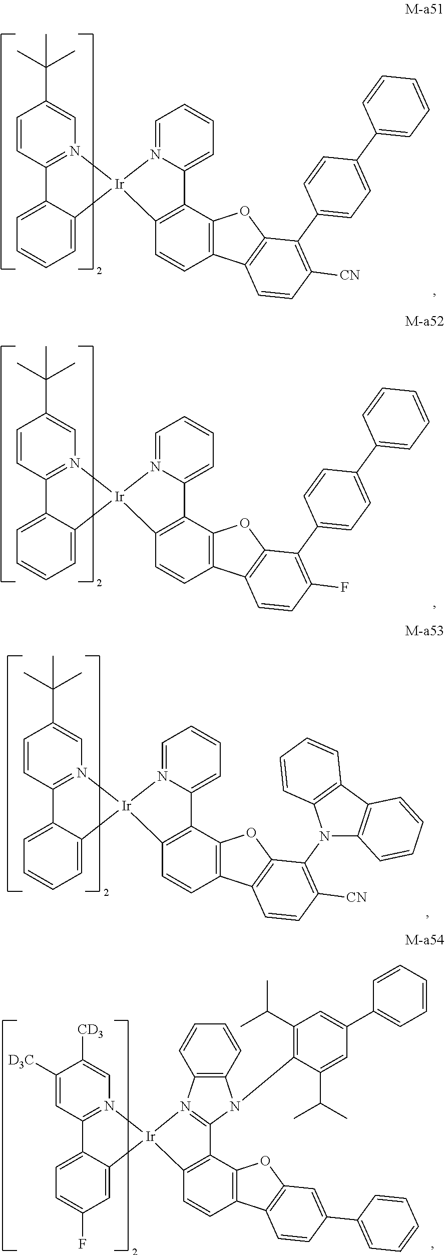

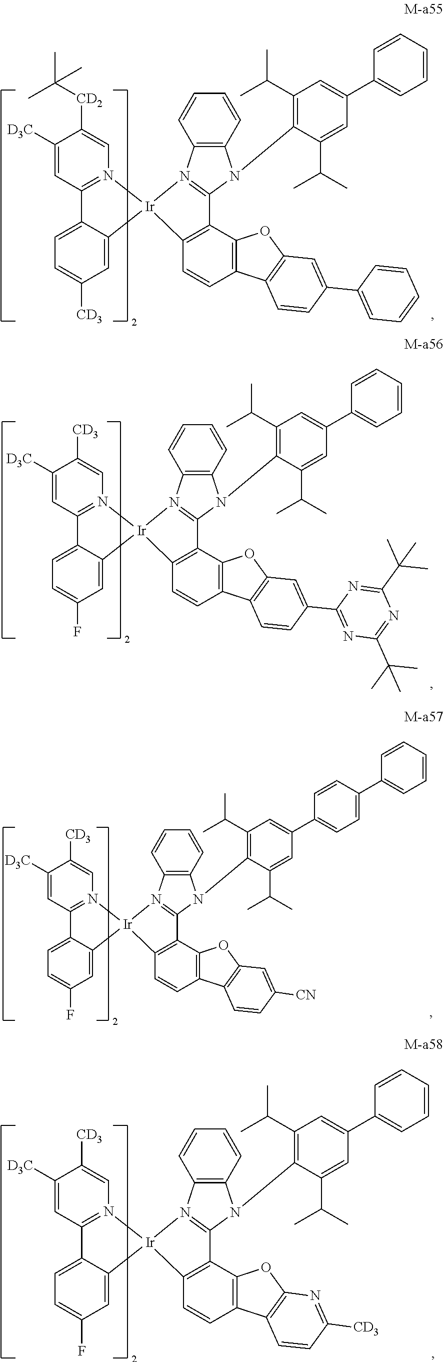

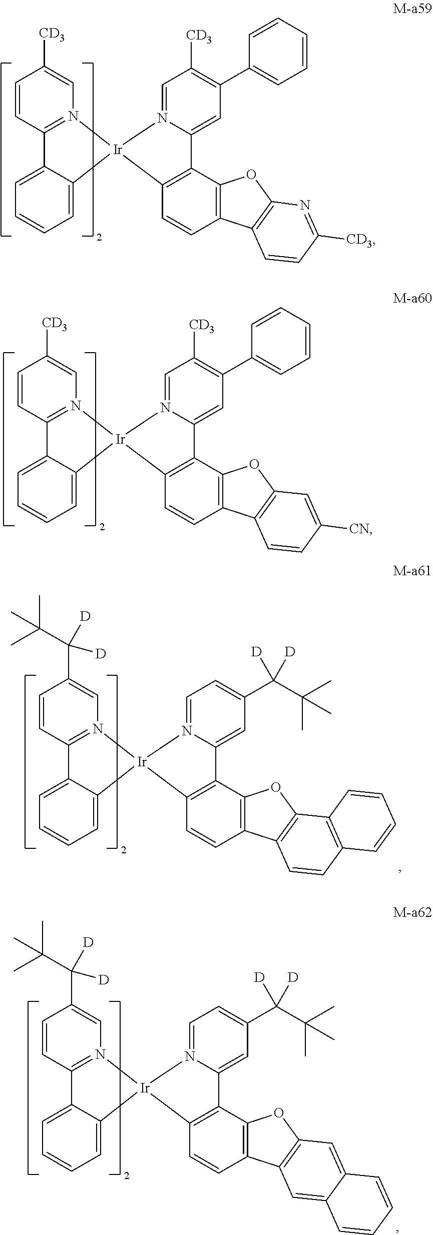

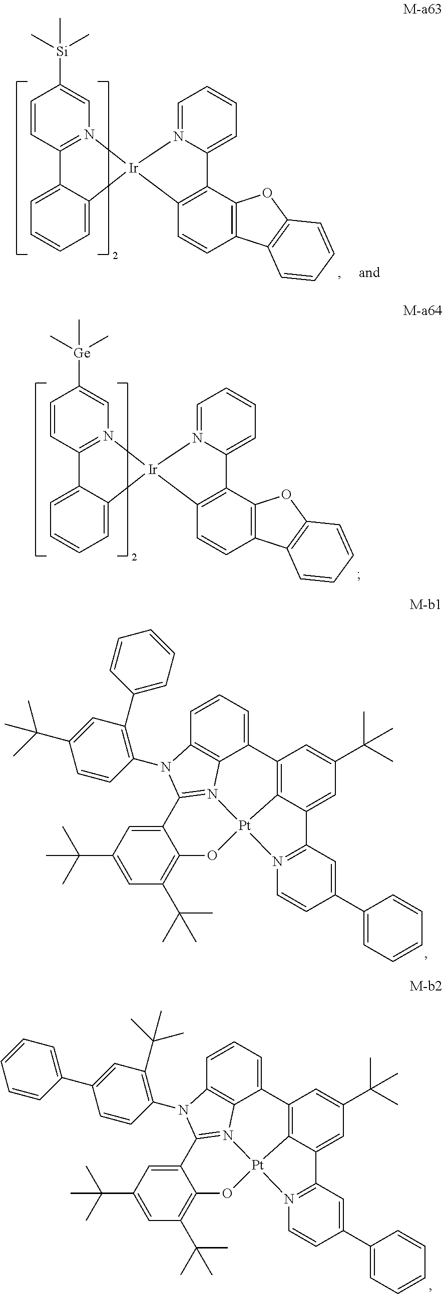

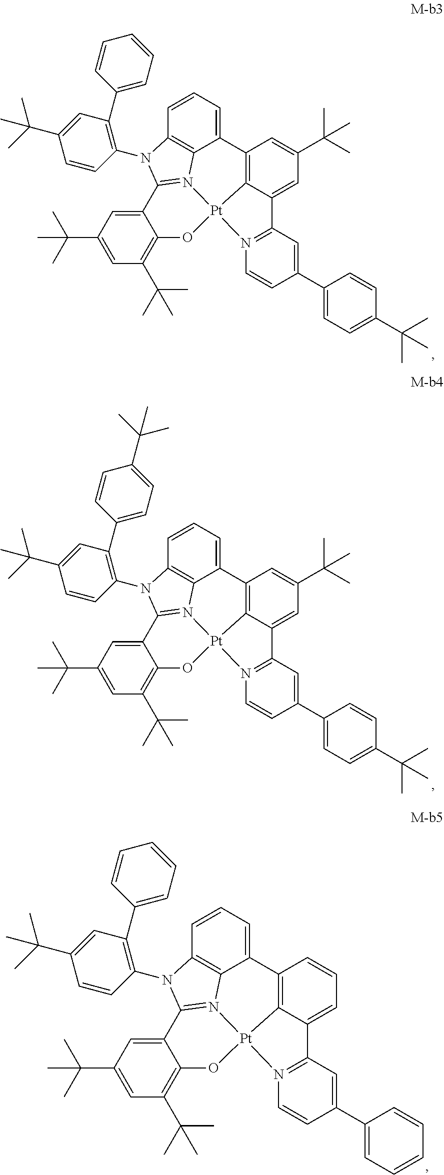

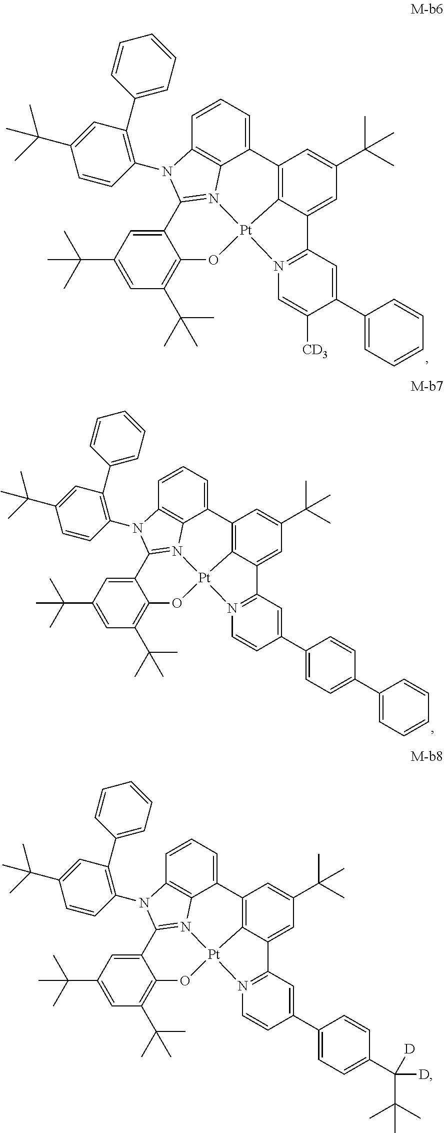

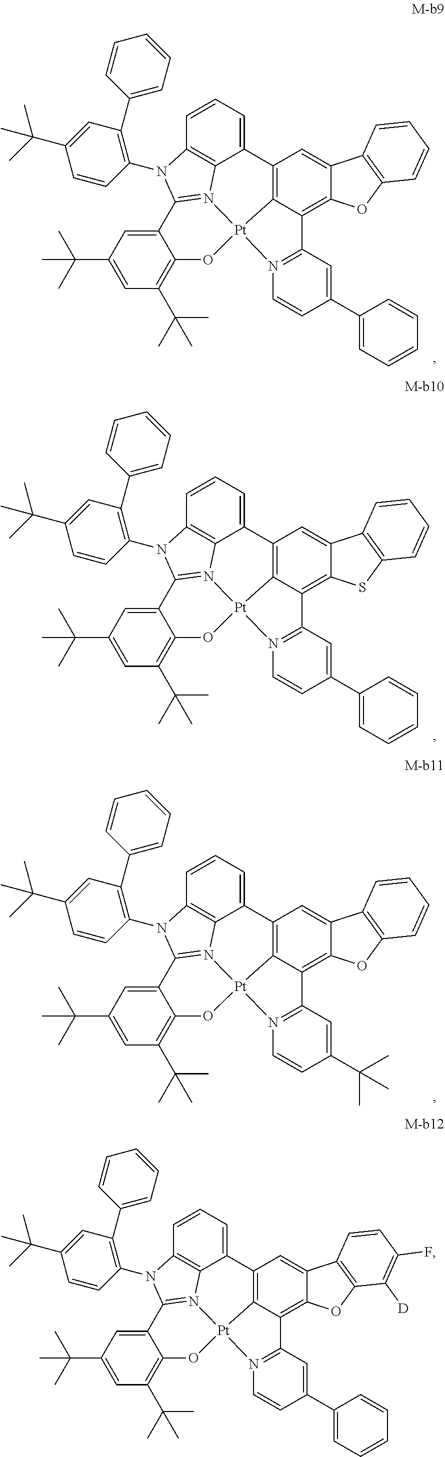

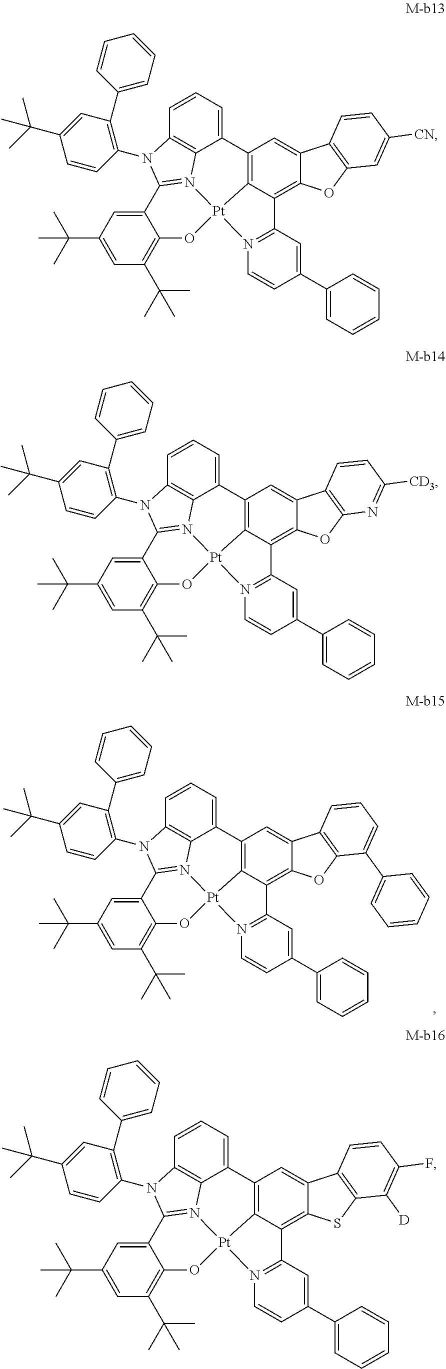

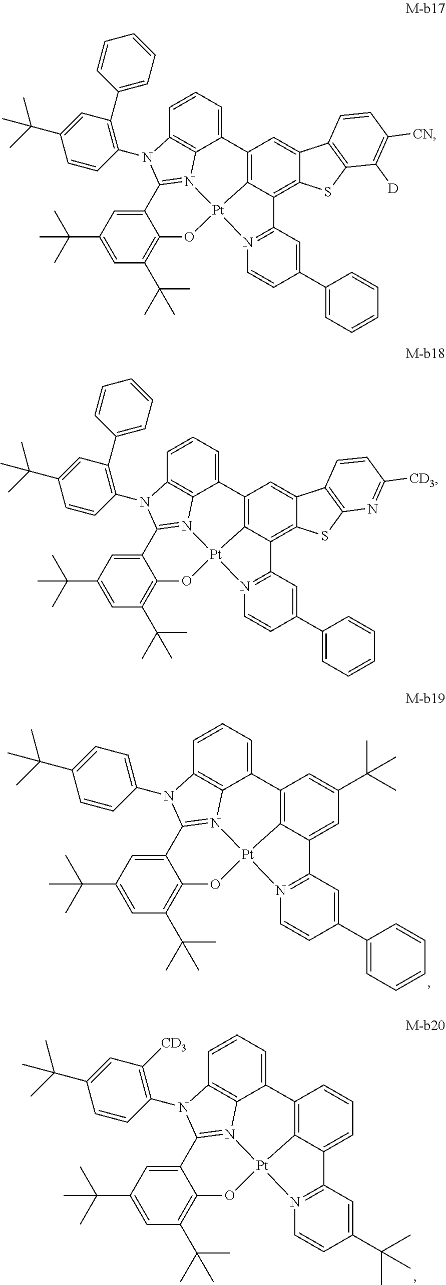

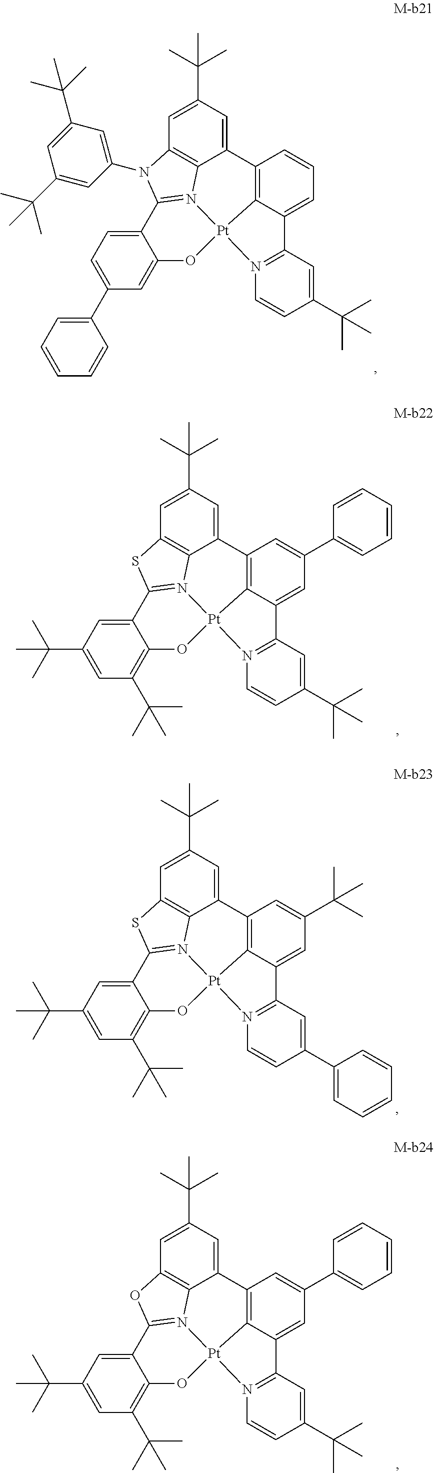

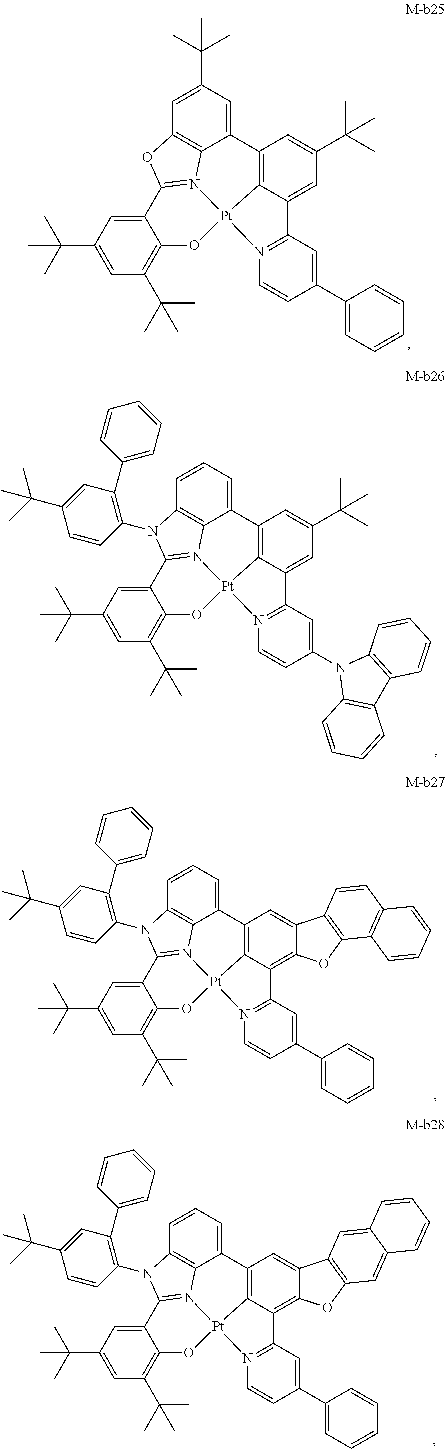

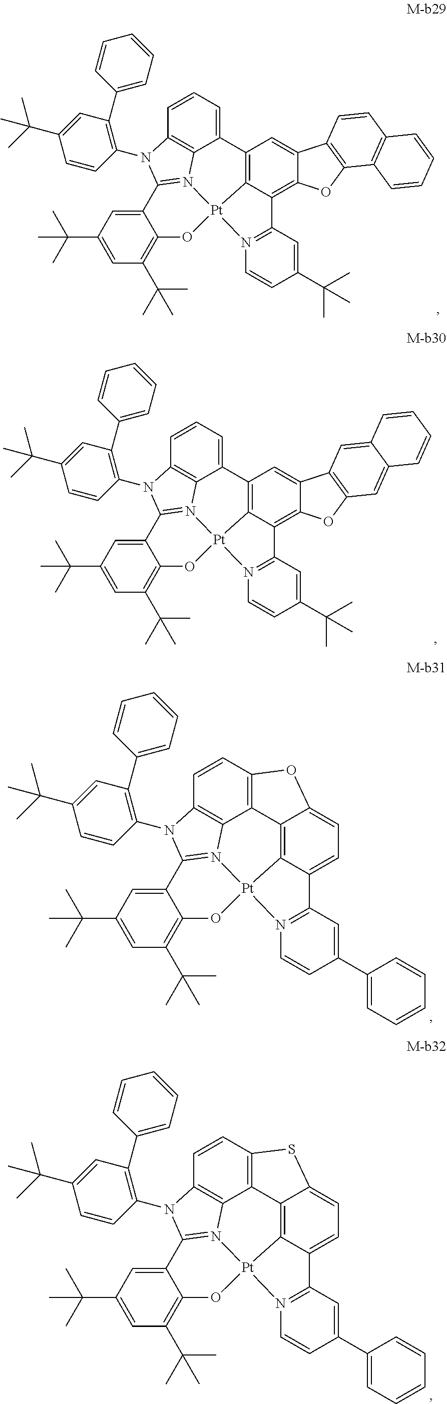

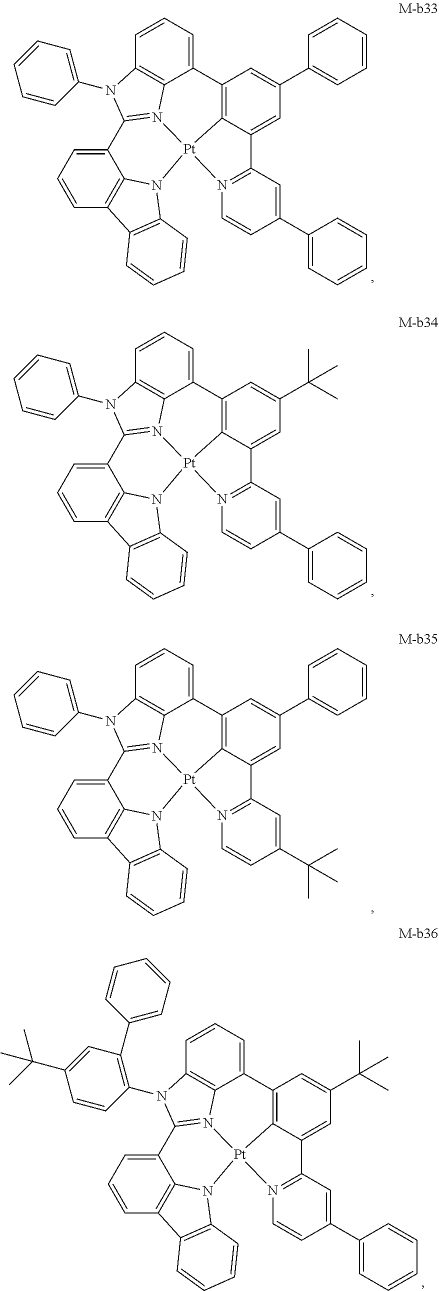

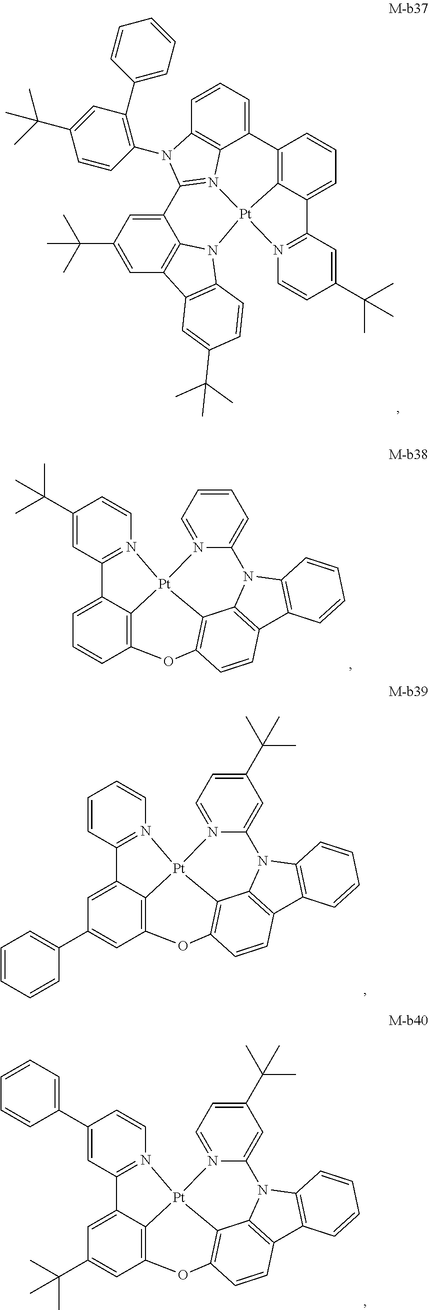

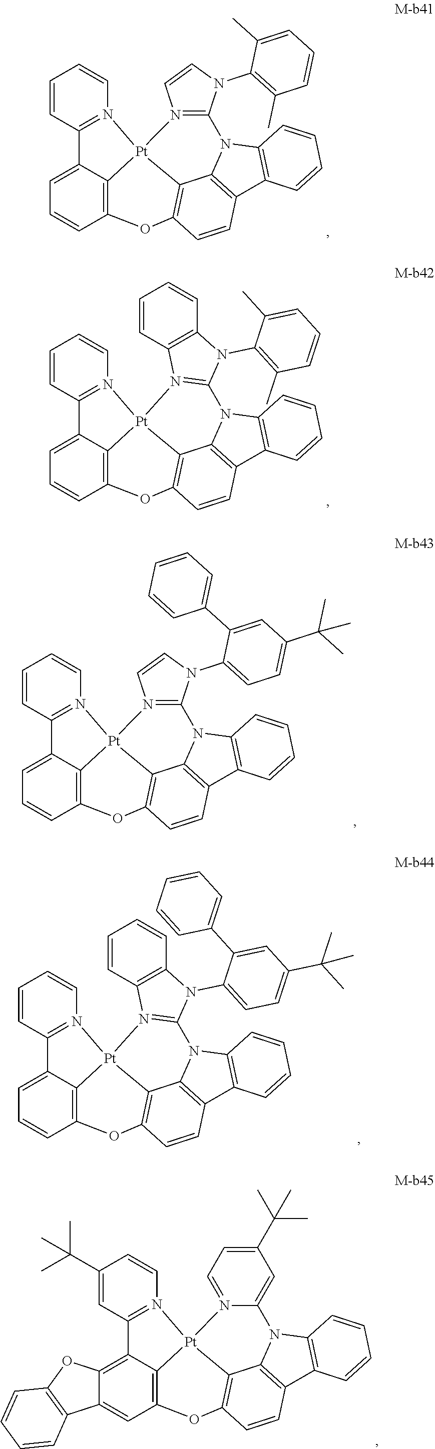

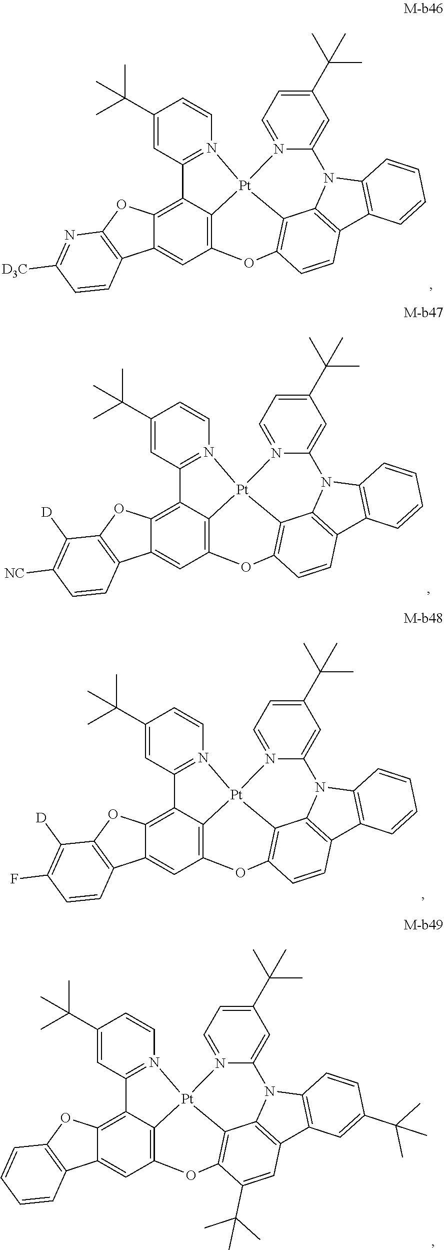

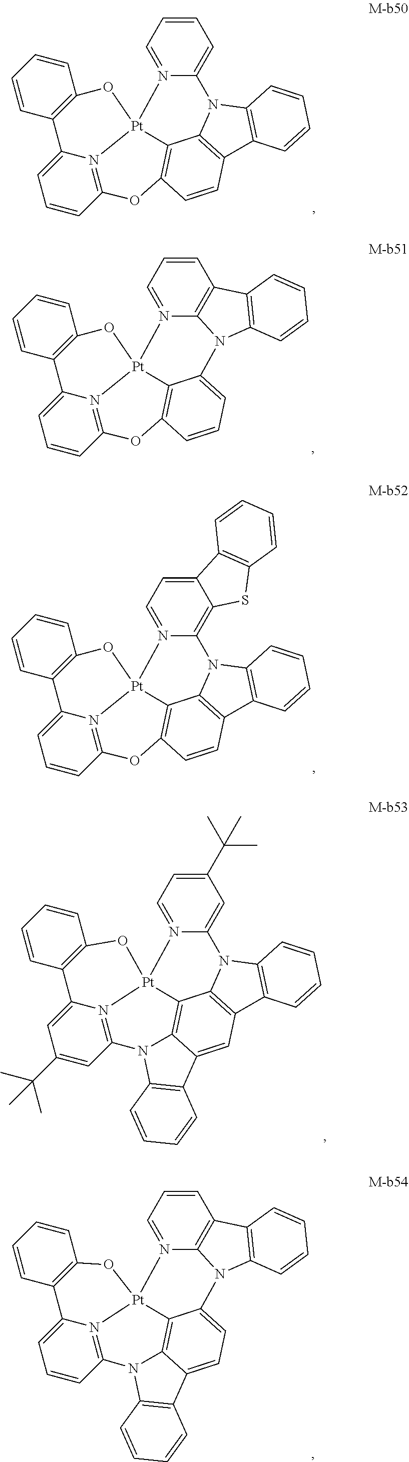

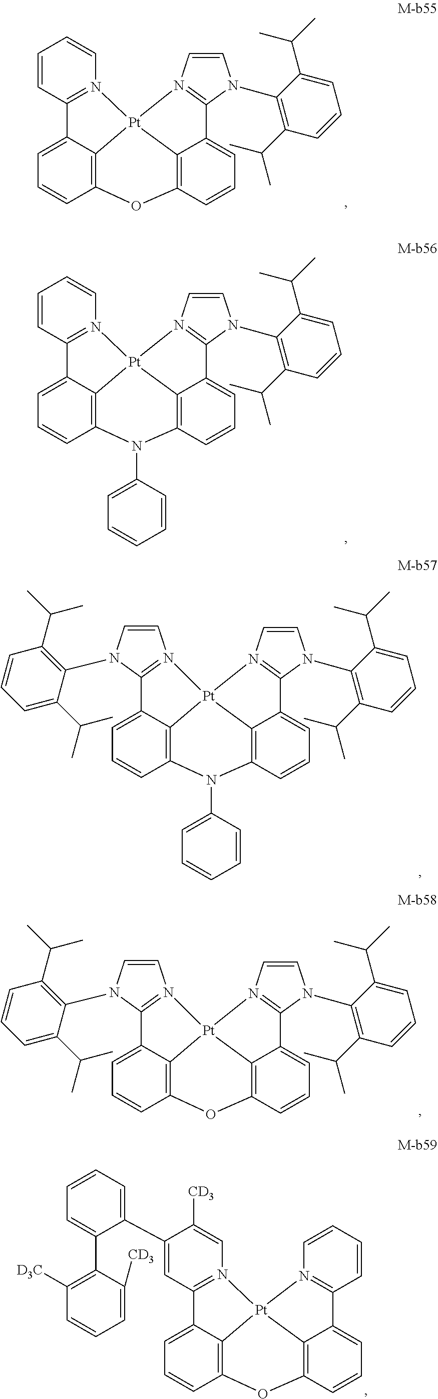

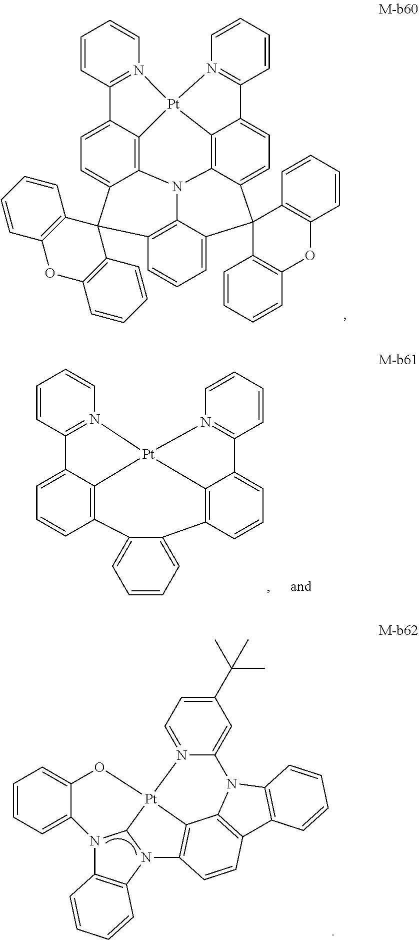

21. The organic electroluminescent device according to claim 1, wherein a triplet energy level of the first host compound is T₁₍ₕₒₛₜ₁₎, a triplet energy level of the metal complex is T_{1(Emt1)}, and a triplet energy level of the fluorescent emissive material is T_{1(Emt2)}, Wherein T₁₍ₕₒₛₜ₁₎>T_{1(Emt1)}, and T₁₍ₕₒₛₜ₁₎>T_{1(Emt2)}; preferably, T₁₍ₕₒₛₜ₁₎>T_{1(Emt1)}>T_{1(Emt2)}.

22. The organic electroluminescent device according to claim 1, wherein the organic layer is an emissive layer, and the first host compound has a structure represented by Formula X-1 or Formula X-2: 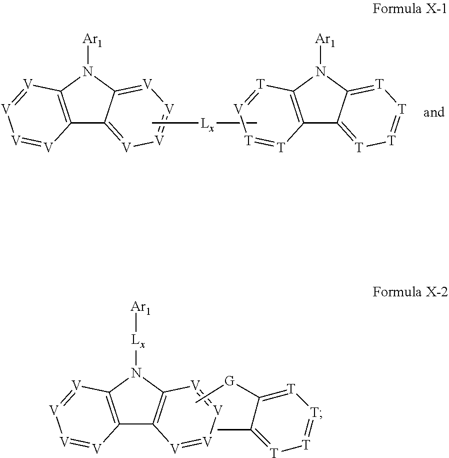
wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
G is, at each occurrence identically or differently, selected from C(R_{g})₂, NR_{g}, O or S;
V is, at each occurrence identically or differently, selected from C, CRᵥ or N,
in Formula X-1, T is, at each occurrence identically or differently, selected from C, CR_{T} or N;
in Formula X-2, T is, at each occurrence identically or differently, selected from CR_{T} or N;
R_{g}, Rᵥ, and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof;
adjacent substituents R_{g}, Rᵥ, and R_{T} can be optionally joined to form a ring;
preferably, the first host compound has a structure represented by one of Formula X-a to Formnula X-p: 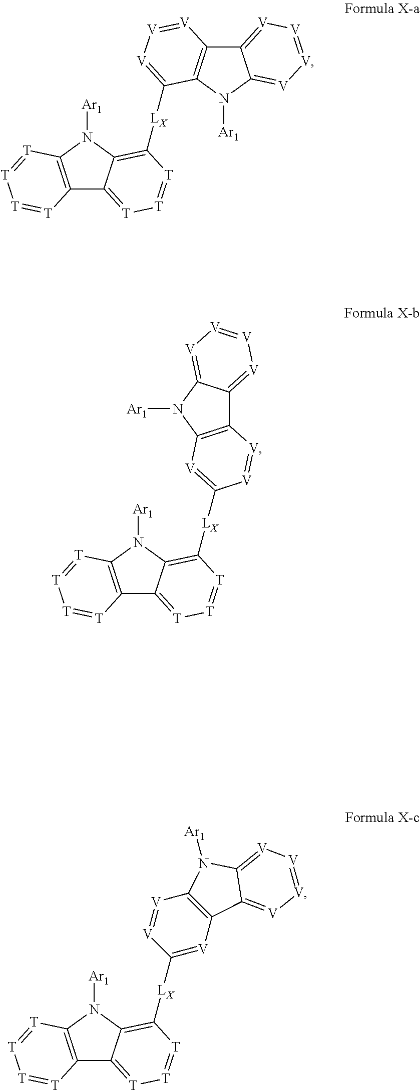 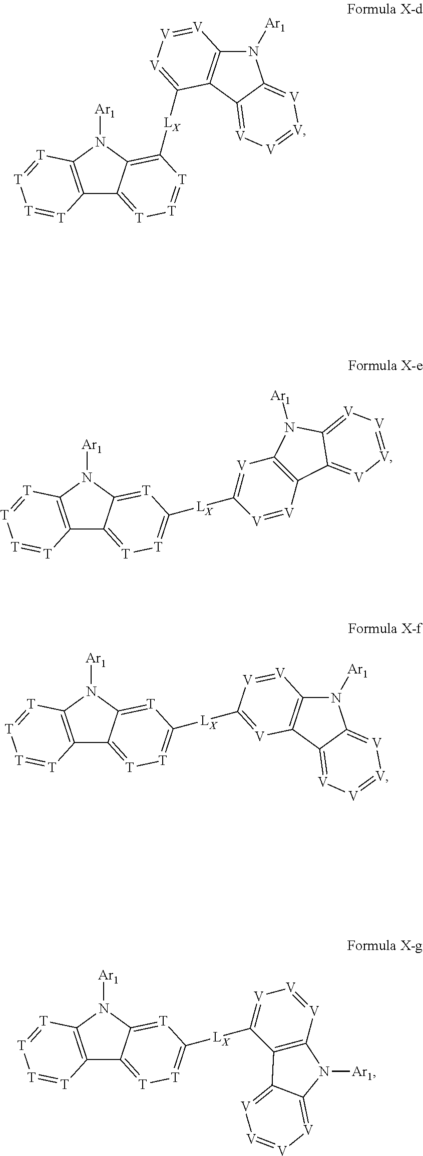 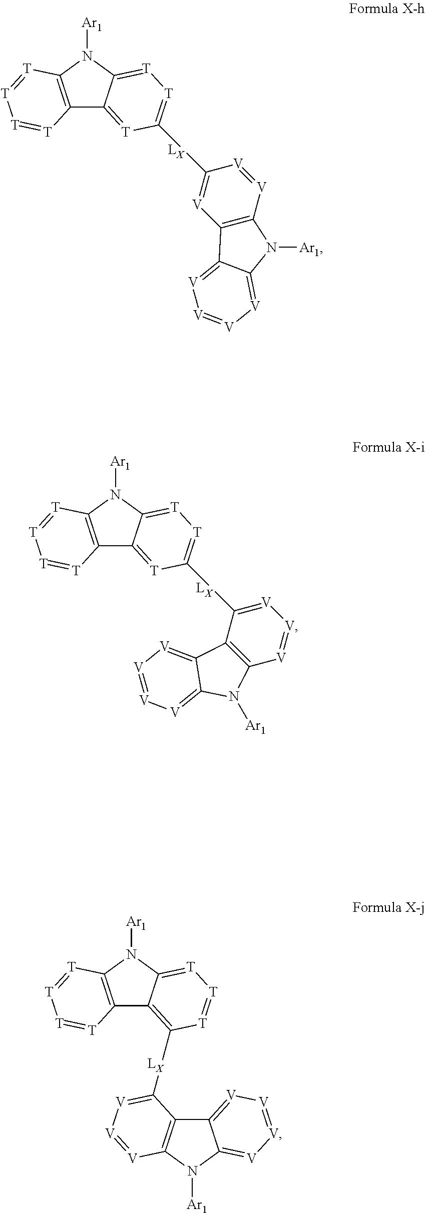 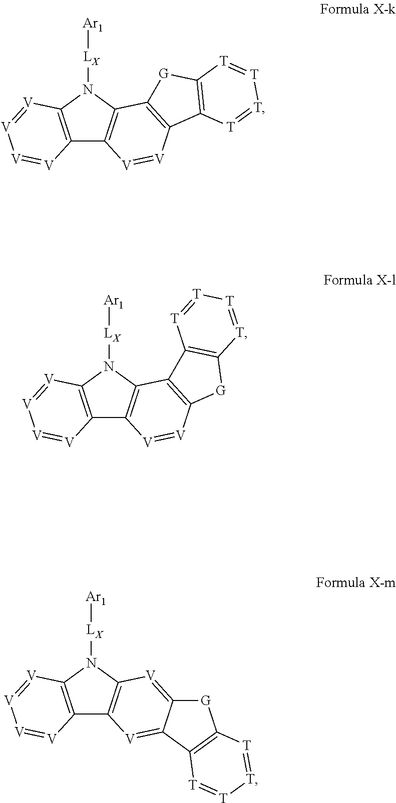 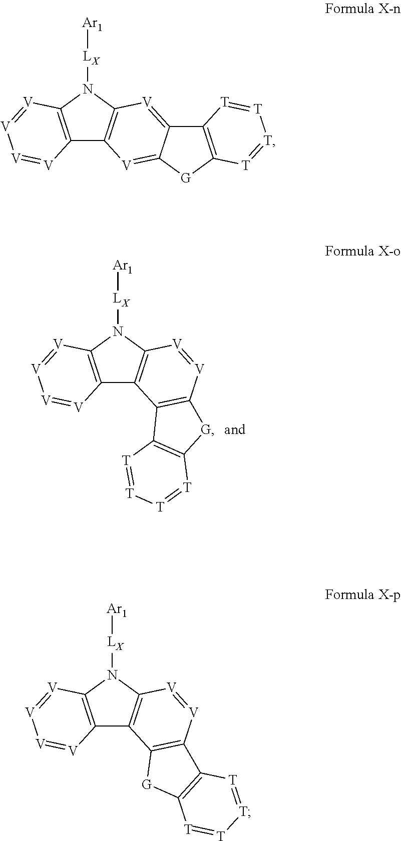
wherein,
Lₓ is, at each occurrence identically or differently selected from a single bond substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
G is, at each occurrence identically or differently, selected from C(R_{g})₂, NR_{g}, O or S;
V is, at each occurrence identically or differently, selected from CRᵥ or N;
T is, at each occurrence identically or differently, selected from CR_{T} or N;
R_{g}, Rᵥ, and R_{T} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms or a combination thereof;
adjacent substituents R_{g}, Rᵥ, and R_{T} can be optionally joined to form a ring.

23. The organic electroluminescent device according to claim 22, wherein the emissive layer comprises a second host compound; preferably, the second host compound has a structure represented by Formula Y: 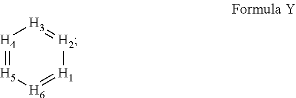
wherein,
H₁ to H₆ are, at each occurrence identically or differently, selected from C, CRₕ or N, at least two of H₁ to H₆ are N, and at least one of H₁ to H₆ is C and joined to Formula A: 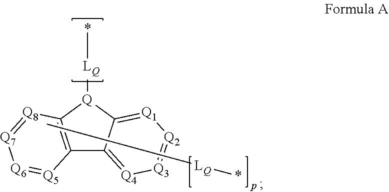
wherein,
Q is, at each occurrence identically or differently, selected from the group consisting of O, S, Se, N, NR_{Q}, CR_{Q}R_{Q}, SiR_{Q}R_{Q}, GeR_{Q}R_{Q}, and R_{Q}C═CR_{Q}; when two R_{Q} are present at the same time, the two R_{Q} may be the same or different;
p is 0 or 1; r is 0 or 1;
when Q is selected from N, p is 0, and r is 1;
when Q is selected from the group consisting of O, S, Se, NR_{Q}, CR_{Q}R_{Q}, SiR_{Q}R_{Q}, GeR_{Q}R_{Q}, and R_{Q}C═CR_{Q}, p is 1, and r is 0;
L_{Q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
Q₁ to Q₈ are, at each occurrence identically or differently, selected from C, CR_{q} or N;
Rₕ, R_{Q}, and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
“*” represents a position where Formula A is joined to Formula Y;
adjacent substituents Rₕ, R_{Q}, and R_{q} can be optionally joined to form a ring.

24. A display device, comprising the organic electroluminescent device according to claim 1.
